(19) United States
(12) Patent Application Publication
(10) Pub. No.: US 2025/0305128 A1
(43) Pub. Date: Oct. 2, 2025

(54) MULTI-ZONE GAS DISTRIBUTION FOR ASYMMETRIC WAFER BOW COMPENSATION

(71) Applicant: Lam Research Corporation, Fremont, CA (US)

(72) Inventors: James Forest Lee, Casper, WY (US); Yanhui Huang, Sherwood, OR (US); Chad Adrien Beaudette, Wilsonville, OR (US); Adriana Vintila, Wilsonville, OR (US); Daniel Boatright, Estacada, OR (US); Curtis Warren Bailey, West Linn, OR (US)

(21) Appl. No.: 18/864,489

(22) PCT Filed: May 11, 2023
(86) PCT No.: PCT/US2023/021927

§ 371 Date: Nov. 8, 2024

Related U.S. Application Data
(60) Provisional application No. 63/364,706, filed on May 13, 2022.
(60) Provisional application No. 63/364,705, filed on May 13, 2022.

(51) Int. Cl. C23C 16/455

(52) U.S. Cl. CPC C23C 16/45512; C23C 16/45565

(57) ABSTRACT

An apparatus includes a main body having a first surface including gas distribution ports (hereinafter, “ports”). The first surface is divided into zones. The ports include: first ports distributed across a first zone among the zones, each first port being fluidically connected to a first gas inlet(s) via a corresponding first gas distribution flow path; second ports distributed across a second zone among the zones, each second port being fluidica Hy connected to a second gas inlet(s) via a corresponding second gas distribution flow path; and third ports distributed across a third zone among the zones, each third port being fluidically connected to a third gas inlet(s) via a corresponding third gas distribution flow path. The first zone separates the second and third zones from one another. Within the main body, the first gas distribution flow paths are separated from each of the second and third gas distribution flow paths.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor manufacturing typically involves one or more processes to deposit and pattern a structure on a wafer. As the complexity and/or non-uniformity of the structure and/or materials on or across the wafer increase, stress applied to the wafer can cause wafer deformation (e.g., bowing, twisting, etc.) impacting various aspects from structure formation to product yield. For example, in three-dimensional NOT-AND logic gate (3D-NAND) structure fabrication, multi-stacked films with thick, high stress carbon-based hard masks, metallization patterns, and substrate trenches can cause significant wafer warpage, leading to issues such as frontside lithographic overlay mismatches, wafer bow beyond chucking limits of an electrostatic chuck, etc.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

Some embodiments provide an apparatus capable of providing one or more gases to a gas distributor (e.g., showerhead, showerhead pedestal, etc.) in distinct or partially mixed states.

Some embodiments provide an apparatus capable of distributing one or more gases, such as one or more process (or reactant) gases and/or one or more dilution gases, in an area adjacent to (e.g., over or under) a substrate in a process chamber.

Additional aspects will be set forth in the detailed description which follows, and, in part, will be apparent from the disclosure, or may be learned by practice of the disclosed embodiments and/or the claimed subject matter.

According to an embodiment, an apparatus includes a stem body and a plurality of interior flow paths. The stem body includes a proximal end and a distal end. The proximal end includes a plurality of inlets. Each of the inlets are distinct from one another and configured to receive a corresponding one or more gases. The distal end is disposed opposite the proximal end along a longitudinal axis of the stem body. The distal end being configured to interface with a gas distributor of a deposition apparatus. The distal end includes a plurality of outlets. At least one of the outlets are distinct from at least another one of the outlets. The plurality of interior flow paths includes a first interior flow path and a second interior flow path. Each of the interior flow paths extend between a corresponding inlet among the inlets and at least one corresponding outlet among the outlets such that the interior flow paths are distinct from one another. Each of the interior flow paths includes one or more structures configured to induce turbulent flow along the longitudinal axis of the stem body in response to a flow of the corresponding one or more gases along that interior flow path.

In some embodiments, the inlets may include a first inlet and a second inlet, an axis of the first inlet may be spaced apart from the longitudinal axis of the stem body in a first direction, a first portion of the first interior flow path may longitudinally extend along the axis of the first inlet, an axis of the second inlet may be spaced apart from the longitudinal axis of the stem body in a second direction different from the first direction, and a first portion of the second interior flow path may longitudinally extend along the axis of the second inlet.

In some embodiments, the one or more structures may define one or more second portions of the first interior flow path. Each of the second portions of the first interior flow path may follow a first helical path about the longitudinal axis of the stem body. In addition, the one or more structures may define one or more second portions of the second interior flow path. Each of the second portions of the second interior flow path may follow a second helical path about the longitudinal axis of the stem body.

In some embodiments, the first and second helical paths may be out of phase with one another such that each second portion of the second interior flow path is intertwined with a corresponding second portion of the first interior flow path.

In some embodiments, the one or more first structures may further define one or more third portions of the first interior flow path. Each of the third portions of the first interior flow path may linearly extend along the longitudinal axis of the stem body. Also, the one or more second structures may further define one or more third portions of the second interior flow path. Each of the third portions of the second interior flow path may linearly extend along the longitudinal axis of the stem body.

In some embodiments, each of the third portions of the first interior flow path may be spaced apart from the longitudinal axis of the stem body in the second direction, and each of the third portions of the second interior flow path may be spaced apart from the longitudinal axis of the stem body in the first direction.

In some embodiments, each of the third portions of the first interior flow path may define a first chamber including at least one first impinging protrusion constricting a passageway of the first interior flow path, and each of the third portions of the second interior flow path may define a second chamber including at least one second impinging protrusion constricting a passageway of the second interior flow path.

In some embodiments, the at least one first impinging protrusion may extend along a first circumferential section of an interior wall of the first chamber, and the at least one second impinging protrusion may extend along a second circumferential section of an interior wall of the second chamber.

In some embodiments, a median reference plane may divide the first and second chambers into corresponding divisions and the median reference plane may extend parallel to and cross the longitudinal axis of the stem body. Further, the first circumferential section of the first chamber may be disposed on an opposite side of the median reference plane from the second circumferential section of the second chamber.

In some embodiments, the first chamber may include multiple first impinging protrusions, and the second chamber may include multiple second impinging protrusions.

In some embodiments, the one or more second portions of the first interior flow path may be alternately arranged with the one or more third portions of the first interior flow path along the longitudinal axis of the stem body, and the one or more second portions of the second interior flow path may be alternately arranged with the one or more third portions of the second interior flow path along the longitudinal axis of the stem body.

In some embodiments, the first interior flow path may include four second portions and three third portions, and the second interior flow path may include four second portions and three third portions.

In some embodiments, three of the four second portions of the first interior flow path may include at least three revolutions about the longitudinal axis of the stem body. One of the four second portions of the first interior flow path may include at least one revolution about the longitudinal axis of the stem body, the one of the four second portions of the first interior flow path may be closer to the distal end of the stem body than the three of the four second portions of the first interior flow path. Three of the four second portions of the second interior flow path may include at least three revolutions about the longitudinal axis of the stem body. One of the four second portions of the second interior flow path may include at least one revolution about the longitudinal axis of the stem body, the one of the four second portions of the second interior flow path may be closer to the distal end of the stem body than the three of the four second portions of the second interior flow path.

In some embodiments, the at least one of the outlets may define an outlet of the first interior flow path, and a fourth portion of the first interior flow path may longitudinally extend along an axis of the at least one of the outlets. The axis of the at least one of the outlets may extend along the longitudinal axis of the stem body.

In some embodiments, the axis of the at least one of the outlets may be coaxially aligned with the longitudinal axis of the stem body.

In some embodiments, the one or more structures may further define one or more fourth portions of the second interior flow path. Each of the fourth portions of the second interior flow path may surround the fourth portion of the first interior flow path. Each of the fourth portions of the second interior flow path may include an annular passageway extending along the longitudinal axis of the stem body. Each annular passageway may include a first end closer to the proximal end of the stem body and a second end closer to the distal end of the stem body. Each second end may terminate at a corresponding impinging surface including a plurality of through-channel orifices extending along the longitudinal axis of the stem body. The corresponding plurality of through-channel orifices may be circumferentially spaced apart from one another about the longitudinal axis of the stem body.

In some embodiments, each annular passageway may be coaxially aligned with the longitudinal axis of the stem body.

In some embodiments, the second interior flow path may include multiple fourth portions axially arranged along the longitudinal axis of the stem body, and first central axes of the through-channel orifices of one fourth portion among the multiple fourth portions may be circumferentially offset from second central axes of the through-channel orifices of another fourth portion among the multiple fourth portions.

In some embodiments, the first central axes may be incongruent with the second central axes.

In some embodiments, the through-channel orifices of the one fourth portion of the second interior flow path may define multiple ones of the outlets of the distal end of the stem body. The multiple ones of the outlets may be distinct from the outlet of the first interior flow path.

In some embodiments, the second interior flow path may include five of the fourth portions.

In some embodiments, the fourth portion of the first interior flow path may extend further from the proximal end of the stem body than each of the fourth portions of the second interior flow path.

In some embodiments, the stem body may be an additively manufactured component, and the interior flow paths may define contiguous voids in the stem body.

In some embodiments, the stem body may be formed of an aluminum alloy.

In some embodiments, the interior flows paths may be fluidically isolated from one another within the stem body.

In some embodiments, the gas distributor is a showerhead-pedestal of the deposition apparatus.

In some embodiments, the gas distributor is a showerhead of the deposition apparatus.

In some embodiments, the interior flow paths may further include at least a third interior flow path.

According to an embodiment, an apparatus includes a showerhead. The showerhead includes first surface, second surface, and a stem body. The first surface includes a plurality of first inlets. The second surface opposes the first surface. The second surface includes a plurality of gas distribution ports. The stem body includes a proximal end, a distal end, and a plurality of interior flow paths. The proximal end includes a plurality of second inlets. Each of the second inlets is distinct from one another and configured to receive one or more gases. The distal end is disposed opposite the proximal end along a longitudinal axis of the stem body. The distal end is coupled to the first surface of the showerhead. The distal end includes a plurality of outlets interfacing with the plurality of first inlets. At least one of the outlets is distinct from at least another one of the outlets. Each of the interior flow paths extends between a corresponding second inlet among the second inlets and at least one corresponding outlet among the outlets such that the interior flow paths are fluidically isolated from one another within the stem body. Each of the interior flow paths includes one or more structures configured to induce turbulent flow along the longitudinal axis of the stem body in response to a flow of one or more gases. A first interior flow path among the interior flow paths is fluidically connected to a first group of the gas distribution ports. A second interior flow path among the interior flow paths is fluidically connected to a second group of the gas distribution ports, the second group being different from the first group.

In some embodiments, the showerhead may be a showerhead pedestal configured to support a substrate at or near its periphery such that a backside of the substrate is substantially exposed to the plurality of gas distribution ports.

In some embodiments, the apparatus may further include a process chamber configured to support a first portion of the stem body and the showerhead therein. The process chamber may include an opening through which a second portion of the stem body extends to expose the proximal end.

According to an embodiment, an apparatus includes a main body. The main body includes a first surface and a second surface opposing the first surface in a first direction. The first surface includes a plurality of gas distribution ports and is divided into a plurality of zones. The plurality of gas distribution ports include: a group of first gas distribution ports distributed across a first zone among the zones, each first gas distribution port being fluidically connected to one or more first gas inlets via a corresponding first gas distribution flow path; a group of second gas distribution ports distributed across a second zone among the zones, each second gas distribution port being fluidically connected to one or more second gas inlets via a corresponding second gas distribution flow path; and a group of third gas distribution ports distributed across a third zone among the zones, each third gas distribution port being fluidically connected to one or more of the third gas inlets via a corresponding third gas distribution flow path. The first zone separates the second zone from the third zone. Within the main body, the first gas distribution flow paths are separated from each of the second and third gas distribution flow paths.

In some embodiments, the one or more second gas inlets may also define the one or more third gas inlets.

In some embodiments, the first gas distribution flow paths may be configured to provide one or more first gases to the first gas distribution ports such that an output of the one or more first gases from the first gas distribution ports exhibits a first gas flow profile across the first zone; the second gas distribution flow paths may be configured to provide one or more second gases to the second gas distribution ports such that an output of the one or more second gases from the second gas distribution ports exhibits a second gas flow profile across the second zone; the third gas distribution flow paths may be configured to provide the one or more second gases to the third gas distribution ports such that an output of the one or more second gases from the third gas distribution ports exhibits a third gas flow profile across the third zone; and the first, second, and third gas flow profiles may be different for identical inlet/outlet boundary conditions.

In some embodiments, the first gas flow profile may be substantially uniform, the second gas flow profile may vary in at least one direction across the second zone, and the third gas flow profile may vary in at least one direction across the third zone.

In some embodiments, each of the second and third gas flow profiles may increase with increasing distance from the first gas flow profile.

In some embodiments, each of the second and third zones may include a first arrangement of gas distribution ports having a first spatial relationship, and a second arrangement of gas distribution ports having a second spatial relationship different from the first spatial relationship.

In some embodiments, the second spatial relationship may include more densely arranged gas distribution ports than the first spatial relationship.

In some embodiments, the first gas distribution ports may be distributed across the first zone according to the first spatial arrangement.

In some embodiments, the first arrangement of gas distribution ports may surround the second arrangement of gas distribution ports.

In some embodiments, the second arrangement of gas distribution ports may be closer to a periphery of the first surface than a center of the first surface.

In some embodiments, the group of the second gas distribution ports may include: a first sub-group of the second gas distribution ports distributed across a first sub-zone of the second zone; and a second sub-group of the second gas distribution ports distributed across a second sub-zone of the second zone, the second sub-zone of the second zone being adjacent to the first sub-zone of the second zone. Further, the group of the third gas distribution ports may include: a first sub-group of the third gas distribution ports distributed across a first sub-zone of the third zone; and a second sub-group of the third gas distribution ports distributed across a second sub-zone of the third zone, the second sub-zone of the third zone being adjacent to the first sub-zone of the third zone.

In some embodiments, under identical inlet/outlet boundary conditions, the second gas distribution flow paths may be configured such that a respective flow conductance along each of those second gas distribution flow paths associated with the second sub-group of the second gas distribution ports is greater than each respective flow conductance along each of those second gas distribution flow paths associated with the first sub-group of the second gas distribution ports. Further, under identical inlet/outlet boundary conditions, the third gas distribution flow paths may be configured such that a respective flow conductance along each of those third gas distribution flow paths associated with the second sub-group of the third gas distribution ports is greater than each respective flow conductance along each of those third gas distribution flow paths associated with the first sub-group of the third gas distribution ports.

In some embodiments, the group of the second gas distribution ports may further include a third sub-group of the second gas distribution ports distributed across a third sub-zone of the second zone, the third sub-zone of the second zone being between the first and second sub-zones of the second zone. Also, the group of the third gas distribution ports may further include a third sub-group of the third gas distribution ports distributed across a third sub-zone of the third zone, the third sub-zone of the third zone being between the first and second sub-zones of the third zone.

In some embodiments, under identical inlet/outlet boundary conditions, the second gas distribution flow paths may be configured such that a respective flow conductance along each of those second gas distribution flow paths associated with the third sub-group of the second gas distribution ports is greater than each respective flow conductance along each of those second gas distribution flow paths associated with the first sub-group of the second gas distribution ports and less than each respective flow conductance along each of those second gas distribution flow paths associated with the second sub-group of the second gas distribution ports. Further, under identical inlet/outlet boundary conditions, the third gas distribution flow paths may be configured such that a respective flow conductance along each of those third gas distribution flow paths associated with the third sub-group of the third gas distribution ports is greater than each respective flow conductance along each of those third gas distribution flow paths associated with the first sub-group of the third gas distribution ports and less than each respective flow conductance along each of those third gas distribution flow paths associated with the second sub-group of the third gas distribution ports.

In some embodiments, the third sub-zone of the second zone may include a sub-portion in which a first plurality of the second gas distribution ports of the third sub-group of the second gas distribution ports are configured differently than a second plurality of the second gas distribution ports of the third sub-group of the second gas distribution ports. In addition, the third sub-zone of the third zone may include a sub-portion in which a first plurality of the third gas distribution ports of the third sub-group of the third gas distribution ports are configured differently than a second plurality of the third gas distribution ports of the third sub-group of the third gas distribution ports.

In some embodiments, the first plurality of the second gas distribution ports of the third sub-group of the second gas distribution ports may be more densely arranged than the second plurality of the second gas distribution ports of the third sub-group of the second gas distribution ports. Also, the first plurality of the third gas distribution ports of the third sub-group of the third gas distribution ports may be more densely arranged than the second plurality of the third gas distribution ports of the third sub-group of the third gas distribution ports.

In some embodiments, the main body may include a plurality of passages extending in a second direction different from the first direction, the passages being spaced apart from one another in a third direction different from the second direction. Further, each of the passages may be fluidically connected to a corresponding plurality of the gas distribution ports.

In some embodiments, a cross-sectional area of each of the passages in a plane perpendicular to the second direction may be substantially equivalent.

In some embodiments, a cross-sectional area of at least one of the passages in a plane perpendicular to the second direction may be different from a cross-sectional area of at least another one of the passages in the plane perpendicular to the second direction.

In some embodiments, corresponding pitches between adjacent passages among the passages may be substantially equivalent.

In some embodiments, a first plurality of the passages may be arranged in the third direction with a first pitch, and a second plurality of the passages may be arranged in the third direction with a second pitch different from the first pitch.

In some embodiments, the apparatus may further include an outer wall surrounding the main body. The main body may further include: a third surface extending between the first surface and the second surface; a plurality of first blind cavities recessed into the third surface and arranged about a perimeter of the main body; and a plurality of second blind cavities recessed into the third surface and arranged about the perimeter of the main body, each of the first blind cavities being disposed between the first surface and a corresponding one of the second blind cavities in the first direction. In addition, a portion of the third surface extending between the first blind cavities and the second blind cavities may form a septal wall. The septal wall may include a plurality of recessed portions in the third surface. Each of the recessed portions may be disposed between corresponding ones of the first and second blind cavities adjacent to one another in the first direction so as to form, in association with an inner surface of the outer wall, a respective gas flow channel fluidically connecting the corresponding ones of the first and second blind cavities.

In some embodiments, each of the first blind cavities may be fluidically connected to one or more of the passages.

In some embodiments, some of the passages may fluidically connect two of the first blind cavities to one another, the two first blind cavities opposing one another relative to a central axis of the main body extending in the first direction.

In some embodiments, each first blind cavity among a first group of the first blind cavities may have a first opening area facing the inner surface of the outer wall and may be fluidically connected to a first amount of the passages, and each first blind cavity among a second group of the first blind cavities may have a second opening area facing the inner surface of the outer wall and may be fluidically connected to a second amount of the passages. The second opening area may be larger than the first opening area. The second amount may be greater than the first amount.

In some embodiments, the apparatus may further include a plurality of first elongated holes in the main body that extend radially from a first central region of the main body, and a plurality of second elongated holes in the main body that extend radially from a second central region of the main body. Each of the first elongated holes may have a corresponding proximal end fluidically connected to at least one of the one or more first inlets, and a corresponding distal end fluidically connected to a second blind cavity among the second blind cavities so as to form a corresponding portion of at least one of the first gas distribution flow paths. Each of the second elongated holes may have a corresponding proximal end fluidically connected to at least one of the one or more second inlets and the one or more third inlets, and a corresponding distal end fluidically connected to a second blind cavity among the second blind cavities so as to form a corresponding portion of at least one of the second and third gas distribution flow paths.

In some embodiments, each of the first elongated holes may extend in a first planar region of the main body, each of the second elongated holes may extend in a second planar region of the main body different from the first planar region of the main body, and the first planar region may be closer to the second surface of the main body than the second planar region.

In some embodiments, each of the first and second planar regions may be closer to the second surface than each of the passages.

In some embodiments, respective cross-sectional areas of the first and second elongated holes in corresponding planes perpendicular to their respective directions of longitudinal extension may be equivalent.

In some embodiments, a first group of the second blind cavities may be physically and fluidically connected directly to the first elongated holes and may be separated from the second elongated holes in an interior of the main body, and a second group of the second blind cavities may be physically and fluidically connected directly to the second elongated holes and may be separated from the first elongated holes in the interior of the main body. The second group of the second blind cavities may include a first sub-group of second blind cavities, each second blind cavity of the first sub-group of second blind cavities may be physically and fluidically connected directly to one distal end of the second elongated holes among the distal ends of the second elongated holes. The second group of the second blind cavities may also include a second sub-group of second blind cavities, each second blind cavity of the second sub-group of second blind cavities may be physically and fluidically connected directly to two distal ends of the second elongated holes among the distal ends of the second elongated holes.

In some embodiments, the first group of the second blind cavities may be arranged in a first region of the main body, the first sub-group of second blind cavities may be arranged in a second region of the main body, and the second sub-group of second blind cavities may be arranged in a third region of the main body. The second region of the main body may be between the first and third regions of the main body.

In some embodiments, the second region may be disposed on opposite sides of the first region, and the third region may be disposed on opposite sides of the second region and opposite sides of the first region.

In some embodiments, each of the first elongated holes may have a substantially equivalent first cross-sectional area in a plane perpendicular to its respective direction of longitudinal extension, each second elongated hole associated with the first sub-group of second blind cavities may have a substantially equivalent second cross-sectional area in a plane perpendicular to its respective direction of longitudinal extension, each second elongated hole associated with the second sub-group of second blind cavities may have a substantially equivalent third cross-sectional area in a plane perpendicular to its respective direction of longitudinal extension, and the first, second, and third cross-sectional areas may be different from one another.

In some embodiments, the third cross-sectional area may be greater than the second cross-sectional area, and the second cross-sectional area may be greater than the first cross-sectional area.

In some embodiments, the apparatus may further include a cooling conduit thermally coupled to the main body. The cooling conduit may have an inlet being configured to receive clean dry air (CDA) at a first temperature and an outlet being configured to output the CDA at a second temperature different from the first temperature. The main body may include a first groove recessed into the second surface. A portion of the cooling conduit may extend within the first groove.

In some embodiments, a first cap structure may enclose the cooling conduit in the first groove in a compressed state.

In some embodiments, the cooling conduit may be formed of stainless steel.

In some embodiments, the cooling conduit may be sized to enable a flow rate of CDA up to about 140 standard liters per minute with a Reynolds number greater than about 2500.

In some embodiments, the apparatus may further include a resistive heating element. The main body may further include a second groove recessed into the second surface. A portion of the resistive heating element may extend within the second groove.

In some embodiments, in the first direction, the second groove may extend farther into the second surface than the first groove. Also, in a radial direction perpendicular to the first direction, an outermost portion of second groove may be closer to a periphery of the main body than an outermost portion of the first groove.

In some embodiments, the apparatus may further include a process chamber configured to support the main body therein. The main body may form a portion of a showerhead.

In some embodiments, the showerhead may be a showerhead pedestal configured to support a substrate thereover such that a majority of a backside of the substrate is exposed to the plurality of gas distribution ports.

In some embodiments, the main body may be formed of an aluminum alloy.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals refer to similar elements.

FIG. 1 schematically illustrates a perspective view of a bowed semiconductor substrate exhibiting asymmetric bowing.

FIG. 2A schematically illustrates a plan view of a substrate exhibiting asymmetric bowing.

FIG. 2B schematically illustrates a cross-sectional view of the substrate of FIG. 2A taken along sectional line 2B-2B.

FIG. 2C schematically illustrates a cross-sectional view of the substrate of FIG. 2A taken along sectional line 2C-2C.

FIG. 3 is a flowchart of a process to mitigate asymmetric wafer bowing according to some embodiments.

FIGS. 4A, 4B1, 4B2, and 4C schematically illustrate various stages of forming a stress compensation layer to mitigate asymmetric wafer bowing according to some embodiments.

FIG. 5 is a graph illustrating a thickness profile and a stress profile for each of i) a compressive film, ii) a tensile film, and iii) a stress compensation layer combining the compressive film and the tensile film according to some embodiments.

FIG. 6 is a graph comparing a desired profile and simulated profiles of reactant gas flowing from variously configured gas distributors relative to a backside of a substrate according to some embodiments.

FIGS. 7A and 7B schematically illustrate perspective views of a gas distributor according to some embodiments.

FIG. 8 schematically illustrates a partially exploded perspective view of the gas distributor of FIG. 7A according to some embodiments.

FIG. 9A schematically illustrates a plan view of a first surface of the gas distributor of FIG. 7A according to some embodiments.

FIG. 9B schematically illustrates an enlarged portion of FIG. 9A according to some embodiments.

FIG. 9C schematically illustrates an enlarged portion of a first surface of another gas distributor according to some embodiments.

FIG. 10 schematically illustrates a side view of a portion of the gas distributor according to some embodiments.

FIG. 11 schematically illustrates a cross-sectional view of the portion of the gas distributor of FIG. 10 according to some embodiments.

FIGS. 12A, 12B, and 12C schematically illustrate cross-sectional views of the gas distributor of FIGS. 7A and 10 respectively taken along sectional lines 12A-12A, 12B-12B, and 12C-12C according to some embodiments.

FIG. 13 schematically illustrates a plan view of a second surface of the portion of the gas distributor of FIG. 10 according to some embodiments.

FIG. 14 schematically illustrates an enlarged portion of FIG. 12B according to some embodiments.

FIG. 15 schematically illustrates a gas distribution flow path through the gas distributor of FIG. 7A according to some embodiments.

FIG. 16 schematically illustrates an exploded perspective view of various components of the gas distributor of FIG. 7B according to some embodiments.

FIG. 17 is a graph demonstrating simulated temperature control of a gas distributor at various setpoint temperatures and duty cycles according to some embodiments.

FIGS. 18A and 18B illustrate perspective views of a stem body of the gas distributor of FIG. 18 according to some embodiments.

FIG. 19 schematically illustrates a cross-sectional view of the stem body of FIG. 18A according to some embodiments.

FIGS. 20, 21A, and 21B schematically illustrate tortuous flow paths interior to the stem body of FIG. 18A according to some embodiments.

FIG. 22 schematically illustrates a side view of the stem body of FIG. 18A according to some embodiments.

FIGS. 23-27 schematically illustrate cross-sectional views of the stem body respectively taken along sectional lines 23-23, 24-24, 25-25, 26-26, and 27-27 according to some embodiments.

FIG. 28 schematically illustrates a thermal management system configured to control the temperature of a gas distributor according to some embodiments.

FIG. 29 schematically illustrates a substrate processing system configured for backside wafer deposition according to some embodiments.

FIG. 30 schematically illustrates a multi-station processing tool configured for backside wafer deposition according to some embodiments.

### DETAILED DESCRIPTION OF SOME EMBODIMENTS

In the following description, numerous specific details are set forth in order to provide a thorough understanding of various embodiments. The disclosed embodiments may be practiced without some or all of these specific details. In other instances, well-known process operations have not been described in detail to not unnecessarily obscure the disclosed embodiments. While the disclosed embodiments will be described in conjunction with specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles, such as printed circuit boards, magnetic recording media, magnetic recording sensors, mirrors, optical elements, micro-mechanical devices, and the like.

Semiconductor fabrication processes involve formation of various structures, many of which may be two-dimensional. As semiconductor device dimensions shrink and devices are scaled to be smaller, the density of features across a semiconductor substrate increases, resulting in layers of material etched and deposited in various ways, including in three dimensions. For example, a 3D-NAND structure is one technology that is becoming increasingly popular due to lower cost and increased memory density compared to other techniques, such as two-dimensional (2D)-NAND structure, and higher reliability in various applications. During the fabrication of a 3D-NAND structure, wafer bow can change drastically. For example, deposition of thick hard mask materials and etching of trenches along a wafer surface in fabricating a 3D-NAND structure can cause wafer bowing. As layers of films are stacked on top of each other during fabrication, more stress is introduced to the semiconductor wafer which can cause bowing. Moreover, stress fields along different axes of the wafer may become increasingly inhomogeneous, leading to multimodal bow shapes.

Bowing can be measured using an optical technique. Wafer bowing can be measured or evaluated by obtaining a wafer map or stress map. Bowing can be quantified using a bow value and/or a warpage value as described herein. In general, a “wafer bow value” measures the deviation of the center point of a median surface of a free, un-clamped wafer from the median surface to a reference plane, which is defined by three corners of an equilateral triangle having a base a specified amount less than the nominal diameter of the wafer, according to the American Society for Testing and Materials (ASTM) F534 standard. A “wafer warp value” is the difference between the maximum and the minimum distances of the median surface of a free, un-clamped wafer from the reference plane, according to the ASTM F657 and ASTM F1390 standards. It is noted, however, that the warpage value can be expressed along one or more axes—for example, an asymmetrically warped wafer may have an x-axis warpage and/or a y-axis warpage. Further, “wafer flatness” is a measure of the deviation of the front surface of a wafer, expressed in total indicator reading or maximum focal plane deviation, relative to a specified reference plane when the back surface of the wafer is ideally flat, according to the ASTM F1530 standard.

In a bow-shaped wafer, the lowest point is the center of the wafer and the highest point is the edge of the wafer. In a dome-shaped wafer, the lowest point is the edge of the wafer and the highest point is the center of the wafer. Bow-shaped and dome-shaped wafers have symmetrical or largely symmetrical bowing. Wafers can also have asymmetric bowing. In asymmetric bowing, warpage is measured along an x-axis and a y-axis. An asymmetrically bowed wafer has different values for the x-axis warpage and y-axis warpage. In some cases, an asymmetrically bowed wafer has a negative x-axis warpage and a positive y-axis warpage. In some cases, an asymmetrically bowed wafer has a positive x-axis warpage and a negative y-axis warpage. In some cases, an asymmetrically bowed wafer has both a positive x-axis warpage and a positive y-axis warpage, but the warpage values are different. In some instances, an asymmetrically bowed wafer has both a negative x-axis warpage and a negative y-axis warpage, but the warpage values are different. One example of an asymmetrically bowed wafer is a saddle-shaped wafer. For a saddle-shaped wafer, in one example, the warpage on the x-axis may be +200 μm and the warpage on the y-axis may be −200 μm. Saddle-shaped wafers have two opposing edges of the wafer that are curved upward while another two opposing edges of the wafer are curved downward. As used herein, warpage can refer to any deviation from planarity exhibited by a wafer, where a bow-shaped wafer, dome-shaped wafer, and saddle-shaped wafer are examples of different types of substrate warpage.

Bowing can cause problems with subsequent processing, such as during lithography, as etching can be uneven if the semiconductor substrate is warped. High bowing can be caused by deposition of a thick, high-stress carbon hard mask layer(s). Additionally, due to multi-stacked films and the presence of thick, high-stress carbon-based hard masks used in such fabrication processes, etching can cause some asymmetric warpage and deposition processes can introduce significant wafer warpage of up to a variation between −1300 μm to +1300 μm bow. For example, an ashable hard mask may have a stress value of up to −1000 MPa and have a bow value of up to −1000 μm. In some cases, a high-aspect ratio slit etch and metal fill (e.g., tungsten fill) can induce large anisotropic stress on the semiconductor substrate.

Addressing such wafer warpage can be a challenge as subsequent or downstream processing may be affected by a wafer warpage exceeding, for example, about ±150 μm, about ±200 μm, about ±300 μm, or about ±500 μm. It, however, is recognized that as processes become more sensitive to wafer topology, lesser degrees of wafer warpage may need to be addressed. One example issue is that mechanical wafer handling may be affected due to wafer warpage, where wafers that are not flat may not be gripped or held effectively by a wafer robot or wafer handling mechanism. Additionally, wafer warpage may contribute to process non-uniformity, where downstream etch, deposition, or clean operations may be adversely affected due to processing non-uniformities across a surface of the wafer. For instance, wafer warpage may lead to poor thermal contact, which can cause non-uniform heating of a wafer that, in turn, can lead to non-uniform processing of the wafer. In some instances, processing of highly warped wafers may cause further warping. For example, etching of a trench in one direction can cause warping in asymmetric bowing due to asymmetric stress on the wafer. In addition, lithography operations may be adversely affected by wafer warpage as precise patterns are unable to be formed. When wafers are used in subsequent processing that involve chucking of the wafer to an electrostatic chuck, highly warped wafers may not be able to be processed in some tools. Many electrostatic chucks have a “chucking limit,” which is defined as the maximum warpage tolerated before the wafer cannot be effectively chucked. For example, some electrostatic chucks have a chucking limit of about ±300 μm. Warped wafers that exceed the chucking limit may not be processed in such instances.

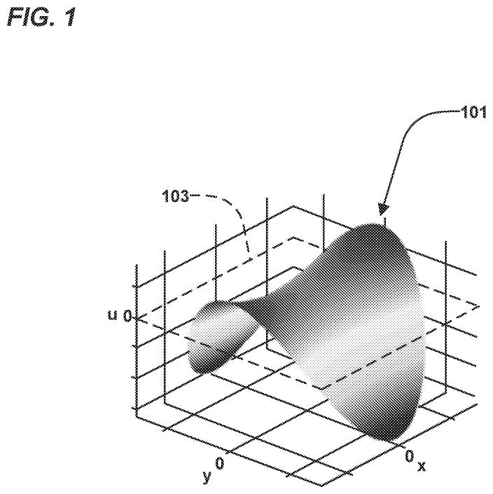

FIG. 1 schematically illustrates a perspective view of a bowed semiconductor substrate exhibiting asymmetric bowing.

Referring to FIG. 1, substrate 101 is shown relative to a three-dimensional coordinate system having reference plane 103 parallel to a plane defined by the x-axis direction and the y-axis direction. In this manner, an extent of deformation (e.g., warpage) of substrate 101 from reference plane 103 is indicated along the u axis-direction. Accordingly, substrate 101 is shown as being asymmetrically bowed. In other words, an extent of the bowing of substrate 101 along the x-axis direction is different than an extent of the bowing of substrate 101 along the y-axis direction. For instance, warpage in the x-axis direction reaches a first positive value and warpage in the y-axis direction reaches a second negative value, a magnitude of the second negative value being greater than a magnitude of the first positive value. Such deformation of substrate 101 may be referred to as “saddle-shaped” bowing of substrate 101. As used herein, warpage refers to any deviation of a median surface of substrate 101 from reference plane 103, and, thereby, from planarity.

As 3D-NAND structures continue to scale up and high-aspect ratio features become increasingly more common, new challenges are emerging related to localized stress and inter-die stress variations on semiconductor substrates. Localized stress and inter-die stress variations may lead to block-bending, cell cross-talk, cell loss, and/or cell misalignments. Localized stress refers to stress changes that occur within a wafer in a non-uniform manner. Poorly compensated/corrected localized stress may lead to localized wafer topology changes, which in turn may lead to poor alignment during lithography. Such poor alignment is typically viewed in terms of in-plane distortion (IPD), which is a quantification of the vector displacement of on-wafer alignment marks from their expected positions due to wafer topology. High IPD during lithography may lead to undesirable changes in critical dimensions or any other feature that is defined in a lithographic step, and so the foregoing phenomena of block-blending, cell cross-talk, cell loss, and/or cell misalignments can arise due to lithographic errors.

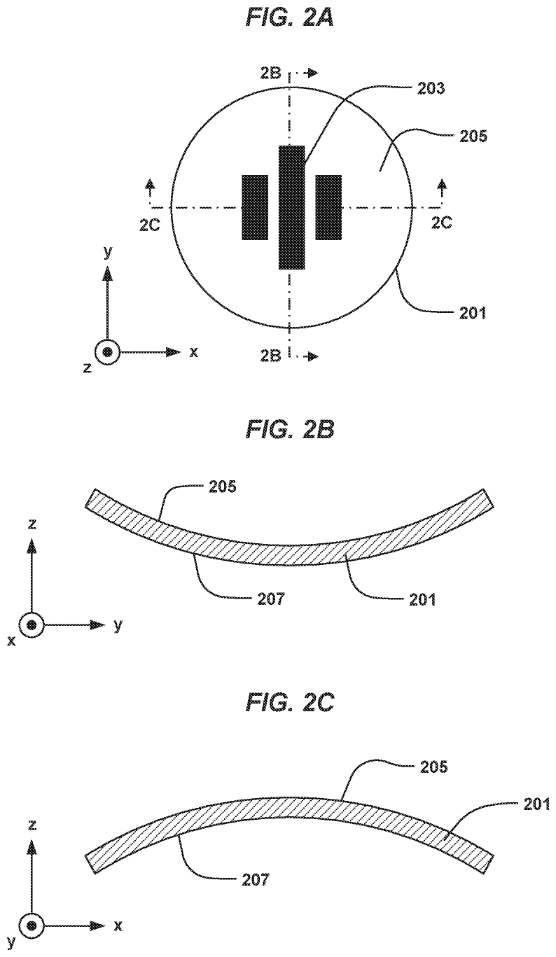

FIGS. 2A to 2C schematically illustrate various views of a substrate exhibiting asymmetric bowing. For instance, FIG. 2A schematically illustrates a plan view of substrate 201, whereas FIGS. 2B and 2C schematically illustrate cross-sectional views of substrate 201 taken along sectional lines 2B-2B and 2C-2C, respectively. As seen in FIG. 2A, substrate 201 may include various features (e.g., metallization pattern 203) formed on frontside 205 that cause, at least in part, substrate 201 to asymmetrically bow. For illustrative convenience, feature formations on frontside 205 of substrate 201 are not shown in FIGS. 2B and 2C. As can be appreciated from FIGS. 2B and 2C, substrate 201 exhibits parabolic bowing along the x-axis direction and anti-parabolic bowing along the y-axis direction, the combination of which can yield saddle-shaped bowing similar to the saddle-shaped bowing of substrate 101 in FIG. 1.

Various techniques may be employed to address the bowing of a substrate, such as substrate 201. For instance, one or more stress compensation layers may be formed on a backside of a semiconductor substrate, such as backside 207. The utilization of backside stress compensation layers has typically been limited to mitigating monotonic global wafer warpage. In other words, techniques to address the bowing of semiconductor substrates are usually limited to addressing axially symmetric or multi-axially symmetric bow profiles. In some instances, asymmetric bowing may be addressed through the formation of backside stress compensation layers using mask or precursor zoning techniques during layer formation. For instance, localized stress modulation may be achieved through the delivery of precursor material to certain areas or regions of an asymmetrically bowed substrate using, for instance, a carrier ring mask. In other instances, localized stress modulation may be achieved using precursor zoning employing multiple plenums to control delivery of gas to different locations. However, such techniques have yielded limited success due, in part, to high IPD overlay and issues associated with chucking a bowed substrate. Such issues may be the result of sharp transitions in film stress between zones and the difficulty in designing a zone layout that minimizes local topography variation.

Accordingly, one or more embodiments seek to provide methods and apparatuses for mitigating asymmetric bowing of a substrate via backside deposition. Precursor control from a gas distributor (e.g., a showerhead, showerhead pedestal, etc.) may provide a desired thickness profile in one or more films deposited on a backside of a substrate. The one or more deposited films may be utilized to collectively form a stress compensation layer. A stress profile of the stress compensation layer may be characterized by a polynomial function. In this manner, the stress compensation layer may mitigate or even resolve localized stress in an asymmetrically bowed substrate. In some implementations, the stress compensation layer may be formed through a film stacking approach, which deposits multiple films having different thickness profiles. In some implementations, a combination of a compressive film having a non-linear thickness profile and a tensile film having a different non-linear thickness profile may be deposited on a backside of a bowed substrate. For instance, the compressive film may have a first parabolic-shaped profile and the tensile film may have a second parabolic-shaped profile opening in a direction opposite the first parabolic-shaped profile. In this manner, the compressive film and the tensile film can be collectively utilized to form a stress compensation layer. In some instances, the stress compensation layer may be flat or substantially flat. Such a film stacking technique via backside deposition may be utilized to minimize (or at least reduce) IPD overlay issues without impacting the ability to chuck the substrate.

Thickness tuning of the one or more films in a stress compensation layer may be achieved by controlling precursor and dilution gas concentration proximate (or adjacent) to a substrate during one or more deposition operations. According to various embodiments, precursor and dilution gas concentration adjacent to the substrate may be controlled by design features in a gas distributor. Such design features may influence flow dynamics of the precursor and dilution gases from the gas distributor. In an embodiment, the gas distributor may be divided into multiple gas distribution groups (or zones). For example, one or more precursor gases may be delivered to (and, thereby, from) one or more first zones and one or more dilution gases may be delivered to (and, thereby, from) one or more second zones. In some instances, gas output from (or a gas flow profile across) one zone may be uniform (or substantially uniform) and gas output from one or more other zones may be irregular, e.g., exhibit a gradient, such as a non-linear gradient increasing with increasing distance from the one zone, such as a parabolic gradient increasing with increasing distance from the one zone. The term “uniform,” as used herein with respect to gas flows and gas flow profiles, refers to a gas flow or gas flow profile that is substantially uniform or similar; such gas flows or gas flow profiles may potentially include minor perturbations or deviations due to various localized effects, but would still be recognizable as generally uniform. To this end, the various gas flow profiles referred to herein may be considered an effect of the structure(s) of the gas distributor, and, thereby, understood as occurring under identical inlet/outlet boundary conditions, e.g., pressure, temperature, etc. In some cases, gas output from the one or more other zones may exhibit a stepped gradient increasing with increasing distance from the one zone or any other suitable gas output profile. According to some embodiments, a combined gas flow profile of all the gas distribution ports may exhibit mirror symmetry about an axis, but not exhibit 3-fold or higher radial symmetry. Such multizone flow control can be utilized to modulate the concentration of precursor and dilution gas adjacent to a substrate during layer formation. It is also contemplated that one or more primary zones may include one or more sub-zones and the one or more sub-zones may, in some implementations, include one or more sub-portions to further tailor the concentration of precursor and dilution gas (or flow dynamics) adjacent to the substrate, such as the flow dynamics in proximity to an edge of the substrate. This may be achieved via different gas distribution port patterns (e.g., positions, densities, port sizes, etc.) between a primary zone, a sub-zone, and/or a sub-portion of a sub-zone. Additionally, or alternatively, different gas distribution flow paths (e.g., sizes, amounts, flow conductance, etc.) supplying one or more precursor or one or more dilution gases to different zones, sub-zones, and/or sub-portions of sub-zones may be utilized to also tailor the concentration of precursor and dilution gas (or flow dynamics) adjacent to the substrate.

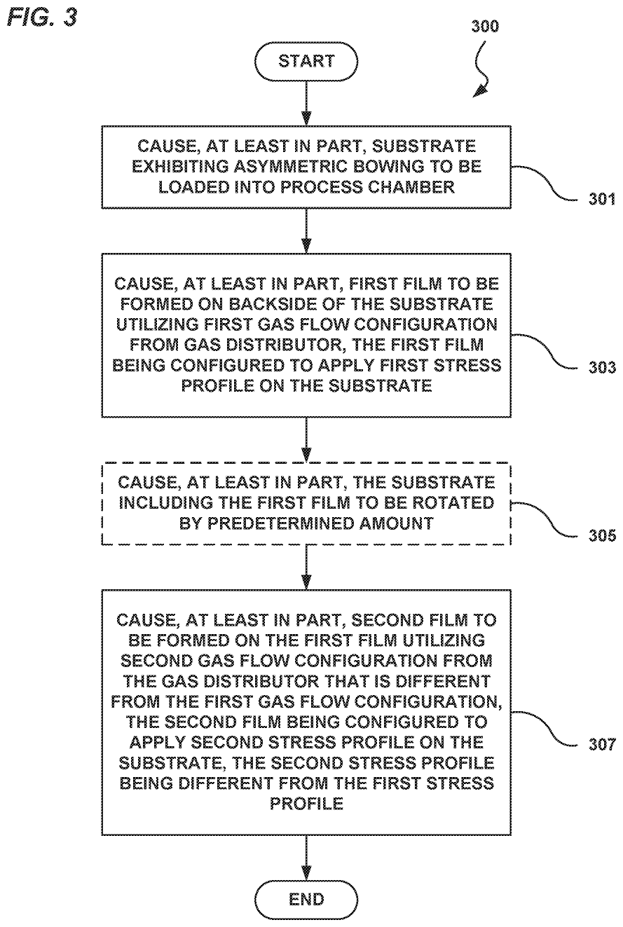

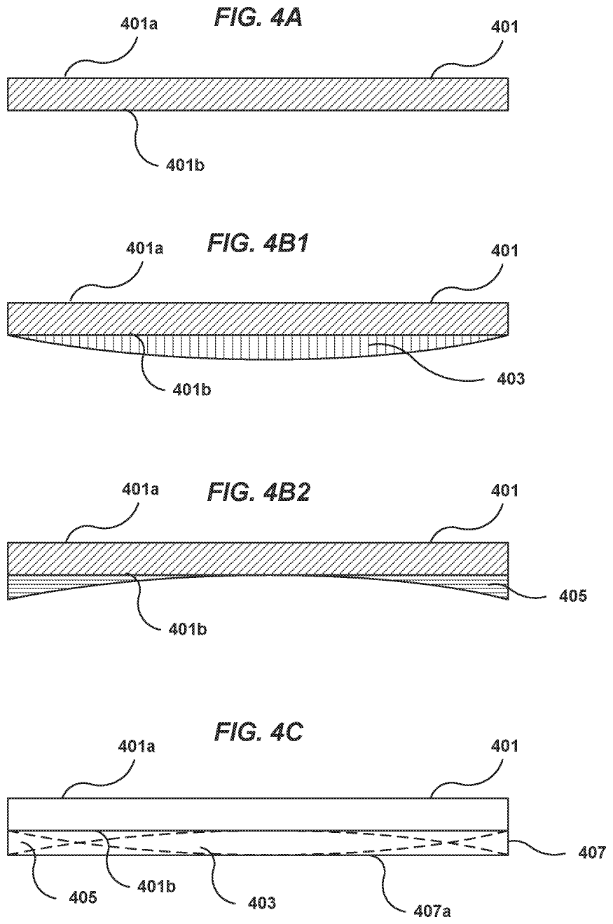

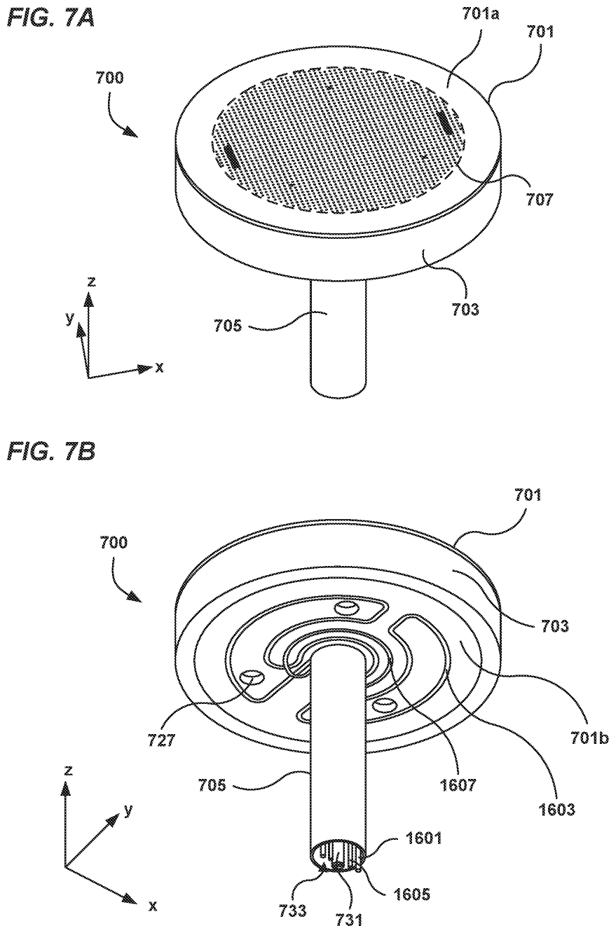

FIG. 3 is a flowchart of a process to mitigate asymmetric wafer bowing according to some embodiments. FIGS. 4A, 4B1, 482, and 4C schematically illustrate various stages of forming a stress compensation layer to mitigate asymmetric wafer bowing according to some embodiments. Process 300 may be performed in a different order and/or with different, fewer, or additional operations. The operations of process 300 will be described in association with the various stages of forming a stress compensation layer shown in FIGS. 4A to 4C. Further, the operations of process 300 may be performed using an apparatus for film deposition, such as an apparatus described in association with one or more of FIGS. 7A, 7B, 8, 9A-9C, 10, 11, 12A-12C, 13-16, 18A, 18B, 19, 20, 21A, 21B, and 22-30. In some implementations, the operations of process 300 may be implemented, at least in part, according to software stored in one or more non-transitory computer readable media.

At block 301, a substrate exhibiting asymmetric bowing may be caused, at least in part, to be loaded into a deposition apparatus, such as an apparatus configured to deposit material on a backside of the substrate. A stress profile acting on the substrate may include one or more compressive regions and/or one or more tensile regions non-uniformly applied to the substrate. In general, tensile stress applied across a substrate induces warpage having positive values and causes, at least in part, concave bending of the substrate. Compressive stress applied across a substrate induces warpage having negative values and causes, at least in part, convex bending of the substrate. The combination of various tensile and compressive stresses across the substrate may result in the substrate including a surface (e.g., median surface) deviating from a reference plane representing an otherwise planar configuration. In some instances, warpage of the substrate may exceed ±300 μm. Further, the asymmetric bowing may result in a saddle-shaped or reversed saddle-shaped substrate.

The substrate may be a silicon wafer, such as a 200-mm wafer, a 300-mm wafer, a 450-mm wafer, or the like, including one or more layers of material, such as dielectric, conducting, and/or semiconducting materials, deposited on a frontside of the substrate. Some of the one or more layers may be patterned. Non-limiting examples of layers include dielectric layers and conductive layers, such as silicon oxides, silicon nitrides, silicon carbides, metal oxides, metal nitrides, metal carbides, and metal layers. In some instances, the substrate itself may be patterned. For example, the substrate may include a 3D-NAND structure having one or more trenches formed (e.g., etched) in the substrate. Accordingly, the one or more compressive regions and the one or more tensile regions of the stress profile may be attributable to, for instance, the one or more layers of materials on the substrate, the one or more patterns in the one or more layers, the one or more trenches in the substrate, etc.

The substrate may exhibit warpage, such as warpage of about ±1000 μm. In some instances, the substrate may have warpage exceeding about ±300 μm. In some cases, the substrate has warpage greater than about ±300 μm and less than about ±1000 μm. The warpage may occur at one or more regions of the substrate. To this end, the warpage may have different values (or profiles) along an x-axis direction and a y-axis direction. The warpage may be a result of anisotropic stress distribution in the substrate.

As used herein, tensile regions create tensile stresses that induce warpage having positive values. Tensile regions cause concave bending of a substrate. As used herein, compressive regions create compressive stresses that induce warpage having negative values. Compressive regions cause convex bending of a substrate. The one or more compressive regions and the one or more tensile regions may be attributable to, for instance, the one or more layers of materials on the substrate, the one or more patterns in the one or more layers, the one or more trenches in the substrate, etc.

In some implementations, a center of the substrate has compressive stress and at least two opposing edges of the substrate have tensile stress. In some cases, a center of the substrate has tensile stress and at least two opposing edges of the substrate have compressive stress. A stress profile in the x-axis direction of the substrate may be described by a parabolic or other non-linear function. A stress profile in the y-axis direction of the substrate may be described by a parabolic or other non-linear function. To this end, the stress profile in the x-axis direction may be described by a polynomial function and the stress profile in the y-axis direction may be described by a polynomial function.

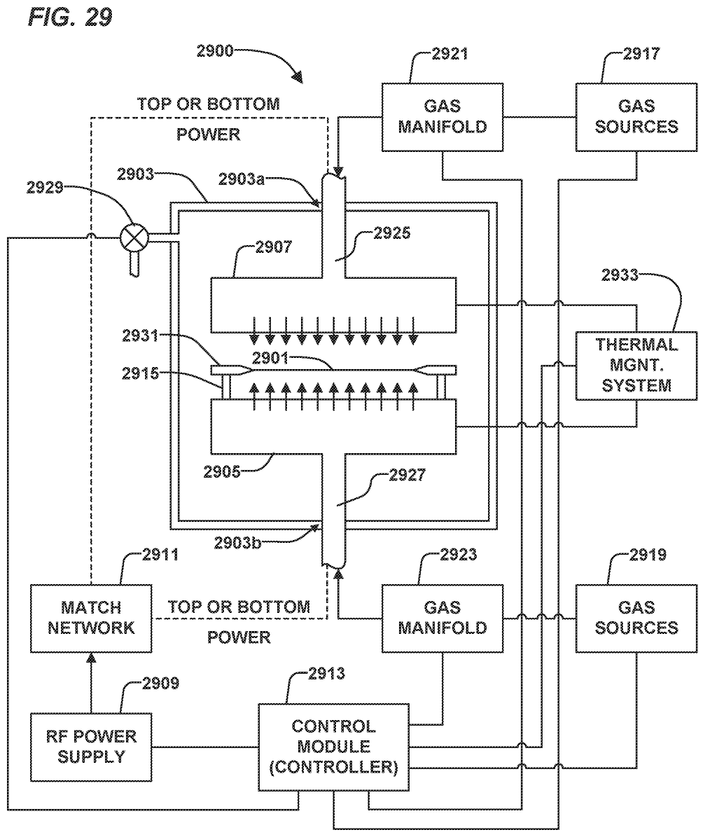

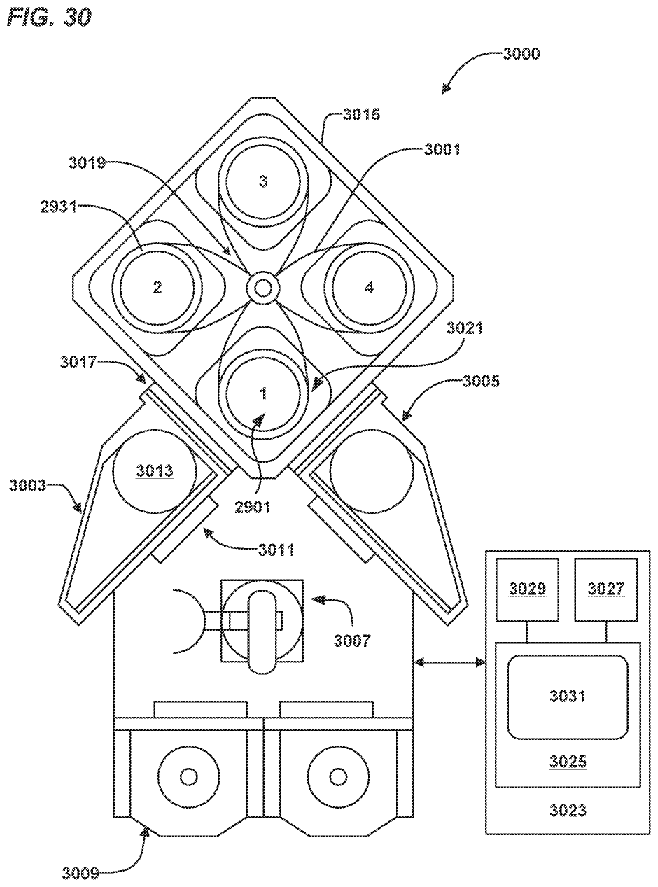

According to some embodiments, the substrate is caused, at least in part, to be provided in a process chamber (e.g., chamber 2903 of FIG. 29) for performing a deposition operation. The process chamber may be configured for backside and/or frontside deposition. In some implementations, backside deposition may be achieved by delivering process gases to a backside of the substrate from a bottom showerhead, e.g., a showerhead pedestal, of the process chamber. In some implementations, the backside of the substrate is not patterned. Showerheads generally described herein refer to showerhead pedestals for delivering gases to a backside of the substrate.

FIG. 4A schematically illustrates a cross-sectional view of a substrate exhibiting asymmetric bowing. Although not visibly shown, substrate 401 is bowed. Frontside 401a of substrate 401 may be patterned with structures leading to anisotropic stress distribution in substrate 401. The anisotropic stress distribution may be characterized by a polynomial function, such as a parabolic function in one or both of the x-axis and y-axis directions, where the x-axis and y-axis define a reference plane of substrate 401. Substrate 401 may be asymmetrically bowed. For example, substrate 401 may exhibit saddle-shaped bowing. In some cases, substrate 401 may have warpage greater than or equal to about +300 μm or less than or equal to about −300 μm in one or both of the x-axis and y-axis directions. Substrate 401 may be caused, at least in part, to be provided in a process chamber for deposition, such as a process chamber for backside deposition.

Adverting back to FIG. 3, at block 303, a first film is caused, at least in part, to be deposited on backside 401b of substrate 401 utilizing a first gas flow configuration from a showerhead pedestal. The first film is caused, at least in part, to have a first non-linear thickness profile on backside 401b of substrate 401.

According to one embodiment, the first film is a compressive film, which is a thin film having an intrinsic compressive stress. The compressive film may have an intrinsic compressive stress, such as a negative stress value of up to −4000 MPa. A thickness profile is presented along an axial direction (e.g., x-axis or y-axis direction) of the film. A non-linear thickness profile is characterized by any deviation from linearity of the film along the axial direction. The non-linear thickness profile may be characterized by a parabolic function or other polynomial function. For instance, the non-linear thickness profile may be a first parabolic-shaped profile that opens upwards or downwards. Where the first parabolic-shaped profile opens upwards, the compressive film is thicker at the edges of substrate 401 and tapers at the center of substrate 401. Where the first parabolic-shaped profile opens downwards, the compressive film is thicker at the center of the substrate 401 and tapers at the edges. Depending on the warpage of substrate 401, the compressive film may have a non-linear thickness profile in one or both of the x-axis and y-axis directions.

Depositing a compressive film according to a non-linear thickness profile may occur by controlling precursor and/or dilution gas concentration from a showerhead pedestal. The precursor and/or dilution gas concentration may be controlled to vary across backside 401b of substrate 401. For instance, thickness control may be achieved by controlling precursor and/or dilution gas concentration adjacent to backside 401b of substrate 401 during deposition. More precursor for depositing a compressive film is flowed in the compressive region(s). Less or no precursor for depositing the compressive film is flowed in the tensile region(s). Controlling precursor concentration to vary across backside 401b of substrate 401 may occur by influencing flow dynamics from the showerhead pedestal. Precursor and/or dilution gas concentration may vary along one or both of an x-axis and y-axis directions of substrate 401.

In some implementations, a compressive film may be a compressive silicon oxide, a compressive silicon nitride, a compressive silicon, or a compressive carbon film, but embodiments are not limited thereto. For instance, in some implementations, the compressive film is a compressive silicon oxide film or a compressive silicon nitride film. A selection of precursor gas, dilution gas, and process conditions can be used to tune the stress of the compressive film. In some implementations, the compressive film is deposited on backside 401b of substrate 401 using any suitable deposition technique, such as plasma enhanced chemical vapor deposition (PECVD), chemical vapor deposition (CVD), plasma enhanced atomic layer deposition (PEALD), or atomic layer deposition (ALD). For example, the compressive film may be caused, at least in part, to be deposited using PECVD.

As used herein, “silicon oxide” includes chemical compounds including silicon and oxygen atoms, including any and all stoichiometric possibilities for SiₓO_{y}, including integer values of x and y and non-integer values of x and y. Further, “silicon nitride” is referred to herein as including any and all stoichiometric possibilities for SiₓN_{y}, including integer values of x and y and non-integer values of x and y; for example, a ratio X:Y may be 3:4.

In some embodiments, a compressive silicon oxide film may be deposited using a mixture of a silicon-containing precursor and an oxygen-containing reactant. Examples of silicon-containing precursors include but are not limited to silanes and tetraethyl orthosilicate (TEOS). Examples of oxygen-containing reactants include but are not limited to oxygen and nitrous oxide. In PECVD, the silicon-containing precursor may react with the oxygen-containing reactant exposed to plasma to form the compressive silicon oxide film. An inert gas, such as helium, may be present.

According to some implementations, a compressive silicon nitride film may be deposited using a mixture of a silicon-containing precursor and a nitrogen-containing reactant. Examples of silicon-containing precursors include but are not limited to silanes and TEOS. Examples of nitrogen-containing reactants include but are not limited to nitrogen and ammonia. In PECVD, the silicon-containing precursor may react with the nitrogen-containing reactant exposed to plasma to form the compressive silicon nitride film. An inert gas, such as helium, may be present.

The selection of a silicon-containing precursor and reactants, as well as the plasma type (dual or single frequency) and process conditions may affect the stress of the film being deposited. In some implementations, a flow rate of the silicon-containing precursor relative to other gases flowed during deposition may tune the stress. For example, in deposition of compressive silicon nitride, increase in silane flow may decrease stress, making what would be a compressive silicon nitride film less compressive. Thus, in some implementations, increase in silane flow causes the deposited film to be less compressive, and, in some implementations, substrate temperature may be tuned to modulate stress in the compressive film. For example, higher temperatures may be used to achieve higher stress or increase a stability of the film being deposited. In some implementations, substrate temperature for deposition on backside 401b of substrate 401 is greater than or equal to about 200° C. and less than or equal to 650° C.

According to some embodiments, a compressive film may be used to compensate the one or more compressive regions of substrate 401. In some implementations, the thickness of the compressive film may vary based on location on substrate 401. For instance, the thickness of the compressive film at any given location may be greater than or equal to 0 nm and less than or equal to about 2000 nm. To this end, an average thickness of the compressive film may be about 1000 nm, but embodiments are not limited thereto. A thickness of the compressive film can affect wafer bow of the compressive film to compensate asymmetric bowing in substrate 401. Accordingly, a non-linear thickness profile in the compressive film achieves a desired wafer bow that compensates the one or more compressive regions of substrate 401.

FIG. 4B1 schematically illustrates a cross-sectional view of compressive film 403 having a parabolic thickness profile deposited on backside 401b of substrate 401. Compressive film 403 may be caused, at least in part, to be deposited by PECVD. Compressive film 403 may be a compressive silicon oxide film, a compressive silicon nitride film, a compressive silicon film, a compressive carbon film, or the like. Compressive film 403 may be thicker at a center of substrate 401 than at opposite edges of substrate 401. Although compressive film 403 is shown having a parabolic thickness profile, the thickness profile may match or substantially match a polynomial function, such as a second order or third order polynomial function. The parabolic thickness profile of compressive film 403 opens downwards. The parabolic thickness profile of compressive film 403 is depicted along an x-axis or y-axis direction.

According to some embodiments, the first film may be a tensile film having a second non-linear thickness profile on backside 401b of substrate 401. A tensile film refers to a thin film having an intrinsic tensile stress. The tensile film may have an intrinsic tensile stress, such as a positive stress value of up to +4000 MPa. The non-linear thickness profile may be characterized by a parabolic function or other polynomial function. Depending on the warpage in substrate 401, the tensile film may have a non-linear thickness profile in one or both of the x-axis and y-axis directions. In some implementations, the non-linear thickness profile may be a second parabolic-shaped profile that opens downwards or upwards. In some implementations, the second parabolic-shaped profile opens in a direction opposite the first parabolic-shaped profile.

Depositing a tensile film according to a non-linear thickness profile may occur by controlling precursor and/or dilution gas concentration from a showerhead pedestal. The precursor and/or dilution gas concentration may be controlled to vary across backside 401b of substrate 401. For instance, thickness control may be achieved by controlling precursor and/or dilution gas concentration adjacent to backside 401b of substrate 401 during deposition. More precursor for depositing the tensile film may be flowed in the tensile region(s), and less or no precursor for depositing the tensile film may be flowed in the compressive region(s). It is noted that controlling the precursor and/or dilution gas concentration to vary across backside 401b of substrate 401 may occur by influencing flow dynamics from the showerhead pedestal. To this end, the precursor and/or dilution gas concentration may vary along one or both of an x-axis and y-axis directions of the substrate 401.

In some implementations, the tensile film may be a tensile silicon oxide film, a tensile silicon nitride film, a tensile silicon film, a tensile carbon film, or the like. For instance, the tensile film may be a tensile silicon oxide film or a tensile silicon nitride film. Selection of precursors, dilatation gas, and process conditions can be used to tune the stress of the tensile film. In some implementations, the tensile film is deposited on backside 401b of substrate 401 using any suitable deposition technique, such as PECVD, CVD, PEALD, or ALD. For example, the tensile film may be caused, at least in part, to be deposited using PECVD.

In some implementations, a tensile silicon oxide film may be deposited using a mixture of a silicon-containing precursor and an oxygen-containing reactant. In PECVD, the silicon-containing precursor may react with the oxygen-containing reactant exposed to plasma to form the tensile silicon oxide film. An inert gas, such as helium, may be present.

A tensile silicon nitride film may be deposited, in some embodiments, using a mixture of a silicon-containing precursor and a nitrogen-containing reactant. In PECVD, the silicon-containing precursor may react with the nitrogen-containing reactant exposed to plasma to form the tensile silicon nitride film. An inert gas, such as helium, may be present.

Selection of a silicon-containing precursor and reactants, as well as the plasma type (dual or single frequency) and process conditions may affect the stress of the film being deposited. In some implementations, a flow rate of the silicon-containing precursor relative to other gases flowed during deposition may tune the stress. In some implementations, substrate temperature may be tuned to modulate stress in the tensile film. For example, higher temperatures may be used to achieve higher stress or increase a stability of the film being deposited. In some implementations, substrate temperature for deposition on backside 401b of substrate 401 is greater than or equal to about 200° C. and less than or equal to 650° C. Embodiments, however, are not limited thereto.

A tensile film may be used to compensate the one or more tensile regions of substrate 401. In some implementations, the thickness of the tensile film may vary based on location on substrate 401. For instance, the thickness of the tensile film at any given location may be greater than or equal to 0 nm and less than or equal to about 2000 nm. To this end, an average thickness of the tensile film may be about 1000 nm, but embodiments are not limited thereto. A thickness of the tensile film can affect wafer bow of the tensile film to compensate asymmetric bowing in substrate 401. Accordingly, a non-linear thickness profile in the tensile film achieves a desired wafer bow that compensates the one or more tensile regions of substrate 401.

FIG. 4B2 schematically illustrates a cross-sectional view of tensile film 405 having a parabolic thickness profile deposited on backside 401b of substrate 401. Tensile film 405 may be deposited by PECVD. Tensile film 405 may be a tensile silicon oxide film, a tensile silicon nitride film, a tensile silicon film, a tensile carbon film, or the like. In some cases, tensile film 405 may be thicker at opposite edges of substrate 401 than at a center of substrate 401. Although tensile film 405 is shown having a parabolic thickness profile, the thickness profile may match or substantially match a polynomial function, such as a second order or third order polynomial function. The parabolic thickness profile of tensile film 405 opens upwards. The parabolic thickness profile of tensile film 405 is depicted along an x-axis or y-axis direction.

Adverting back to FIG. 3, at block 305, substrate 401 including the first film formed on backside 401b may be optionally caused, at least in part, to be rotated by a predetermined amount before formation of another film on the first film. For instance, substrate 401 may be caused, at least in part, to be rotated greater than about 0° and less than about 180°, such as greater than about 30° and less than about 150°, e.g., greater than about 60° and less than about 120°, for instance, greater than about 80° and less than about 100°. In one embodiment, the substrate 401 may be caused, at least in part, to be rotated by or about 90°. It is noted, however, that any other suitable rotation may be utilized.

According to some embodiments, rotation of substrate 401 may be achieved manually or via one or more automated methods. For instance, substrate 401 may be removed from a processing chamber, rotated using an external aligner, and loaded back into the processing chamber. In some implementations, substrate 401 may be rotated in a processing chamber via rotation of a support structure, e.g., a susceptor, a showerhead pedestal, etc. It is also contemplated that substrate 401 may be rotated within a processing chamber via a spindex, spider forks, or any other suitable wafer handling robot.

At block 307, a second film is caused, at least in part, to be formed on the first film utilizing a second gas flow configuration different from the first gas flow configuration. In some implementations, the second gas flow configuration may be opposite the first gas flow configuration, as will become more apparent below. It is noted, however, that the first gas flow configuration may include one or more process gases being flowed in a first zone of a showerhead pedestal and one or more dilution gases being flowed in second and third zones of the showerhead pedestal that flank the first zone. In this manner, the second gas flow configuration may include one or more dilution gases being flowed in the first zone of the showerhead pedestal and one or more process gases being flowed in the second and third zones of the showerhead pedestal.

In some implementations, the second film may be configured to apply a second stress profile on substrate 401 that is different from a first stress profile applied by the first film. As such, deposition of the compressive film and the tensile film may occur interchangeably. That is, the compressive film may be deposited first followed by the tensile film, or the tensile film may be deposited first followed by the compressive film. In either case, the compressive film and the tensile film may be stacked and together achieve a flat or substantially flat surface forming a stress compensation layer. This flatness may result from the compressive film having a first non-linear thickness profile different from the tensile film having a second non-linear thickness profile. As a result, a stress compensation layer is formed on backside 401b of substrate 401 that is flat or substantially flat. In general, a stress compensation layer refers to the one or more films deposited on backside 401b of substrate 401 to correct or compensate wafer bowing in substrate 401. As used herein, the phrase “substantially flat” refers to wafer bowing or deviations from a flat reference plane that is less than about 100 μm. Having a flat or substantially flat stress compensation layer reduces IPD, where low IPD reduces overlay impact, ensures proper wafer chucking, and avoids defocusing.

According to various embodiments, a stress compensation layer is formed by stacking multiple films, e.g., the compressive film and the tensile film, with the stress compensation layer having a non-linear stress profile. The non-linear stress profile of the stress compensation layer may be largely characterized by a polynomial function, such as a parabolic function. In some implementations, additional films or layers may be stacked on the compressive film and tensile film for achieving a desired stress profile in the stress compensation layer. In some implementations, the stress compensation layer is removed. For instance, the stress compensation layer may be removed in further downstream processing operations.

FIG. 4C schematically illustrates a side view of stress compensation layer 407 formed on backside 401b of substrate 401. Stress compensation layer 407 includes compressive film 403 and tensile film 405 stacked on one another. By stacking compressive film 403 and tensile film 405, stress compensation layer 407 achieves a flat or substantially flat surface 407a. At least because compressive film 403 and tensile film 405 open in opposite directions, combining the thickness profiles of compressive film 403 and tensile film 405 forms a flat or substantially flat profile. Different regions of stress compensation layer 407 have different stress values to locally modulate stress. The stress variation in stress compensation layer 407 may be characterized by a polynomial function, such as a parabolic function. In various embodiments, stress compensation layer 407 mitigates asymmetric bowing in substrate 401. Prior to depositing stress compensation layer 407, substrate 401 may have warpage greater than or equal to about +300 μm or less than or equal to about −300 μm in one or both of the x-axis and y-axis directions. After depositing stress compensation layer 407, substrate 401 may have warpage between about −300 μm and about +300 μm in both the x-axis and the y-axis directions. In some implementations, substrate 401 may have warpage between about −100 μm and about +100 μm in both the x-axis and the y-axis directions after depositing stress compensation layer 407. It, however, is also contemplated that formation of stress compensation layer 407 on backside 401b of substrate 401 may eliminate (or substantially eliminate) warpage in one or more of the x-axis and the y-axis directions, e.g., reduce warpage in one or more of the x-axis and the y-axis directions to or about 0 μm.

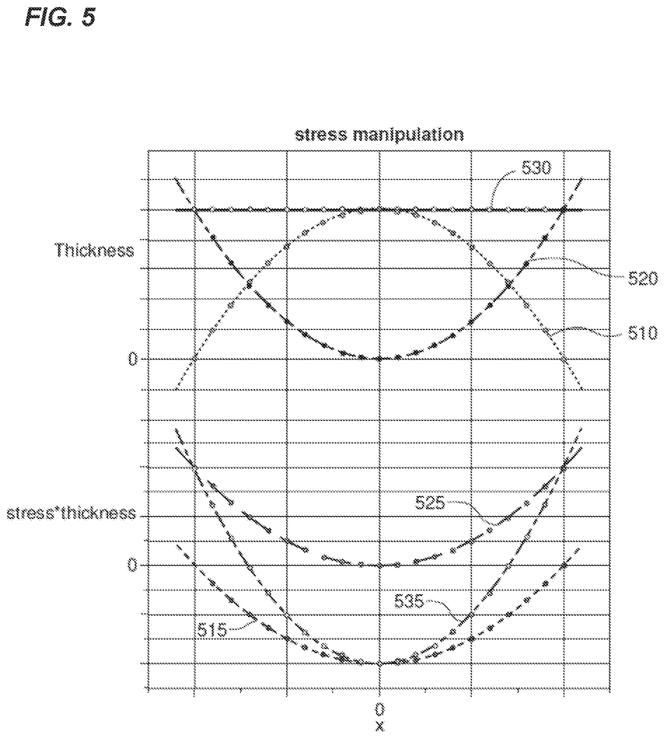

FIG. 5 is a graph illustrating a thickness profile and a stress profile for each of i) a compressive film, ii) a tensile film, and iii) a stress compensation layer combining the compressive film and the tensile film according to some embodiments.

As seen in FIG. 5, an upper portion of the graph provides a thickness profile as a function of position along the x-axis direction of a substrate. A lower portion of the graph provides a stress profile as a function of position along the x-axis direction of the substrate. Values in the stress profile are product values of stress multiplied by film thickness. The product value of stress multiplied by film thickness correlates with wafer bowing.

With respect to thickness profiles, first thickness profile 510 of a highly compressive film is depicted having a first parabolic-shaped curve. The thickness changes as a polynomial function such that the thickness in first thickness profile 510 increases parabolically towards the center of the substrate and parabolically decreases towards the edges of the substrate. Second thickness profile 520 of a highly tensile film is depicted as a second parabolic-shaped curve opening in a direction opposite the first parabolic-shaped curve. For instance, the thickness changes as a polynomial function such that the thickness in second thickness profile 520 increases parabolically towards the edges of the substrate and decreases parabolically towards the center of the substrate. A combination of the highly compressive film and the highly tensile film yield third thickness profile 530, which is flat or uniform across the x-axis direction of the substrate.

With continued reference to FIG. 5, first stress profile 515 of the highly compressive film is depicted as a third parabolic-shaped curve. As the thickness of the highly compressive film parabolically increases towards the center of the substrate, the stress parabolically decreases, and, thereby, becomes more negative. As the thickness of the highly compressive film parabolically decreases at the edges of the substrate, the stress parabolically becomes less negative and crosses the neutral axis. Second stress profile 525 of the highly tensile film is depicted as a fourth parabolic-shaped curve. As the thickness of the highly tensile film parabolically increases towards the edges of the substrate, the stress parabolically increases. As the thickness of the highly tensile film parabolically decreases towards the center of the substrate, the stress parabolically decreases and reaches the neutral axis. Third stress profile 535 is a result, e.g., total stress, applied by the combination of the highly compressive film and the highly tensile film. Towards the edges of the substrate, the stress of third stress profile 535 parabolically increases, whereas towards the center of the substrate, the stress parabolically becomes more negative.

According to various embodiments, a thickness profile of a compressive or tensile film is modulated by controlling a concentration of precursor and dilution gas adjacent to a substrate during material deposition. This concentration of precursor and dilution gas may be controlled by varying how much precursor and dilution gas is flowed from a gas distributor, such as a showerhead or showerhead pedestal, along at least one of the x-axis and y-axis directions. Structural components of the gas distributor may be configured to vary precursor and/or dilution gas distribution therefrom.

For descriptive and illustrative convenience, various embodiments will be described in association with showerhead pedestal implementations configured to modulate precursor and dilution gas distribution adjacent to a backside of a substrate. It will be appreciated, however, that some embodiments are equally applicable to showerhead implementations. The precursor and dilution gas distribution profile adjacent to the substrate may match (or substantially match) a desired thickness profile of material deposited on a substrate. The desired thickness profile may be described by a polynomial function, such as a second or higher order polynomial function. Various features and/or designs of showerhead pedestals for providing such tailored thickness profiles will be described in association with FIGS. 7A, 7B, 8, 9A-9C, 10, 11, 12A-12C, 13-16, 18A, 18B, 19, 20, 21A, 21B, and 22-27. In some implementations, precursor and dilution gas output may be divided into multiple zones in order to produce a particular thickness profile, as will become more apparent below.

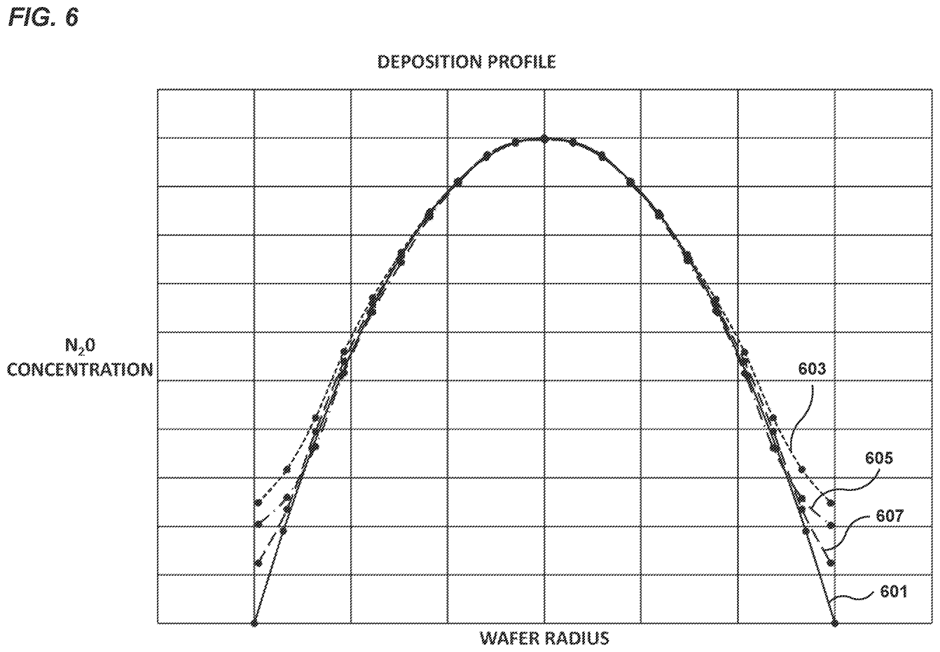

FIG. 6 is a graph comparing a desired profile and simulated profiles of reactant gas concentration flowing from variously configured gas distributors relative to a backside of a substrate according to some embodiments.

Referring to FIG. 6, reactant gas concentration from a showerhead pedestal is shown relative to locations on a gas output surface of the showerhead pedestal. The locations extend along a radial direction, which may extend in the x-axis or y-axis direction. Gas concentration of desired profile 601 follows a parabolic curve, with maximum concentration at a center of the showerhead pedestal and zero concentration at edges of the showerhead pedestal. Simulated profiles 603, 605, and 607 may not perfectly match desired profile 601, but at least one may substantially match desired profile 603 to achieve a sufficient deposition profile on a backside of a substrate. An observed or simulated curve may be considered to “substantially match” a parabolic or polynomial curve based upon fitting the observed curve to a polynomial function and evaluating the residuals therebetween to determine an acceptable level of correlation. For instance, when a statistical measure (such as R-square or an adjusted R-square) of the residuals reaches or exceeds a predetermined confidence level, the observed curve may be considered to “substantially match” the polynomial function. According to various embodiments, a gas distributor may be configured to output a gas concentration profile that substantially matches a desired parabolic or polynomial function. Simulated profiles 603, 605, and 607 will be described in more detail after various gas distribution features of some example showerhead pedestals are explored.

According to various embodiments, a gas distributor is used to distribute one or more gases, such as one or more process (or reactant) gases and/or one or more dilution gases, in an area adjacent to (e.g., over or under) a substrate in a process chamber. Generally, the gas distributor has a first surface and a second surface, each of which includes ports (or holes) that are fluidically interposed between an interior and an exterior of a main body of the gas distributor. The first surface defines a portion of the main body that, during a semiconductor process, faces towards a location in the process chamber where a wafer may be positioned during processing operations. The first surface includes a plurality of gas distribution ports, which are openings or apertures that permit gas to be delivered from within the gas distributor towards the substrate. The second surface defines a portion of the main body that faces away from the location in the process chamber where a wafer may be positioned during processing operations. In a plan view, each of the first and second surfaces may have a circular (or substantially circular) shape, but embodiments are not limited thereto. At least one third surface may extend between the first and second surfaces to enclose one or more volumes within the gas distributor. These one or more volumes may define portions of one or more gas distribution flow paths interior to the gas distributor and may be defined by one or more through-holes (or passages), cavities, recessed portions, and/or elongated holes in an interior of the gas distributor. One or more gas inlets may interface with the second surface to deliver one or more gases for distribution. In some embodiments, the one or more gas inlets are provided in a stem connected to the second surface. Gas within the one or more volumes exits the gas distributor by flowing out of the plurality of gas distribution ports. Some example architectures of a gas distributor are described in association with FIGS. 7A, 7B, 8, 9A-9C, 10, 11, 12A-12C, 13-16, 18A, 18B, 19, 20, 21A, 21B, and 22-27 in the context of various showerhead pedestal implementations. As previously mentioned, a showerhead pedestal is a showerhead configured to deliver gas(es) to a backside of a substrate.

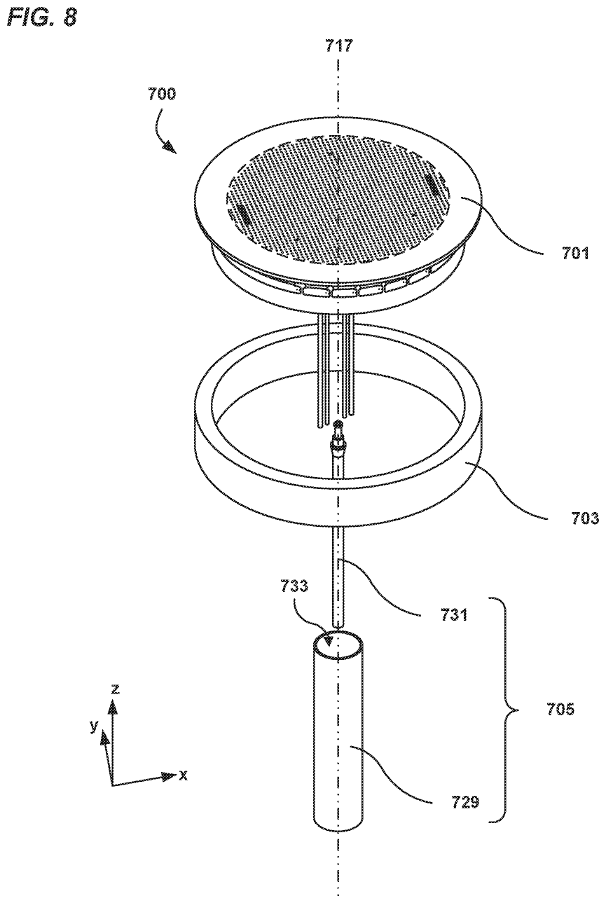

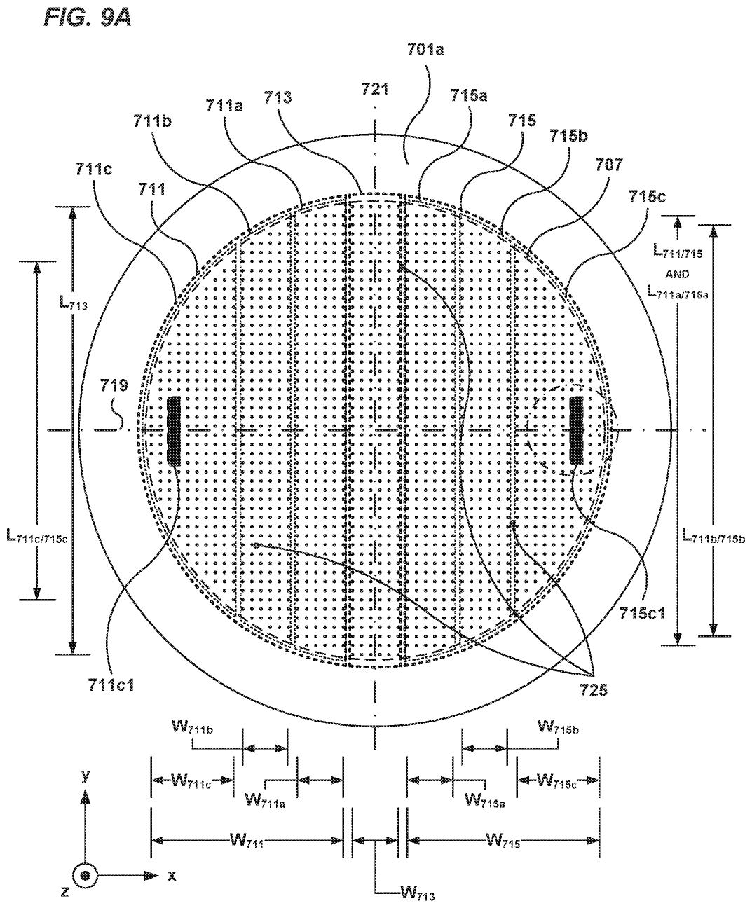

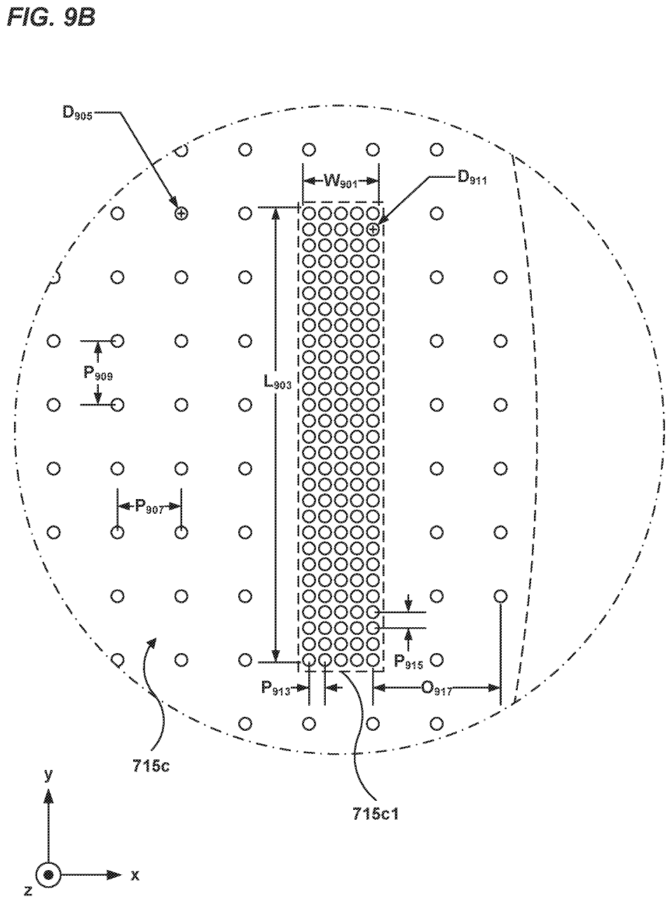

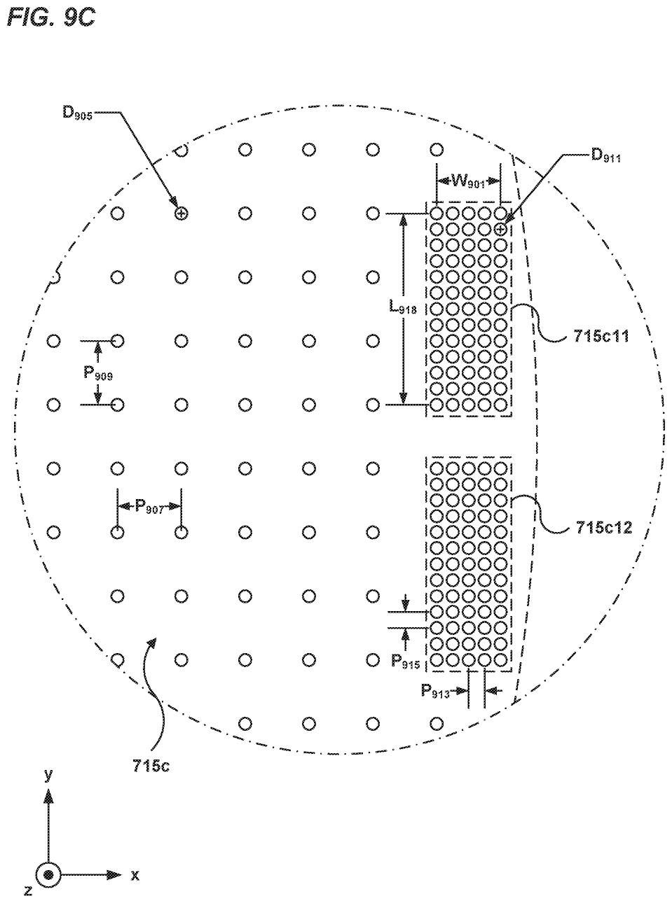

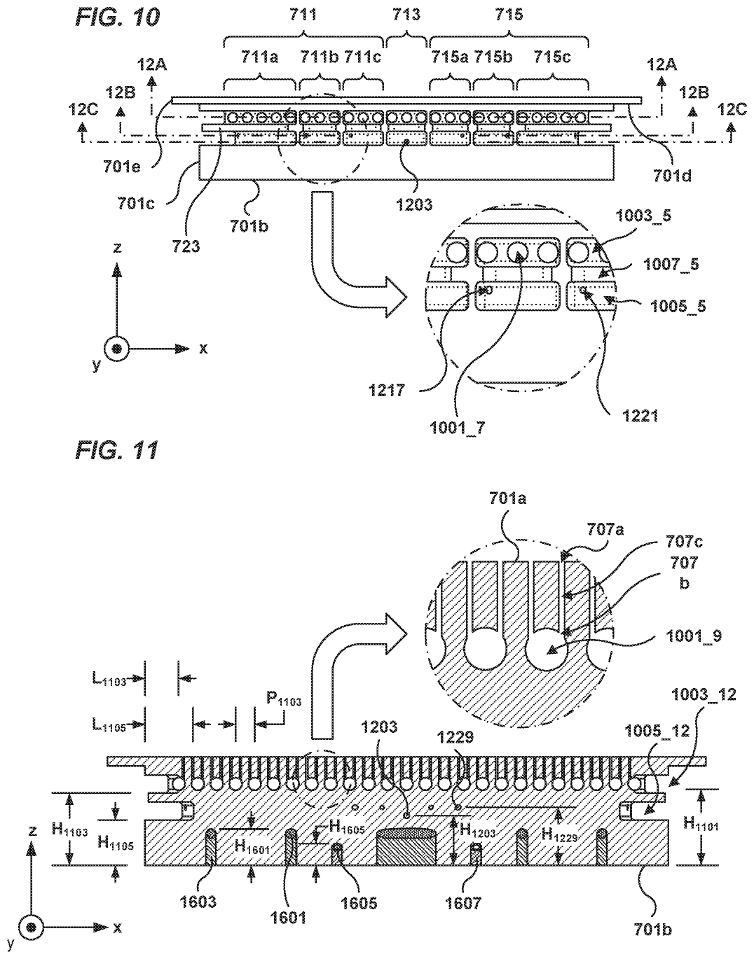

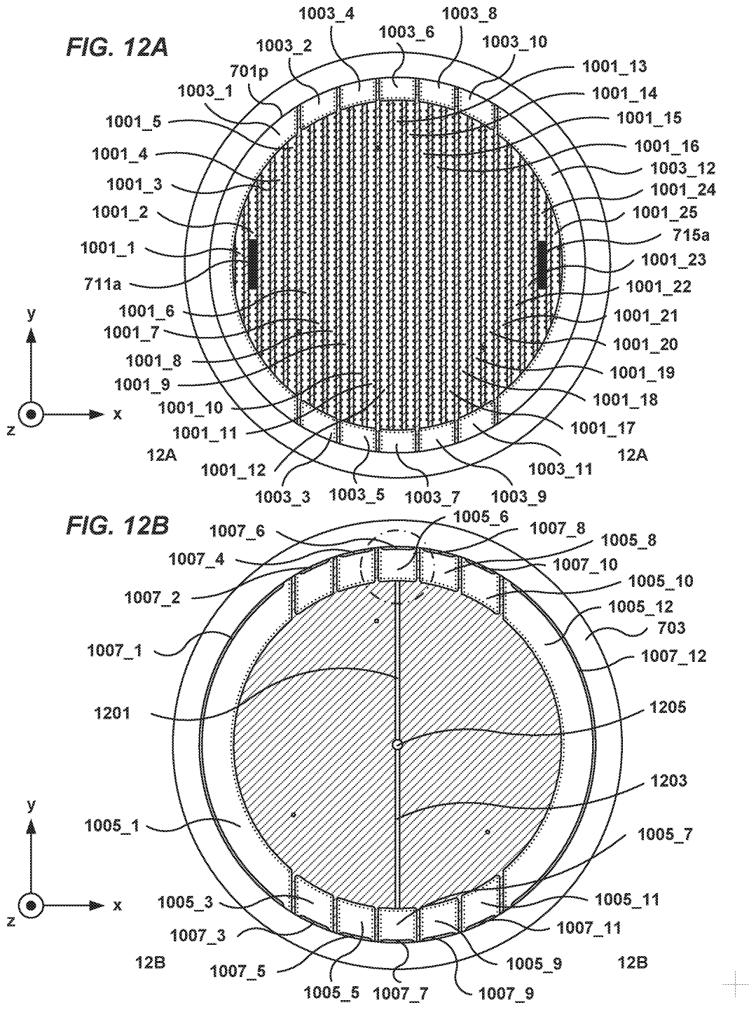

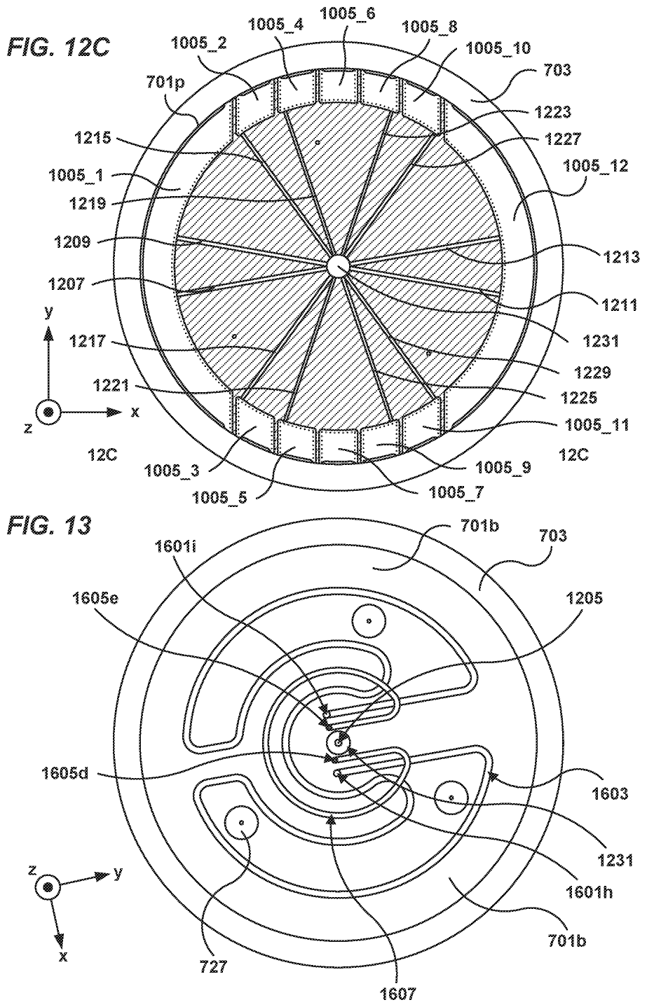

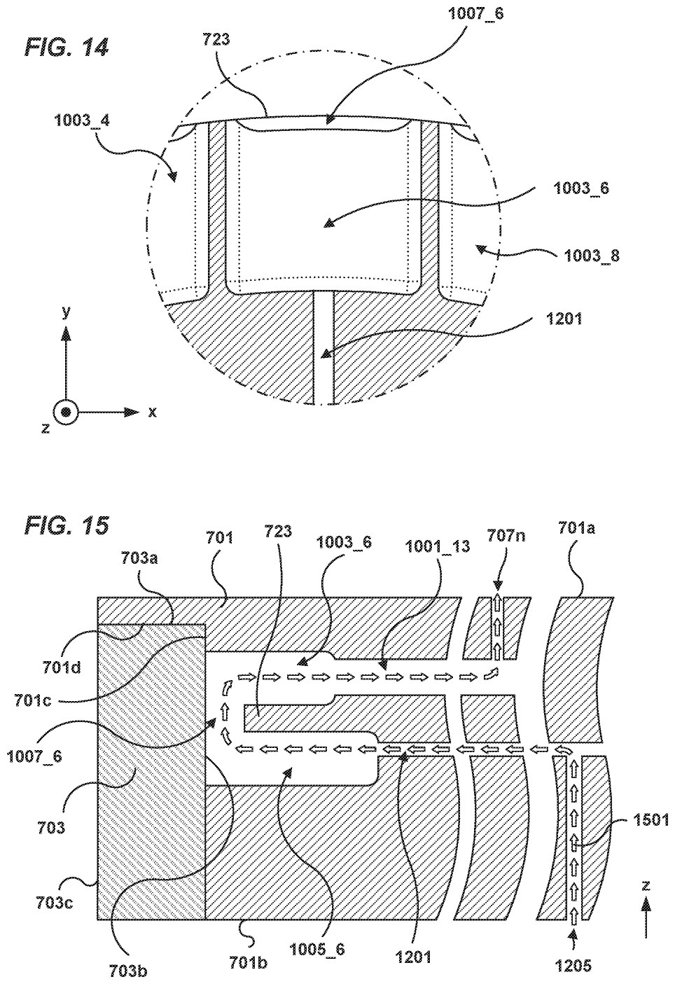

FIGS. 7A and 7B schematically illustrate perspective views of a gas distributor according to some embodiments. FIG. 8 schematically illustrates a partially exploded perspective view of the gas distributor of FIG. 7A according to some embodiments. FIG. 9A schematically illustrates a plan view of a first surface of the gas distributor of FIG. 7A according to some embodiments. FIG. 9B schematically illustrates an enlarged portion of FIG. 9A according to some embodiments. FIG. 9C schematically illustrates an enlarged portion of a first surface of another gas distributor according to some embodiments. FIG. 10 schematically illustrates a side view of a portion of the gas distributor according to some embodiments. FIG. 11 schematically illustrates a cross-sectional view of the portion of the gas distributor of FIG. 10 according to some embodiments. FIGS. 12A, 12B, and 12C schematically illustrate cross-sectional views of the gas distributor of FIGS. 7A and 10 respectively taken along sectional lines 12A-12A, 12B-12B, and 12C-12C according to some embodiments. FIG. 13 schematically illustrates a plan view of a second surface of the portion of the gas distributor of FIG. 10 according to some embodiments. FIG. 14 schematically illustrates an enlarged portion of FIG. 12B according to some embodiments. FIG. 15 schematically illustrates a gas distribution flow path through the gas distributor of FIG. 7A according to some embodiments.

Referring to FIGS. 7A-15, showerhead pedestal 700 includes main body 701, outer wall 703, and stem 705. Main body 701 has first surface 701a and second surface 701b opposing first surface 701a in a first direction, e.g., a direction extending parallel to the z-axis direction. Accordingly, a thickness of main body 701 is defined along the first direction. First surface 701a includes a plurality of gas distribution ports 707, which may be divided into a plurality of zones (or groups), such as zones 711, 713, and 715. Each of gas distribution ports 707 may include a corresponding outlet 707a, inlet 707b, and passageway 707c fluidically interposed between outlet 707a and inlet 707b. Zones 711, 713, and 715 may be adjacent to one another along a second direction (e.g., a direction extending parallel to the x-axis direction). Further, zones 711, 713, and 715 may longitudinally extend in a third direction (e.g., a direction extending parallel to the y-axis direction). In some embodiments, the longitudinal extension of zone 713 may separate zone 711 from zone 715. The first, second, and third directions cross one another, and, in some instances, the first, second, and third directions may be perpendicular to one another. Although three zones are depicted, embodiments are not limited thereto. For example, the gas distribution ports 707 may be divided into two zones or divided into four or more zones. Further, although the outlets 707a of gas distribution ports 707 are shown having circular cross-sectional areas, any suitable shape may be utilized, e.g., elliptical, polygonal, freeform, etc. For convenience, gas distribution ports 707 will, hereinafter, be assumed to have a circular cross-sectional area for outlets 707a, inlets 707b, and passageways 707c.

In addition, one or more of the zones of gas distribution ports 707 may include at least one sub-zone of gas distribution ports. For instance, zone 711 may include sub-zones 711a, 711b, 711c, and 711c1, and zone 715 may include sub-zones 715a, 715b, 715c, and 715c1, such as depicted in FIGS. 9A and 9B. It is noted that sub-zones 711c1 and 715c1 may form respective sub-portions of sub-zones 711c and 715c. As such, sub-zones 711c1 and 715c1 will, hereinafter, be referred to as sub-portions 711c1 and 715c1. In another embodiment, sub-zones 711c and 715c may each respectively include two or more sub-portions. For example, sub-zone 715c may include sub-portions 715c11 and 715c12, such as depicted in FIG. 9C. As will become more apparent below, each of the zones of gas distribution ports may have a same pattern (or spatial arrangement) of gas distribution ports, except the gas distribution ports disposed in a sub-portion of a sub-zone may have a different pattern, e.g., denser pattern. Embodiments, however, are not limited thereto.

According to one embodiment, not only does central axis 717 of showerhead pedestal 700 extend through a center of zone 713, but so do transverse axes 719 and 721 of first surface 701a. Transverse axis 719 may extend through the respective centers of zones 711 and 715, as well as the respective centers of sub-zones 711a, 711b, 711c, 715a, 715b, and 715c and sub-portions 711c1 and 715c1. In this manner, corresponding shapes of zones 711, 713, and 715 may have maximum widths W₇₁₁, W₇₁₃, and W₇₁₅, as well as maximum lengths L₇₁₁, L₇₁₃, and L₇₁₅. The corresponding shapes of sub-zones 711a, 711b, and 711c may have maximum widths W₇₁₁ₐ, W₇₁₁₆, and W_{711c}, as well as maximum lengths L₇₁₁ₐ, L_{711b}, and Lytic. The corresponding shapes of sub-portions 711c1 and 715c1 may have maximum widths W₉₀ and maximum lengths L₉₀₅. Length L₇₁₃ may be greater than each of lengths L₇₁₁, L₇₁₁ₐ, L_{711b}, L_{711c}, L₇₁₅, L₇₁₅ₐ, L_{715b}, L_{715c}, and L₉₀₃. Lengths L₇₁₁, L₇₁₁ₐ, L₇₁₅, and L₇₁₅ₐ may be equivalent and may be greater than each of lengths L_{711b}, L_{711c}, L_{715b}, L_{715c}, and L₉₀₃. Each of lengths L₇₁₅ₐ and L_{715b} may be greater than each of lengths L_{711c}, L_{715c}, and L₉₀₃, and each of lengths L_{711c} and L_{715c} may be greater than length L₉₀₃. Width W₉₀₁ may be smaller than each of widths W₇₁₃, W₇₁₁, W₇₁₁ₐ, W_{711b}, W_{711c}, W₇₁₅, W₇₁₅ₐ, W_{715b}, and W_{715c}. Widths Win and W₇₁₅ may be equivalent and may be greater than width W₇₁₃. Widths W_{711c} and W_{715c} may be equivalent and may be greater than each of widths W₇₁₃, W₇₁₁ₐ, W₇₁₁₆, W₇₁₅ₐ, and W_{715b}. In some embodiments, widths W₇₁₁ₐ, W₇₁₁₆, W₇₁₃, W₇₁₅ₐ, and W_{715b} may be equivalent.

In various implementations, the shape of zone 713 may exhibit symmetry about each of transverse axes 719 and 721. The shapes of zones 711 and 715, sub-zones 711a, 711b, 711c, 715a, 715b, and 715c, and sub-portions 711c1 and 715c1 may exhibit symmetry about transverse axis 719. To this end, the shape of zone 711 may have mirror symmetry with the shape of zone 715 about transverse axis 721. The shapes of sub-zones 711a, 711b, and 711c may have mirror symmetry with the respective shapes of sub-zones 715a, 715b, and 715c. To this end, the shapes of sub-portions 711c1 and 715c1 may be equivalent. Similarly, a pattern of gas distribution ports in zone 713 may have symmetry about each of transverse axes 719 and 721. The patterns of gas distribution ports in zones 711 and 715, sub-zones 711a, 711b, 711c, 715a, 715b, and 715c, and sub-portions 711c1 and 715c1 may have symmetry about transverse axis 719. In one or more embodiments, at least some of the gas distribution ports in zones 711, 713, and 715 may be distributed (or arranged) across a circular area. It is also noted that the combined patterns of gas distribution ports in zone 711, sub-zones 711a, 711b, and 711c, and sub-portion 711c1 and the combined patterns of gas distribution ports in zone 715, sub-zones 715a, 715b, 715c, and sub-portion 715c1 may exhibit mirror symmetry about a transverse axis (e.g., transverse axis 721), but not exhibit 3-fold or higher radial symmetry.

With reference to FIGS. 9A and 9B, each of the gas distribution ports in zones 711, 713, and 715 may have an equivalent (or substantially equivalent) diameter D₉₀₅ and may be spaced apart from one another by (or substantially by) pitch P₉₀₇ in the second direction and by (or substantially by) pitch P₉₀₉ in the third direction. Pitches Poor and P₉₀₉ may, in some embodiments, be equivalent. Further, each of the gas distribution ports in sub-portions 711c1 and 715c1 may have an equivalent (or substantially equivalent) diameter D₉₁₁ and may be spaced apart from one another by (or substantially by) pitch P₉₁₃ in the second direction and pitch P₉₁₅ in the third direction. Pitches P₉₁₃ and P₉₁₅ may, in some instances, be equivalent. In some embodiments, pitches P₉₁₃ and P₉₁₅ may be about one fourth the respective sizes of pitches P₉₀₇ and P₉₀₉. According to an embodiment, diameters D₉₀₅ and D₉₁₁ may be equivalent, pitch P₉₀₇ may be greater than pitch P₉₁₃, and pitch P₉₀₉ may be greater than pitch P₉₁₅. Further, in the second direction and relative to central axis 717, the outermost gas distribution ports of sub-portions 711c1 and 715c1 may be respectively inset from the outermost gas distribution ports of zones 711 and 715 by (or substantially by) distance O₉₁₇. In some instances, distance O₉₁₇ may be about 0, or, in other words, the outermost gas distribution ports of sub-portions 711c1 and 715c1 may be aligned or substantially aligned with the outermost gas distribution ports of zones 711 and 715, such as shown in FIG. 9C. In some embodiments, distance O₉₁₇ may be greater than or equal to about half as much as pitch P₉₀₇ and less than or equal to about three times as much as pitch P₉₀₇, e.g., distance O₉₁₇ may be twice as much as pitch P₉₀₇.

Although certain shapes, relative dimensions, and symmetries for the zones, sub-zones, and sub-portions of sub-zones have been described, embodiments are not limited thereto. For instance, the zones, sub-zones, and sub-portions of gas distribution ports 707 may have any suitable shape, relative dimensions, symmetries, and/or asymmetries that may enable a uniform (or substantially uniform) amount of gas flow within zone 713 and an increasing amount of gas flow in zones 711 and 715 as a distance from central axis 717 increases. Further, although certain patterns, pitches, diameters, offsets, symmetries, and/or asymmetries for the gas distribution ports in the zones, sub-zones, and sub-portions have been described, embodiments are not limited thereto. For example, the gas distribution ports in the zones, sub-zones, and sub-portions may have any suitable pattern, pitch, diameter, offset, symmetry, and/or asymmetry that may enable a uniform (or substantially uniform) amount of gas flow within (or across) zone 713 and an increasing amount of gas flow within (or across) zones 711 and 715 as a distance from central axis 717 increases. To this end, the gas distribution ports in a sub-zone or sub-portion of a sub-zone may have any suitable pattern, pitch, diameter, symmetry, and/or asymmetry that may enable an increasing amount of gas flow in (or across) zones 711 and 715 as a distance from central axis 717 increases. Further, the gas distribution ports in a sub-portion may have any suitable offset from an outermost gas distribution port of a corresponding zone including the sub-portion to enable gas flow at (or near) an edge portion of zones 711 and 715 to match (or substantially match) an intended gas flow profile across zones 711 and 715. Thus, the various gas flow profiles serve as a stand-in for all of the various structural ways the gas distribution ports 707 may be configured to arrive at an intended result.

For example, in some implementations, the gas distribution ports of zones 711 and 715 may have a variable pitch in at least one of the second and third directions. For instance, in zones 711 and 715, the pitch between at least some of the gas distribution ports in at least one of the second and third directions may decrease with increasing distance from central axis 717. For example, the pitch between the gas distribution ports in the second direction of sub-zone 711a may be larger than the pitch between the gas distribution ports in the second direction of sub-zone 711b, and the pitch between the gas distribution ports in the second direction of sub-zone 711b may be larger than the pitch between the gas distribution ports in the second direction of sub-zone 711c. The same may be true with respect to the relative pitches between the gas distribution ports in the second direction of sub-zones 715a, 715b, and 715c.

In some embodiments, the cross-sectional area of some of gas distribution ports 707 may be different. For example, in zones 711 and 715, the cross-sectional area of some of the gas distribution ports may increase with increasing distance from central axis 717, such as along at least one of the second and third directions. For example, the cross-sectional area of the gas distribution ports of sub-zone 711a may be smaller than the cross-sectional area of the gas distribution ports of sub-zone 711b, and the cross-sectional area of the gas distribution ports of sub-zone 711b may be smaller than the cross-sectional area of the gas distribution ports of sub-zone 711c. The same may be true with respect to the relative cross-sectional areas of the gas distribution ports of sub-zones 715a, 715b, and 715c.

According to various embodiments, gas distribution ports 707 may distribute one or more gases, such as one or more process (or reactant) gases and/or one or more dilution gases, in an area adjacent to a backside of a substrate in a process chamber. For instance, one or more first gases may be flowed from the gas distribution ports of zone 713 and one or more second gases may not only be flowed from the gas distribution ports of zones 711 and 715, but also from the gas distribution ports of sub-portions 711c1 and 715c1. As such, showerhead pedestal 700 may modulate a concentration of precursor gas delivered across a backside of a substrate by flowing one or more dilution gases in one of zone 713 or zones 711 and 715 and flowing one or more precursor gases in the other of zone 713 or zones 711 and 715. In this manner, a flow of dilution gas in certain zones or regions adjacent to the substrate will dilute or otherwise limit a concentration of precursor gas in the regions adjacent to the substrate that is flowed from certain other zones or regions adjacent to the substrate. Example dilution gases include, but are not limited to, various inert gases or gas species, such as nitrogen gas (N₂), helium (He), argon (Ar), neon (Ne), or xenon (Xe). Example process (or precursor) gases include, but are not limited to, silicon-containing gases, oxygen-containing gases, and nitrogen-containing gases (although generally not pure N₂).

In some implementations, the dilution gas is flowed through main body 701 to mix with precursor gas in an environment adjacent to the substrate. According to some embodiments, the dilution gas is flowed through main body 701 to mix with precursor gas in an environment adjacent to the substrate, but without mixing within main body 701 of showerhead pedestal 700. As such, main body 701 may include one or more first gas distribution flow paths to distribute the one or more first gases to the gas distribution ports of zone 713 and may include one or more second gas distribution flow paths to distribute the one or more second gases to not only the gas distribution ports of zones 711 and 715, but also to the gas distribution ports of sub-portions 711c1 and 715c1, if present. As will become more apparent below, each of the first and second gas distribution flow paths may establish a route through main body 701 starting at an inlet and ending at a gas distribution port. In some cases, one or more interior volumes may be defined between the inlet and the gas distribution port, such as by one or more elongated holes, blind cavities, recessed portions, and/or through-holes (or passages). Before describing each of these interior volumes, gas concentration profiles from various simulated examples of gas distribution port arrangements will be addressed.

Adverting back to FIG. 6 and with continued reference to FIGS. 9A to 9C, various configurations of gas distribution ports 707 of showerhead pedestal 700 may be utilized to tailor a gas concentration profile that matches or substantially matches a desired profile, such as a profile characterized by a parabolic or polynomial function. In a first simulated example of a showerhead pedestal similar to showerhead pedestal 700, gas distribution ports 707 were divided into multiple zones similar to zones 711, 713, and 715. In a second simulated example of another showerhead pedestal similar to showerhead pedestal 700, gas distribution ports 707 were not only divided into multiple zones similar to zones 711, 713, and 715, but some of the multiple zones (e.g., zones similar to 711 and 715) included a plurality of sub-portions. For instance, a zone similar to zone 715 included sub-portions similar to sub-portions 715c11 and 715c12 shown in FIG. 9C, and a zone similar to zone 711 exhibited symmetry with the zone similar to zone 715 about transverse axis 721. Comparable to as shown in FIG. 9C, each of the sub-portions similar to sub-portions 715c11 and 715c12 had a maximum width W₉₀₁ and a maximum length L₉₁₅. Further, the outermost gas distribution ports of the sub-portions similar to sub-portions 715c11 and 715c12 were, in the second simulated example, substantially aligned with the respective outermost gas distribution ports of the zone similar to zone 715, or, in other words, distance O₉₁₇ was (or was about) 0. In a third simulated example of a showerhead pedestal similar to showerhead pedestal 700, gas distribution ports 707 were not only divided into multiple zones similar to zones 711, 713, and 715, but each of the zones similar to zones 711 and 715 respectively included sub-portions similar to sub-portions 711c1 and 715c1 depicted in FIG. 9B. In this manner, the outermost gas distribution ports of the sub-portions similar to sub-portions 711c1 and 715c1 were inset from the respective outermost gas distribution ports of the zones similar to zones 711 and 715 by distance O₉₁₇, which was about twice as much as pitch P₉₀₇. The gas distribution flow paths within each simulated showerhead pedestal implementation were the same.

To determine a simulated gas concentration profile, a reactant gas (i.e., nitrous oxide (N₂O)) was simulated as being flowed from the zones similar to zone 713 and a dilution gas was simulated as being flowed from the zones similar to zones 711 and 715, as well as the sub-portions similar to sub-portions 711c1, 715c1, 715c11, and 715c12. In this manner, the dilution gas was simulated as being flowed from each of the example showerhead pedestals simultaneously with the reactant gases for depositing a compressive or tensile film on a substrate. It is noted that the dilution gas reduces (or dilutes) a concentration of the reactant gas adjacent to the substrate. As such, more dilution gas at a periphery of the substrate reduces a concentration of reactant gas at the periphery, and more dilution gas at a center of the substrate reduces a concentration of reactant gas at the center.

As can be appreciated from the results shown in FIG. 6, the configuration of the showerhead pedestal in association with the first simulated example yielded gas concentration profile 603 with the least amount of correlation with desired profile 601. The configuration of the showerhead pedestal in association with the third simulated example yielded gas concentration profile 607 with the most amount of correlation with desired profile 601. Also, the correlation of gas concentration profile 605 corresponding to the configuration of the showerhead pedestal in association with the second simulated example was between gas concentration profiles 603 and 607. As such, the utilization of one or more sub-portions in one or more primary zones or sub-zones may be utilized to further tailor a gas concentration profile such that the gas concentration profile more closely matches or substantially matches a desired profile, such as a profile characterized by a parabolic or polynomial function. Hereinafter, each of various interior volumes in showerhead pedestal 700 that are configured to supply gas to a gas distribution port among gas distribution ports 707 will be described in more detail.

With reference to FIGS. 10, 11, and 12A, gas distribution ports 707 are fluidically connected to a plurality of through-holes (or passages), such as through-holes 1001_1 to 1001_25. Through-holes 1001_1 to 1001_25 longitudinally extend in a fourth direction that crosses the first direction. The third and fourth directions may be equivalent. In some embodiments, through-holes 1001_1 to 1001_25 are gun-drilled through main body 701 at (or substantially at) distance H₁₁₀₁ from second surface 701b. Further, through-holes 1001_1 to 1001_25 may be spaced apart from one another in a fifth direction by (or substantially by) pitch P₁₁₀₃. The fifth direction crosses the first and fourth directions, and, in some implementations, may be equivalent to the second direction. Although twenty-five through-holes are shown as an example, embodiments are not limited thereto. A dichotomy, however, exists between the structural integrity of main body 701 and the gas distribution effect provided by a corresponding number of the through-holes. For instance, the structural integrity of main body 701 may decrease as the number of through-holes increases, but the gas distribution effect may increase.

According to various embodiments, groups of through-holes 1001_1 to 1001_25 may be configured to provide gas to the gas distribution ports of a corresponding zone, sub-zone, or sub-portion of a sub-zone. For instance, through-holes 1001_1 to 1001_11 may be fluidically connected to the gas distribution ports of zone 711, through-holes 1001_12 to 1001_14 may be fluidically connected to the gas distribution ports of zone 713, and through-holes 1001_15 to 1001_25 may be fluidically connected to the gas distribution ports of zone 715. To this end, through-holes 1001_1 to 1001_5 are fluidically connected to the gas distribution ports of sub-zone 711c and sub-portion 711c1, through-holes 1001_6 to 1001_8 are fluidically connected to the gas distribution ports of sub-zone 711b, and through-holes 1001_9 to 1001_11 are fluidically connected to the gas distribution ports of sub-zone 711a. Similarly, through-holes 1001_15 to 1001_17 are fluidically connected to the gas distribution ports of sub-zone 715a, through-holes 1001_18 to 1001_20 are fluidically connected to the gas distribution ports of sub-zone 715b, and through-holes 1001_21 to 1001_25 are fluidically connected to the gas distribution ports of sub-zone 715c and sub-portion 715c1.

Distal ends of through-holes 1001_1 to 1001_25 are fluidically connected to a first plurality of blind cavities, e.g., blind cavities 1003_1 to 1003_12. Each of blind cavities 1003_1 to 1003_12 extend into third surface 701c of main body 701 to (or substantially to) depth L₁₁₀₃ and at (or substantially at) distance H₁₁₀₈ from second surface 701b of main body 701. Third surface 701c of main body 701 may be connected to second surface 701b of main body 701 and extend towards first surface 701a of main body 701. Fourth surface 701d of main body 701 may connect third and fifth surfaces 701c and 701e of main body 701. Fifth surface 701e of main body 701 may connect first and fourth surfaces 701a and 701d of main body 701. In some embodiments, blind cavities 1003_1 to 1003_12 are arranged about perimeter 701p of main body 701. For instance, blind cavities 1003_1 to 1003_12 may be defined in third surface 701c of main body 701 and azimuthally arranged about central axis 717. Although twelve blind cavities at (or substantially at) distance H₁₁₀₈ from second surface 701b of main body 701 are shown as an example, embodiments are not limited thereto.

As seen in FIGS. 10 and 12A, each of blind cavities 1003_1 to 1003_12 may interface with one or more distal ends of at least one of through-holes 1001_1 to 1001_25. For instance, first and second distal ends of through-holes 1001_1 to 1001_5 may interface with blind cavity 1003_1, which may be fluidically connected to the gas distribution ports of sub-zone 711c and sub-portion 711c1. First distal ends of through-holes 1001_6 to 1001_8 may interface with blind cavity 1003_2 and second distal ends of through-holes 1001_6 to 1001_8 may interface with blind cavity 1003_3. In this manner, blind cavities 1003_2 and 1003_3 may be fluidically connected to the gas distribution ports of sub-zone 711b. First distal ends of through-holes 1001_9 to 1001_11 may interface with blind cavity 1003_4 and second distal ends of through-holes 1001_9 to 1001_11 may interface with blind cavity 1003_5. As such, blind cavities 1003_4 and 1003_5 may be fluidically connected to the gas distribution ports of sub-zone 711a. First distal ends of through-holes 1001_12 to 1001_14 may interface with blind cavity 1003_6 and second distal ends of through-holes 1001_12 to 1001_14 may interface with blind cavity 1003_7. In this manner, blind cavities 1003_6 and 1003_7 may be fluidically connected to the gas distribution ports of zone 713. First distal ends of through-holes 1001_15 to 1001_17 may interface with blind cavity 1003_8 and second distal ends of through-holes 1001_15 to 1001_17 may interface with blind cavity 1003_9. Thus, blind cavities 1003_8 and 1003_9 may be fluidically connected to the gas distribution ports of sub-zone 715a. First distal ends of through-holes 1001_18 to 1001_20 may interface with blind cavity 1003_10 and second distal ends of through-holes 1001_18 to 1001_20 may interface with blind cavity 1003_11. In this manner, blind cavities 1003_10 and 1003_11 may be fluidically connected to the gas distribution ports of sub-zone 715b. First and second distal ends of through-holes 1001_21 to 1001_25 may interface with blind cavity 1003_12, which may be fluidically connected to the gas distribution ports of sub-zone 715c and sub-portion 715c1. Accordingly, each of blind cavities 1003_2 to 1003_11 may interface with three through-holes among through-holes 1001_1 to 1001_25, whereas each of blind cavities 1003_1 and 1003_12 may interface with five through-holes among through-holes 1001_1 to 1001_25. Embodiments, however, are not limited to the above-noted configuration between blind cavities and through-holes. For instance, any given blind cavity among the first plurality of blind cavities may interface with one, two, or four through-holes, or may interface with more than five through-holes to enable a uniform (or substantially uniform) amount of gas flow within zone 713 and an increasing amount of gas flow in zones 711 and 715 as a distance from central axis 717 increases.

In some embodiments, respective sizes (e.g., at least one of openings, depths, widths, and volumes) of blind cavities 1003_1 and 1003_12 may be equivalent, and respective sizes of blind cavities 1003_2 to 1003_11 may be equivalent. To this end, each of the respective sizes of blind cavities 1003_1 and 1003_12 may be greater than each of the respective sizes of blind cavities 1003_2 to 1003_11. Embodiments, however, are not limited thereto.

Referring to FIGS. 10, 11, 12B, and 12C, blind cavities 1003_1 to 1003_12 are fluidically connected to a second plurality of blind cavities, e.g., blind cavities 1005_1 to 1005_12, via corresponding recessed portions, e.g., recessed portions 1007_1 to 1007_12, in septal wall 723 of main body 701. In this manner, blind cavity 1005_1 may be fluidically connected to the gas distribution ports of sub-zone 711c and sub-portion 711c1, blind cavities 1005_2 and 1005_3 may be fluidically connected to the gas distribution ports of sub-zone 711b, and blind cavities 1005_4 and 1005_5 may be fluidically connected to the gas distribution ports of sub-zone 711a. In a similar fashion, blind cavity 1005_12 may be fluidically connected to the gas distribution ports of sub-zone 715c and sub-portion 715c1, blind cavities 1005_10 and 1005_11 may be fluidically connected to the gas distribution ports of sub-zone 715b, and blind cavities 1005_8 and 1005_9 may be fluidically connected to the gas distribution ports of sub-zone 715a. Also, blind cavities 1005_6 and 1005_7 may be fluidically connected to the gas distribution ports of zone 713.

According to various embodiments, blind cavities 1005_1 to 1005_12 may extend into third surface 701c of main body 701 to (or substantially to) depth L₁₁₀₅ and at (or substantially at) distance H₁₁₀₅ from second surface 701b of main body 701 such that septal wall 723 separates blind cavities 1005_1 to 1005_12 from blind cavities 1003_1 to 1003_12 in the first direction. That said, recessed portions 1007_1 to 1007_12 in septal wall 723 form a plurality of gas flow channels fluidically connecting blind cavities 1005_1 to 1005_12 adjacent to corresponding ones of blind cavities 1003_1 to 1003_12 in the first direction. As such, blind cavities 1005_1 to 1005_12 may also be arranged about perimeter 701p of main body 701, such as azimuthally arranged about central axis 717. Although twelve blind cavities at (or substantially at) distance H₁₁₀₅ from second surface 701b of main body 701 are shown as an example, embodiments are not limited thereto.

In some embodiments, respective sizes (e.g., at least one of openings, depths, widths, and volumes) of blind cavities 1005_1 and 1005_12 may be equivalent, and respective sizes of blind cavities 1005_2 to 1005_11 may be equivalent. To this end, each of the respective sizes of blind cavities 1005_1 and 1005_12 may be greater than each of the respective sizes of blind cavities 1005_2 to 1005_11. Furthermore, in some implementations, respective sizes of blind cavities 1003_1, 1003_12, 1005_1, and 1005_12 may be equivalent, and respective sizes of blind cavities 1003_2 to 1003_11 and 1005_2 to 1005_11 may be equivalent. Embodiments, however, are not limited thereto.

As seen in FIGS. 7A, 7B, 12A-12C, and 15, outer wall 703 may be connected to main body 701 such that upper and inner surfaces 703a and 703b of outer wall 703 respectfully abut against fourth and third surfaces 701d and 701c of main body 701. In some implementations, a gap may exist between one or more of upper and inner surfaces 703a and 703b of outer wall 703 and fourth and third surfaces 701d and 701c of main body 701. It is noted, however, that a size of the gap(s) may be configured (or maintained within an acceptable tolerance) to produce a gas blocking effect preventing, minimizing, or at least reducing gas flow therethrough. For instance, a flow conductance associated with the gap(s) may be low enough relative to a flow conductance of a gas distribution flow path to discourage deviation from the gas distribution flow path. In this manner, blind cavities 1003_1 to 1003_12 and 1005_1 to 1005_12 may form corresponding interior volumes in showerhead pedestal 700. In some embodiments, depth L₁₁₀₅ of blind cavities 1005_1 to 1005_12 is greater than depth Los of blind cavities 1003_1 to 1003_12. This increase in depth L₁₁₀₅ as compared to depth L₁₁₀₃ may enable blind cavities 1005_1 to 1005_12 to function as gas intake plenums and blind cavities 1003_1 to 1003_12 to function as gas distribution plenums. For instance, initial gas flow into blind cavities 1005_1 to 1005_12 may help build a stabilized pressure of source gas within showerhead pedestal 700 that, in turn, can help build a stabilized pressure of distribution gas within blind cavities 1003_1 to 1003_12. The distribution gas in blind cavities 1003_1 to 1003_12 is made available to the distal ends of through-holes 1001_1 to 1001_25 for output via gas distribution ports 707. This configuration may not only allow gas distribution ports antipodally arranged about central axis 717 to exhibit similar gas flow, but also allow showerhead pedestal 700 to reach steady-state gas flow without expending too much extraneous reactant and dilution gas.

Referring to FIGS. 11 and 12B, blind cavity 1005_6 is fluidically connected to a distal end of elongated hole 1201, whereas blind cavity 1005_7 is fluidically connected to a distal end of elongated hole 1203. Proximate ends of elongated holes 1201 and 1203 are fluidically connected to first inlet 1205, which is configured to receive the one or more first gases into main body 701. Although illustrated as a single inlet, first inlet 1205 may be one or more first inlets 1205. In this manner, elongated holes 1201 and 1203 extend radially from central axis 717 in a first generally planar region of main body 701 at (or substantially at) distance H₁₂₀₃ from second surface 701b of main body 701. Accordingly, first inlet 1205 and elongated holes 1201 and 1203 may be fluidically connected to the gas distribution ports of zone 713.

As seen in FIGS. 11 and 12C, blind cavity 1005_1 is fluidically connected to distal ends of elongated holes 1207 and 1209, whereas blind cavity 1005_12 is fluidically connected to distal ends of elongated holes 1211 and 1213. Blind cavities 1005_2 to 1005_5 are fluidically connected to respective distal ends of elongated holes 1215, 1217, 1219, and 1221. Further, blind cavities 1005_8 to 1005_11 are fluidically connected to respective distal ends of elongated holes 1223, 1225, 1227, and 1229. Proximate ends of elongated holes 1207 to 1229 are fluidically connected to second inlet 1231, which is configured to receive the one or more second gases into main body 701. Although illustrated as one inlet, second inlet 1231 may be formed as one or more second inlets 1231. In this manner, elongated holes 1207 to 1229 extend radially from central axis 717 in a second generally planar region of main body 701 at (or substantially at) distance H₁₂₂₉ from second surface 701b of main body 701. Distance H₁₂₂₉ may be, in some implementations, greater than distance H₁₂₀₃. As such, elongated holes 1201 and 1203 may be closer to second surface 701b of main body 701 than elongated holes 1207 to 1229. It is also noted that distance H₁₁₀₁ may, in some embodiments, be greater than distance H₁₂₂₉. As such, each of elongated holes 1201, 1203, and 1207 to 1229 may be closer to second surface 701b of main body 701 than each of through-holes 1001_1 to 1001_25.

Based on the above-noted configuration, second inlet 1231 and elongated holes 1207 and 1209 may be fluidically connected to the gas distribution ports of sub-zone 711c and sub-portion 711c1, second inlet 1231 and elongated holes 1215 and 1217 may be fluidically connected to the gas distribution ports of sub-zone 711b, and second inlet 1231 and elongated holes 1219 and 1221 may be fluidically connected to the gas distribution ports of sub-zone 711a. In a similar fashion, second inlet 1231 and elongated holes 1211 and 1213 may be fluidically connected to the gas distribution ports of sub-zone 715c and sub-portion 715c1, second inlet 1231 and elongated holes 1227 and 1229 may be fluidically connected to the gas distribution ports of sub-zone 715b, and second inlet 1231 and elongated holes 1223 and 1225 may be fluidically connected to the gas distribution ports of sub-zone 715a.

Accordingly, in various implementations, each of blind cavities 1005_2 to 1005_11 may interface with one elongated hole among elongated holes 1201, 1203, and 1207 to 1229, and each of blind cavities 1005_1 and 1005_12 may interface with two elongated holes among elongated holes 1201, 1203, and 1207 to 1229. As such, blind cavities 1005_1 and 1005_12 may receive more of the one or more second gases via elongated holes 1207 to 1213 than is received by blind cavities 1005_2 to 1005_5 and 1005_8 to 1005_11 via elongated holes 1215 to 1229. In addition, blind cavities 1005_1 and 1005_12 may receive more of the one or more second gases via elongated holes 1207 to 1213 than the one or more first gases received by blind cavities 1005_6 and 1005_7 via elongated holes 1201 and 1203. Embodiments, however, are not limited thereto. For instance, any given blind cavity among the second plurality of blind cavities may interface with any suitable number of elongated holes, such as three, four, five, or six or more elongated holes to enable, for instance, a uniform (or substantially uniform) amount of gas flow within zone 713 and an increasing amount of gas flow in zones 711 and 715 as a distance from central axis 717 increases.

According to some embodiments, a cross-sectional area of each of elongated holes 1201, 1203, and 1207 to 1229 may be equivalent or substantially equivalent. However, in some implementations, at least one of elongated holes 1201, 1203, and 1207 to 1229 may have a different cross-sectional area than at least another one of elongated holes 1201, 1203, and 1207 to 1229. For instance, elongated holes 1201 and 1203 may have equivalent (or substantially equivalent) first cross-sectional areas, elongated holes 1207 to 1213 may have equivalent (or substantially equivalent) second cross-sectional areas, elongated holes 1215, 1217, 1227, and 1229 may have equivalent (or substantially equivalent) third cross-sectional areas, and elongated holes 1219 to 1225 may have equivalent (or substantially equivalent) fourth cross-sectional areas. The first and second cross-sectional areas may be equivalent or substantially equivalent. Each of the second cross-sectional areas may be greater than each of the third cross-sectional areas, and each of the third cross-sectional areas may be greater than each of the fourth cross-sectional areas.

Variance between the first to fourth cross-sectional areas may enable variable flow conductance within showerhead pedestal 700. For instance, decreasing the cross-sectional area of an elongated hole may decrease its flow conductance, and, thereby, increase the flow resistance experienced by gas(es) flowing therethrough. Increasing flow resistance, decreases throughput. The corollary is also true. In other words, increasing the cross-sectional area of an elongated hole may increase its flow conductance, and, thereby, decrease the flow resistance experienced by gas(es) traversing the elongated hole. Decreasing flow resistance, increases throughput. Thus, variance between the first to fourth cross-sectional areas of corresponding elongated holes 1201, 1203, and 1207 to 1229 may be utilized to vary the amount of gas(es) passed to blind cavities 1005_1 to 1005_12, and, to that end, output via the corresponding gas distribution ports fluidically connected thereto. Accordingly, the relative sizing of the first to fourth cross-sectional areas may be utilized to tailor a flow rate of gas supplied to different zones, sub-zones, and/or sub-portions of sub-zones of gas distribution ports. This, in turn, may be utilized to control precursor and dilution gas concentration proximate (or adjacent) to a substrate during one or more deposition operations utilizing showerhead pedestal 700.

For example, the relative cross-sectional areas of elongated holes 1201, 1203, and 1207 to 1213 may enable elongated holes 1201, 1203, and 1207 to 1213 to provide more gas(es) to blind cavities 1005_6, 1005_7, 1005_1, and 1005_12 than is provided to blind cavities 1005_2, 1005_3, 1005_10, and 1005_11 via elongated holes 1215, 1217, 1227, and 1229, which may have smaller relative cross-sectional areas than elongated holes 1201, 1203, and 1207 to 1213. In this manner, more gas(es) may be provided to the gas distribution ports fluidically connected to blind cavities 1005_6, 1005_7, 1005_1, and 1005_12 than the gas distribution ports fluidically connected to blind cavities 1005_6, 1005_7, 1005_1, and 1005_12. In addition, the relative cross-sectional areas of elongated holes 1215, 1217, 1227, and 1229 may enable elongated holes 1215, 1217, 1227, and 1229 to provide more gas(es) to blind cavities 1005_2, 1005_3, 1005_10, and 1005_11 than is provided to blind cavities 1005_4, 1005_5, 1005_8, and 1005_9 via elongated holes 1219, 1221, 1223, and 1225, which may have smaller relative cross-sectional areas than elongated holes 1215, 1217, 1227, and 1229. As such, more gas(es) may be provided to the gas distribution ports fluidically connected to blind cavities 1005_2, 1005_3, 1005_10, and 1005_11 than the gas distribution ports fluidically connected to blind cavities 1005_4, 1005_5, 1005_8, and 1005_9. Such a configuration may enable a uniform (or substantially uniform) output of the one or more first gases via zone 713, as well as enable a variable output of the one or more second gases via zones 711 and 715. For example, in zone 711, sub-zone 711c and sub-portion 711c1 may output more of the one or more second gases than sub-zone 711b, and sub-zone 711b may output more of the one or more second gases than sub-zone 711a. Similarly, in zone 715, sub-zone 715c and sub-portion 715c1 may output more of the one or more second gases than sub-zone 715b, and sub-zone 715b may output more of the one or more second gases than sub-zone 715a.

According to various embodiments, the one or more second gases may be supplied to the gas distribution ports of zone 711 via second inlet 1231, elongated holes 1207, 1209, and 1215 to 1221, blind cavities 1005_1 to 1005_5, recessed portions 1007_1 to 1007_5, blind cavities 1003_1 to 1003_5, and through-holes 1001_1 to 1001_11. Also, the one or more second gases may be supplied to the gas distribution ports of sub-portion 711c1 via second inlet 1231, elongated holes 1207 and 1209, blind cavity 1005_1, recessed portion 1007_1, blind cavity 1003_1, and through-hole 1001_2. Similarly, the one or more second gases may be supplied to the gas distribution ports of zone 715 via second inlet 1231, elongated holes 1211, 1213, and 1223 to 1229, blind cavities 1005_8 to 1005_12, recessed portions 1007_8 to 1007_12, blind cavities 1003_8 to 1003_8, and through-holes 1001_15 to 1001_25. To this end, the one or more second gases may be supplied to the gas distribution ports of sub-portion 715c1 via second inlet 1231, elongated holes 1211 and 1213, blind cavity 1005_12, recessed portion 1007_12, blind cavity 1003_12, and through-hole 1001_24. Also, the one or more first gases may be supplied to the gas distribution ports of zone 713 via first inlet 1205, elongated holes 1201 and 1203, blind cavities 1005_6 and 1005_7, recessed portions 1007_6 and 1007_7, blind cavities 1003_6 and 1003_7, and through-holes 1001_12 to 1001_14. Thus, at least some of the gas distribution flow paths formed between second inlet 1231 and the gas distribution ports of zones 711 and 715 may share a coincident portion, such as within a passageway of second inlet 1231. An illustrative gas distribution flow path will be described in more detail in association with FIG. 15.

Adverting to FIG. 15, gas distribution flow path 1501 may supply n^{th} gas distribution port 707n of zone 713 with the one or more first gases received at first inlet 1205. In this manner, gas distribution flow path 1501 may flow from first inlet 1205 to elongated hole 1201, which allows the one or more first gases of gas distribution flow path 1501 to flow into blind cavity 1005_6 that may function as an intake plenum. As pressure builds in blind cavity 1005_6, the one or more first gases of gas distribution flow path 1501 may flow through recessed portion 1007_6 and into blind cavity 1003_6, which may function as a gas distribution plenum. As pressure builds in blind cavity 1003_6, the one or more first gases of gas distribution flow path 1501 may be forced into through-hole 1001_13 and expelled via n^{th} gas distribution port 707n to an area proximate a substrate during a deposition operation. Each of the other gas distribution ports among gas distribution ports 707 may be similarly supplied with the one or more first gases or the one or more second gases via corresponding gas distribution flow paths routing between first inlet 1205 or second inlet 1231 and the corresponding one of the other gas distribution ports among gas distribution ports 707. It is noted that the gas distribution flow paths extending from first inlet 1205 may be fluidically isolated from the gas distribution flow paths extending from second inlet 1231 in an interior of showerhead pedestal 700.

It is noted that a ratio of precursor gas flow rate to inert gas flow rate through at least two zones may be controlled for adjusting a concentration of precursor gas adjacent to a substrate. For instance, where the ratio is higher, more precursor gas is flowed along an axial length of showerhead pedestal 700, such as along an x-axis or y-axis direction of showerhead pedestal 700. As a result, a concentration of precursor gas will taper less (e.g., have a shallower slope) along the axial length. When the ratio is lower, less precursor gas is flowed along the axial length of showerhead pedestal 700. As a result, the concentration of precursor gas will taper more (e.g., have a steeper slope) along the axial length. The ratio of the precursor gas flow rate to the inert gas flow rate may be controlled by adjusting the relationships between and amongst gas distribution ports 707, through-holes 1001_1 to 1001_25, blind cavities 1003_1 to 1003_12 and 1005_1 to 1005_12, recessed portions 1007_1 to 1007_12, and elongated holes 1201, 1203, and 1207 to 1229, as well as the relative sizing, amounts, arrangements, patterns, etc., of gas distribution ports 707, through-holes 1001_1 to 1001_25, blind cavities 1003_1 to 1003_12 and 1005_1 to 1005_12, recessed portions 1007_1 to 1007_12, and elongated holes 1201, 1203, and 1207 to 1229. In one embodiment, the gas distribution ports of zone 713 may provide a uniform (or substantially uniform) output (or gas flow profile) of one or more first gases, and the gas distribution ports of zones 711 and 715 along with the gas distribution ports of sub-portions 711c1 and 715c1 may provide a varying output (or gas flow profile) of one or more second gases that increases with increasing distance from central axis 717. As such, the various gas flow profiles mentioned herein may also serve as a stand-in for all of the various structural ways the internal volumes in showerhead pedestal 700 may be configured to arrive at an intended result. To the end, the various gas flow profiles mentioned herein may serve as a stand-in for all of the various structural ways the internal volumes in showerhead pedestal 700 may be configured and the various structural ways the gas distribution ports 707 may be configured to arrive at an intended result.

According to some embodiments, main body 701 is manufactured as a monolithic structure. For instance, one or more additive manufacturing techniques, such as direct laser metal sintering (or, if a ceramic showerhead is desired, a ceramic sintering process), may be utilized to form main body 701. It is also contemplated that main body 701 may be machined from solid stock, such as billet material. In other implementations, multiple plate structures may be stacked to form main body 701, and, to this end, one or more indexing pin or other similar features may be utilized to align the plate structures. In such instances, main body 701 may include one or more apertures extending through portions of the plate structures to allow the one or more indexing pins to align the plate structures with one another. Furthermore, in instances in which a multiple-plate structure is used, the various plates forming the overall structure of main body 701 may be brazed or diffusion bonded together along mating surfaces to prevent gas flow between contacting surfaces of the plates. It is also contemplated that, in some cases, main body 701 and outer wall 703 may be manufactured as a monolithic structure or formed as separate components that are coupled (or detachably coupled) together.

In some implementations, main body 701 may further include one or more apertures (such as apertures 725) in first surface 701a and extending through main body 701 in the first direction. In this manner, each aperture may interface with a corresponding blind bore (such as blind bore 727) in second surface 701b. The combination of the blind bores and apertures may be configured to interface with respective lift pins of a substrate processing system, e.g., substrate processing system 2900 of FIG. 29. For instance, the lift pins may be movably disposed through apertures 725 to enable a substrate supported over showerhead pedestal 700 to be raised or lowered respective to first surface 701a of main body 701.

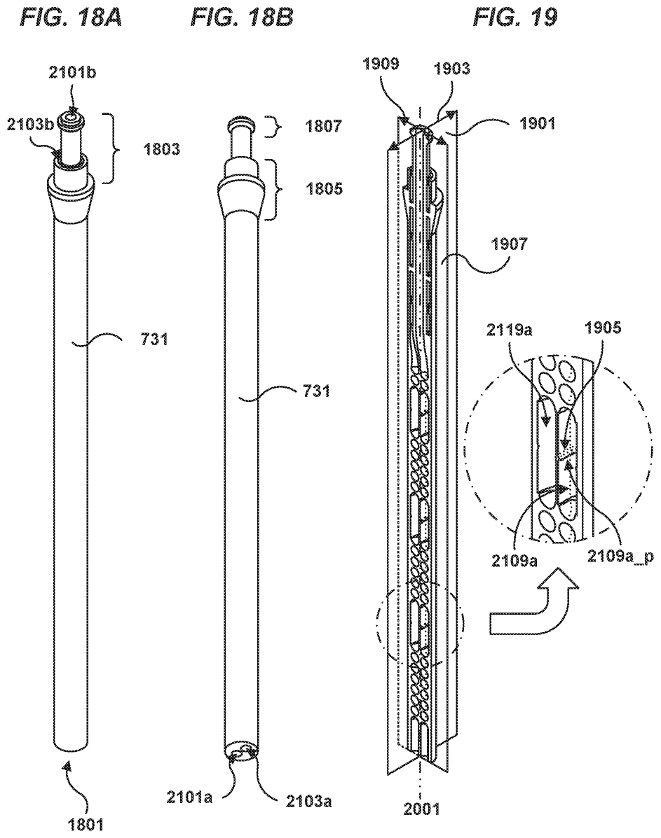

According to various embodiments, one or more gases are supplied to showerhead pedestal 700 in distinct or partially mixed states. As such, showerhead pedestal 700 may include one or more tortuous flow paths configured to induce turbulent flow as one or more received gases flow therethrough and prior to being received within an interior of main body 701. In some implementations, the tortuous flow paths are made part of stem 705. Such configuration can supplant (or be utilized in association with) conventional, external mixing assemblies to reduce tool costs or increase mixing effects. Some example tortuous flow paths are described in association with FIGS. 18A, 188, 19, 20, 21A, 21B, and 22-27.

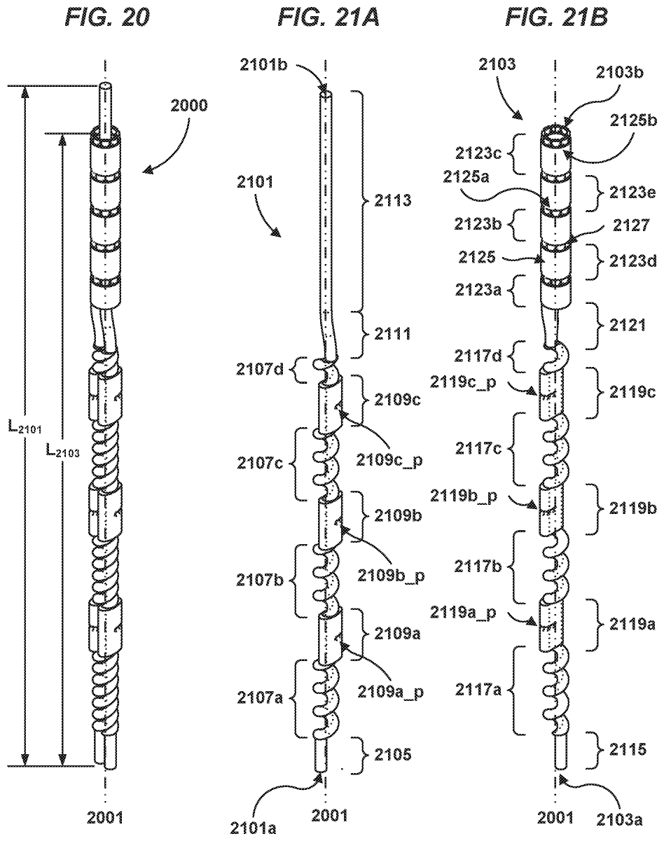

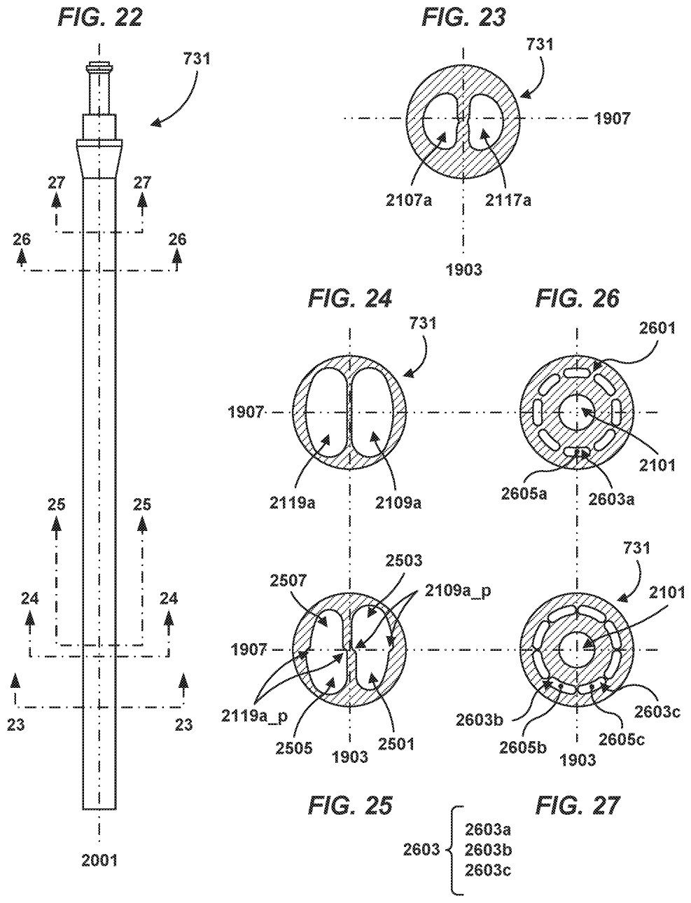

FIGS. 18A and 18B illustrate perspective views of a stem body of the gas distributor of FIG. 18 according to some embodiments. FIG. 19 schematically illustrates a cross-sectional view of the stem body of FIG. 18A according to some embodiments. FIGS. 20, 21A, and 21B schematically illustrate tortuous flow paths interior to the stem body of FIG. 18A according to some embodiments. FIG. 22 schematically illustrates a side view of the stem body of FIG. 18A according to some embodiments. FIGS. 23-27 schematically illustrate cross-sectional views of the stem body respectively taken along sectional lines 23-23, 24-24, 25-25, 26-26, and 27-27 according to some embodiments.

Referring to FIGS. 7B, 8, 12B, 12C, 18A, 18B, 19, 20, 21A, 21B, and 22-27, stem 705 includes outer wall 729 and stem body 731. Outer wall 729 may be connected to second surface 701b of main body 701, such as by being welded or otherwise affixed to second surface 701b of main body 701. Stem body 731 may include a plurality of interior flow paths 2000, such as first interior flow path 2101 and second interior flow path 2103, each interior flow path being configured to distinctly deliver one or more gases to main body 701. In some cases, first interior flow path 2101 is configured to deliver the one or more first gases in a mixed state to first inlet 1205, and second interior flow path 2103 is configured to deliver the one or more second gases in a mixed state to second inlet 1231. As such, stem body 731 has proximal end 1801 with a plurality of inlets (e.g., inlets 2101a and 2103a) and distal end 1803 opposing proximal end 1801. Distal end 1803 includes a plurality of outlets, such as first and second outlets 2101b and 2103b. In some implementations, stem body 731 includes first flanged portion 1805 configured to engage first inlet 1205 and second flanged portion 1807 configured to engage second inlet 1231.

According to various embodiments, each of the plurality of interior flow paths 2000 includes one or more structures configured to induce turbulent flow along longitudinal axis 2001 of stem body 731 in response to a flow of one or more gases along that interior flow path. Longitudinal axis 2001 may extend in the first direction and may be coincident with central axis 717. The one or more structures may include at least one of a linear extension, a helical path, a chamber, an impinging protrusion, an annular passageway, and a through-channel orifice.

In some implementations, first interior flow path 2101 may include inlet 2101a, first portion 2105, a plurality of second portions 2107a to 2107d, a plurality of third portions 2109a to 2109c, a fourth portion 2111, a fifth portion 2113, and first outlet 2101b. First portion 2105 linearly extends from inlet 2101a along longitudinal axis 2001. Second portions 2107a to 2107d may be fluidically connected to first portion 2105 and form corresponding helical paths about longitudinal axis 2001. Third portions 2109a to 2109c may be fluidically connected to first and second portions 2105 and 2107a to 2107d and form corresponding chambers extending along longitudinal axis 2001. Fifth portion 2113 may be fluidically connected to first, second, and third portions 2105, 2107a to 2107d, and 2109a to 2109c, and may linearly extend along longitudinal axis 2001, e.g., fifth portion 2113 may be coaxially aligned with longitudinal axis 2001. Fourth portion 2111 is fluidically interposed between fifth portion 2113 and each of second and third portions 2107a to 2107d and 2109a to 2109c.

According to some embodiments, second interior flow path 2103 may include inlet 2103a, first portion 2115, a plurality of second portions 2117a to 2117d, a plurality of third portions 2119a to 2119c, a fourth portion 2121, a plurality of fifth portions 2123a to 2123e, and second outlet 2103b. First portion 2115 linearly extends from inlet 2103a along longitudinal axis 2001. Second portions 2117a to 2117d may be fluidically connected to first portion 2115 and form corresponding helical paths about longitudinal axis 2001. Third portions 2119a to 2119c may be fluidically connected to first and second portions 2115 and 2117a to 2117d and form corresponding chambers extending along longitudinal axis 2001. Fifth portions 2123a to 2123e may be fluidically connected to each of first, second, and third portions 2115, 2117a to 2117d, and 2119a to 2119c, and may linearly extend along longitudinal axis 2001. For instance, fifth portions 2123a to 2123e may be coaxially aligned with longitudinal axis 2001. Fourth portion 2121 is fluidically interposed between each of fifth portions 2123a to 2123e and each of second and third portions 2117a to 2117d and 2119a to 2119c.

With reference to FIGS. 19, 20, 21A, and 21B, each of first portions 2105 and 2115 may extend parallel (or substantially parallel) to one another along longitudinal axis 2001. First portion 2105 of first interior flow path 2101 may be offset to a first side of median reference plane 1901 including longitudinal axis 2001 and first reference direction 1903. First portion 2115 of second interior flow path 2103 may be offset to a second side of median reference plane 1901 opposing the first side of median reference plane 1901. Similarly, each of third portions 2109a to 2109c and 2119a to 2119c may extend parallel (or substantially parallel) to one another along longitudinal axis 2001. Third portions 2109a to 2109c of first interior flow path 2101 may be offset to the second side of median reference plane 1901, whereas third portions 2119a to 2119c of second interior flow path 2103 may be offset to the first side of median reference plane 1901. Embodiments, however, are not limited thereto.

With continued reference to FIGS. 19, 20, 21A, and 21B, each of second portions 2107a to 2107d and 2117a to 2117d may form one or more revolutions about longitudinal axis 2001. For instance, each of second portions 2107a to 2107c and 2117a to 2117c may form three revolutions about longitudinal axis 2001, whereas each of second portions 2107d and 2117d may form approximately one revolution about longitudinal axis 2001. According to some implementations, the revolutions of second portions 2107a to 2107d of first interior flow path 2101 may be out of phase with the revolutions of second portions 2117a to 2117d of second interior flow path 2103 such that each second portion of second interior flow path 2103 is intertwined with a corresponding second portion of first interior flow path 2101. In some embodiments, second portion 2107d of first interior flow path 2101 may be closer to distal end 1803 than each of second portions 2107a to 2107c. Embodiments, however, are not limited to this configuration. For instance, first interior flow path 2101 may be spaced apart from second interior flow path 2103 such that second portions 2107a to 2107d and 2117a to 2117d do not intertwine with one another.

According to some implementations, second portions 2107a to 2107d of first interior flow path 2101 are alternately arranged with third portions 2109a to 2109c of first interior flow path 2101 along longitudinal axis 2001. Further, second portions 2117a to 2117d of second interior flow path 2103 are alternately arranged with third portions 2119a to 2119c of second interior flow path 2103 along longitudinal axis 2001. In this manner, first and second interior flow paths 2101 and 2103 may include four second portions and three third portions, but embodiments are not limited thereto. For instance, at least one of first and second interior flow paths 2101 and 2103 may include less than four second portions or may include five or more second portions. As another example, at least one of first and second interior flow paths 2101 and 2103 may include less than three third portions or may include four or more third portions. In other implementations, second portions 2107a to 2107d of first interior flow path 2101 may sequentially occur along longitudinal axis 2001 and then third portions 2109a to 2109c of first interior flow path 2101 may sequentially occur along longitudinal axis 2001, or vice versa. The same may be true of second interior flow path 2103.

Referring to FIGS. 19, 21A, and 21B, each of third portions 2109a to 2109c of first interior flow path 2101 includes at least one impinging protrusion constricting a passageway of first interior flow path 2101. For instance, each of third portions 2109a to 2109c includes a corresponding one of impinging protrusions 2109a_p to 2109c_p. In some embodiments, each of third portions 2119a to 2119c of second interior flow path 2103 includes at least one impinging protrusion constricting a passageway of second interior flow path 2103. For example, each of third portions 2119a to 2119c includes a corresponding one of impinging protrusions 2119a_p to 2119c_p. Embodiments, however, are not limited thereto. For instance, at least one of third portions 2109a to 2109c of first interior flow path 2101 and/or at least one of third portions 2119a to 2119c of second interior flow path 2103 may not include any impinging protrusions or may include two or more impinging protrusions.

In some embodiments, impinging protrusions 2109a_p to 2109c_p extend along respective circumferential sections of interior walls of third portions 2109a to 2109c of first interior flow path 2101, and impinging protrusions 2119a_p to 2119c_p extend along respective circumferential sections of interior walls of third portions 2119a to 2119c of second interior flow path 2103. For instance, impinging protrusion 2109a_p extends along circumferential section 1905 of an interior wall of third portion 2109a. According to some implementations, median reference plane 1907, which includes reference direction 1909 and longitudinal axis 2001, divides each of third portions 2109a to 2109c and 2119a to 2119c into corresponding divisions. For instance, as can be appreciated from FIGS. 19 and 25, third portion 2109a of first interior flow path 2101 may be divided into divisions 2501 and 2503 and third portion 2119a of second interior flow path 2103 may be divided into divisions 2505 and 2507. As such, impinging protrusions 2109a_p to 2109c_p of third portions 2109a to 2109c of first interior flow path 2101 may be disposed on a first side of median reference plane 1907, and impinging protrusions 2119a_p to 2119c_p of third portions 2119a to 2119c of second interior flow path 2103 may be disposed on a second side of median reference plane 1907 opposing the first side of median reference plane 1907. Embodiments, however, are not limited thereto.

Referring to FIGS. 20, 21A, and 21B, fifth portions 2123a to 2123e of second interior flow path 2103 may surround fifth portion 2113 of first interior flow path 2101. In some embodiments, fifth portion 2113 of first interior flow path 2101 is coaxially aligned with fifth portions 2123a to 2123e of second interior flow path 2103. Each of fifth portions 2123a to 2123e includes an annular passageway (e.g., annular passageway 2125) extending along longitudinal axis 2001. Each annular passageway has a first end (e.g., first end 2125a) closer to proximal end 1801 of stem body 731 and a second end (e.g., second end 2125b) closer to distal end 1803 of stem body 731. Each second end terminates at a corresponding impinging surface 2601 including a plurality of through-channel orifices 2603 extending along longitudinal axis 2001. Through-channel orifices 2603 may be circumferentially spaced apart from one another about longitudinal axis 2001. In some embodiments, through-channel orifices 2603 of adjacent fifth portions among fifth portions 2123a to 2123e of second interior flow path 2103 are offset from one another such that the central axes of through-channel orifices 2603 of a first one of the adjacent fifth portions are circumferentially offset from (e.g., incongruent with) the central axes of through-channel orifices 2603 of a second one of the adjacent fifth portions. For example, central axis 2605a of instance 2603a of through-channel orifices 2603 of the first one of the adjacent fifth portions may extend between respective central axes 2605b and 2605c of instances 2603b and 2603c of through-channel orifices 2603 of the second one of the adjacent fifth portions. It is noted that central axes 2605a to 2605c are depicted extending out of the page in FIGS. 26 and 27. Further, through-channel orifices 2603 of fifth portion 2123c may form multiple instances of second outlet 2103b of second interior flow path 2103. Each instance of second outlet 2103b of second interior flow path 2103 is distinct from first outlet 2101b of first interior flow path 2101.

Although second interior flow path 2103 is depicted as including five fifth portions, embodiments are not limited thereto. For instance, second interior flow path 2103 may include four or less fifth portions or may include six or more fifth portions. In some embodiments, length L₂₁₀₁ of first interior flow path 2101 is greater than length L₂₁₀₃ of second interior flow path 2103 such that a distal end of fifth portion 2113 of first interior flow path 2101 extends further from proximal end 1801 of stem body 731 than each of the distal ends of fifth portions 2123a to 2123e of second interior flow path 2103.

In some embodiments, stem body 731 is manufactured as a monolithic structure. For instance, one or more additive manufacturing techniques, such as direct laser metal sintering (or, if a ceramic stem body is desired, a ceramic sintering process), may be utilized to form stem body 731. In this manner, each of the plurality of interior flow paths 2000 defines a corresponding contiguous void in stem body 731. As such, each of the plurality of interior flow paths 2000 may be fluidically isolated from one another within stem body 731. For instance, first interior flow path 2101 may be fluidically isolated from second interior flow path 2103 within stem body 731 such that first interior flow path 2101 is configured to supply the one or more first gases to first inlet 1205 of main body 701 and second interior flow path 7203 is configured to supply the one or more second gases to second inlet 1231 of main body 701.

Although stem body 731 (and, thereby, stem 705) is shown including two interior flow paths, embodiments are not limited thereto. For instance, stem body 731 may include three or more interior flow paths. As another example, stem 705 may include multiple stem bodies 731 such that stem 705 includes greater than two interior flow paths.

It is also recognized that, in many semiconductor wafer processing applications, such as plasma-enhanced chemical vapor deposition (PECVD) processes, a deposition (or etching) process may be negatively affected by variations in process parameters, such as temperatures of a target wafer and/or a gas distributor, such as a showerhead pedestal. These variations may appear during process initiation (e.g., before reaching steady state), cleaning cycles, idling, etc. For example, when a reactor is initially turned on, it may take a relatively long time before the temperature of the gas distributor is stabilized. For instance, a gas distributor may be heated by radiation from the wafer (or another gas distributor) and/or by plasma, which may be introduced at some point during processing and can cause other temperature fluctuation. In addition, a gas distributor may lose heat to the process and dilution gases flowed through the gas distributor and due to radiation from its external surfaces. It is also noted that temperature variation may be caused by other more permanent changes in a system, such as drifts in surface emissivity of the gas distributor. Variable temperature may cause, at least in part, substantial deviation of a profile of a deposited film or etched feature from a target profile. Moreover, operating a gas distributor at relatively high temperature can not only shorten the operational life of the gas distributor, but may also cause, at least in part, particle contamination on a gas distribution surface of the gas distributor. Such build up may flake off and contaminate a structure being formed on (or in) a substrate via the gas distributor. As such, embodiments of showerhead pedestal 700 may incorporate heating and/or cooling channels (or loops) to enable active control of the temperature of showerhead pedestal 700. Some example structures and thermal management systems are described in association with FIGS. 78, 11, 13, 16, and 28.

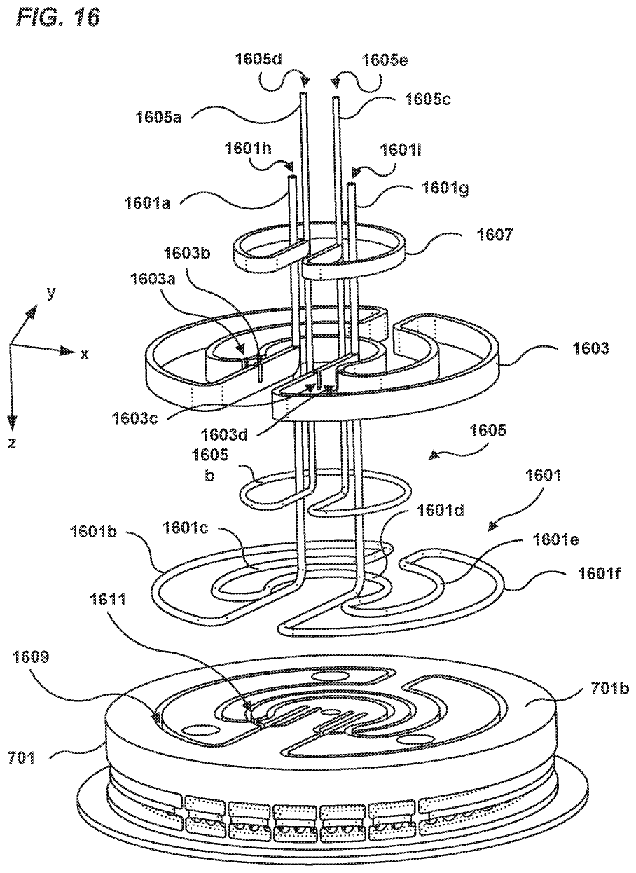

FIG. 16 schematically illustrates an exploded perspective view of various components of the gas distributor of FIG. 7B according to some embodiments.

Referring to FIGS. 7B, 11, 13, and 16, showerhead pedestal 700 may include one or more electrodes and/or heating elements (hereinafter, individually or collectively referred to as a heating loop) 1601, first cap (or cover) structure 1603, one or more cooling conduits and/or cooling elements (hereinafter, individually or collectively referred to as a cooling loop) 1605, and second cap (or cover) structure 1607. In various embodiments, main body 701 is formed of at least one conductive material, such as one or more metals and/or metal alloys. For example, main body 701 may be formed of an aluminum alloy, such as a precipitation-hardened aluminum alloy, e.g., AL6061. It is contemplated, however, that any other suitable material may be utilized. In this manner, main body 701 can be thermally conductive.

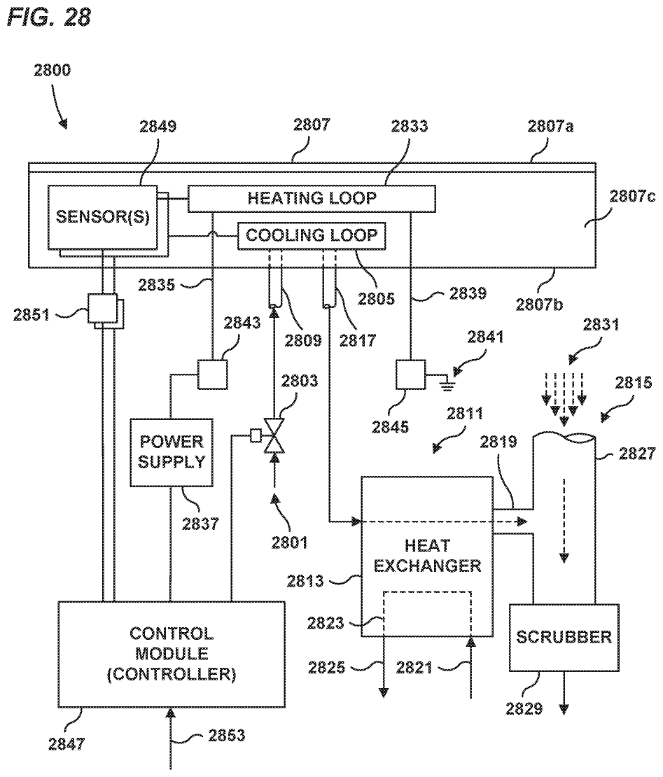

According to some embodiments, main body 701 includes heating loop 1601 coupled to a power source (e.g., power supply 2837 of FIG. 28) to controllably heat showerhead pedestal 700 and a substrate (such as wafer 2901 of FIG. 29) supported thereon. Heating loop 1601 may be resistively heated and thermally coupled to main body 701. Further, heating loop 1601 may be disposed on and/or at least partially embedded within main body 701. For example, main body 701 may include at least one slot (or groove) 1609 in second surface 701b that is configured to receive a lower section of heating loop 1601.

As depicted in FIGS. 7B, 11, 13, and 16, first portion 1601a of heating loop 1601 may enter main body 701 through hollow 733 in stem 705, bend to form second portion 1601b in a first outer peripheral region of main body 701, bend to form third portion 1601c in a first inner peripheral region of main body 701, bend to form fourth portion 1601d in an inner central region of main body 701, bend to form fifth portion 1601e in a second inner peripheral region of main body 701, bend to form a sixth portion 1601f in a second outer peripheral region of main body 701, and bend to form seventh portion 1601g exiting main body 701 through hollow 733 in stem 705. It is noted that first distal end 1601h of heating loop 1601 may be coupled to a power source and second distal end 1601i of heating loop 1601 may be coupled to a refence level, such as ground, floating ground, or another relatively low potential.

In some implementations, second and sixth portions 1601b and 1601f of heating loop 1601 may follow generally “C” shaped paths in corresponding outer peripheral regions of main body 701 that face one another. Third and fifth portions 1601c and 1601e of heating loop 1601 may also follow generally “C” shaped paths, but in corresponding inner peripheral regions of main body 701 that face one another. The corresponding outer peripheral regions of main body 701 may at least partially surround the corresponding inner peripheral regions of main body 701. Fourth portion 1601d of heating loop 1601 may follow a generally “Q” shaped path in the inner central region of main body 701 adjacent to distal end 1803 of stem body 731. In addition, the inner central region of main body 701 may be at least partially surrounded by the corresponding inner peripheral regions of main body 701. It is also noted that first and seventh portions 1601a and 1601g of heating loop 1601 may generally extend in an axial direction along central axis 717 of showerhead pedestal 700, whereas second to sixth portions 1601b to 1601f of heating loop 1601 may generally meander in a transverse plane at (or substantially at) a first distance H₁₆₀₁ (see FIG. 11) from second surface 701b of main body 701. It is contemplated, however, that any other suitable path through and/or about main body 701 may be utilized.

The lower section of heating loop 1601 may be encased in main body 701 between a bottom surface of slot 1609 and first cap structure 1603, which may be formed of at least one thermally conductive material, such as one or more metals and/or metal alloys. For instance, first cap structure 1603 may be made of the same material as main body 701, such as an aluminum alloy, e.g., a precipitation-hardened aluminum alloy, for example, AL6061. It is contemplated, however, that any other suitable material may be utilized. In this manner, first cap structure 1603 may be pressed into slot 1609 and welded (e.g., friction stir welded) to main body 701. Pressure applied to first cap structure 1603 during welding may, in some instances, partially deform heating loop 1601. The applied pressure and/or partial deformation of heating loop 1601 may, in some cases, ensure contact between one or more inner surfaces of slot 1609 and one or more outer surfaces of heating loop 1601. This may improve conductive heat transfer between heating loop 1601 and main body 701.

Showerhead pedestal 700 may also include cooling loop 1605 configured to maintain temperature control and compensate for temperature variations, which may occur before, during, and/or after substrate processing. For instance, cooling loop 1605 may be utilized to compensate for temperature increases or spikes when reactant gases are excited to generate plasma inside a process chamber (such as chamber 2903 of FIG. 29) and/or when the plasma is struck. To this end, cooling loop 1605 may form a conduit (or tube) through which a conductive cooling fluid, such as gas, may flow. In some embodiments, cooling loop 1605 may be formed of a thermally conductive material, such as one or more metals and/or metal alloys. For example, cooling loop 1605 may be formed of stainless steel, but embodiments are not limited thereto. It is noted, however, that the material selection for cooling loop 1605 should be considered in the context of the process/process recipe utilizing showerhead pedestal 700. In some cases, a wall temperature of cooling loop 1605 may reach about 350° C. to about 450° C., e.g., about 375° C. to about 425° C., e.g., about 400° C., and, as such, a material of cooling loop 1605 should be selected that can withstand anticipated/potential wall temperatures.

Cooling loop 1605 may have an outer diameter ranging from about 0.125″ to about 0.375″, e.g., from about 0.1875″ to about 0.3125.″ An inner diameter of cooling loop 1605 may range from about 0.069″ to about 0.319″, e.g., from about 0.132″ to about 0.215.″ In some embodiments, cooling loop 1605 may have an outer diameter of about 0.25″ and an inner diameter of about 0.18.″ Also, a length of cooling loop 1605 within main body 701 may be from about 10″ to about 26″, e.g., from about 13″ to about 23″, such as about 16″ to about 20.″ In some cases, the length of cooling loop 1605 within main body 701 may be about 18.″ Such a configuration may enable up to about 140 standard liters per minute (SLM) of clean dry air (CDA) with a very turbulent flow to pass through cooling loop 1605. For instance, the flow of CDA through cooling loop 1605 may exhibit a Reynolds number (Re) greater than 2000, such as about 2500 to about 35000. It is noted, however, that the sizes of the inner diameter, outer diameter, and length of cooling loop 1605 are not limited to these examples. For instance, the sizes the inner diameter, outer diameter, and the length of cooling loop 1605 may be dimensioned according to desired cooling metrics associated with one or more processes and/or process recipes to be performed in association with showerhead pedestal 700. The same is also true with respect to the flow rate of conductive cooling fluid through cooling loop 1605. To this end, the sizing of the inner diameter, outer diameter, and length of cooling loop 1605 may be chosen in consideration of material choice for cooling loop 1605 and main body 701, a length of cooling loop 1605 within main body 701, a path shape of cooling loop 1605 through main body 701, a type of conductive cooling fluid being utilized, a flow rate of the conductive cooling fluid, any imposed flow rate modulation techniques, etc.

According to various embodiments, cooling loop 1605 may be disposed on and/or at least partially embedded in main body 701. For example, main body 701 may include at least one slot (or groove) 1611 in second surface 701b that is configured to receive a lower section of cooling loop 1605. As depicted in FIGS. 7B, 11, 13, and 16, first portion 1605a of cooling loop 1605 may enter main body 701 through hollow 733 in stem 705, bend to form second portion 1605b in an outer central region of main body 701, and bend to form third portion 1605c exiting main body 701 through hollow 733 in stem 705. In some implementations, second portion 1605b of cooling loop 1605 may follow a generally circular-shaped path in the outer central region of main body 701 adjacent to the inner central region of main body 701 through which heating loop 1601 extends. To this end, the inner central region of main body 701 may, in a plan view, be disposed between the outer central region of main body 701 and a portion of main body 701 coupled to distal end 1803 of stem body 731. It is also noted that first and third portions 1605a and 1605c of cooling loop 1605 may generally extend in an axial direction along central axis 717 of showerhead pedestal 700, whereas second portion 1605b of cooling loop 1605 may generally meander in a transverse plane at (or substantially at) a second distance H₁₆₀₅ from second surface 701b of main body 701. In some embodiments, first distance H₁₆₀₁ may be greater than second distance H₁₆₀₅ such that cooling loop 1605 is disposed closer to second surface 701b of main body 701 than heating loop 1601. It is contemplated, however, that any other suitable path through and/or about main body 701 may be utilized.

The lower section of cooling loop 1605 may be encased in main body 701 between a bottom surface of slot 1611 and second cap structure 1607, which may be formed of at least one thermally conductive material, such as one or more metals and/or metal alloys. For instance, second cap structure 1607 may be made of the same material as main body 701, such as an aluminum alloy, e.g., a precipitation-hardened aluminum alloy, for example, AL6061. It is contemplated, however, that any other suitable material may be utilized. In this manner, second cap structure 1607 may be pressed into slot 1611 and welded (e.g., friction stir welded) to main body 701. Pressure applied to second cap structure 1607 during welding may, in some instances, partially deform cooling loop 1605. The applied pressure and/or partial deformation of cooling loop 1605 may, in some instances, ensure contact between one or more inner surfaces of slot 1611 and one or more outer surfaces of cooling loop 1605. This may improve conductive heat transfer between cooling loop 1605 and main body 701.

Although heating loop 1601 and cooling loop 1605 may generally meander in transverse planes at different distances from second surface 701b of main body 701, first and second cap structures 1603 and 1607 may cross paths. As such, at least one of first and second cap structures 1603 and 1607 may include one or more notched portions to allow passage of the other of the first and second cap structures 1603 and 1607. For instance, first cap structure 1603 may include notched portions 1603a to 1603d to allow passage of second cap structure 1607 therethrough.

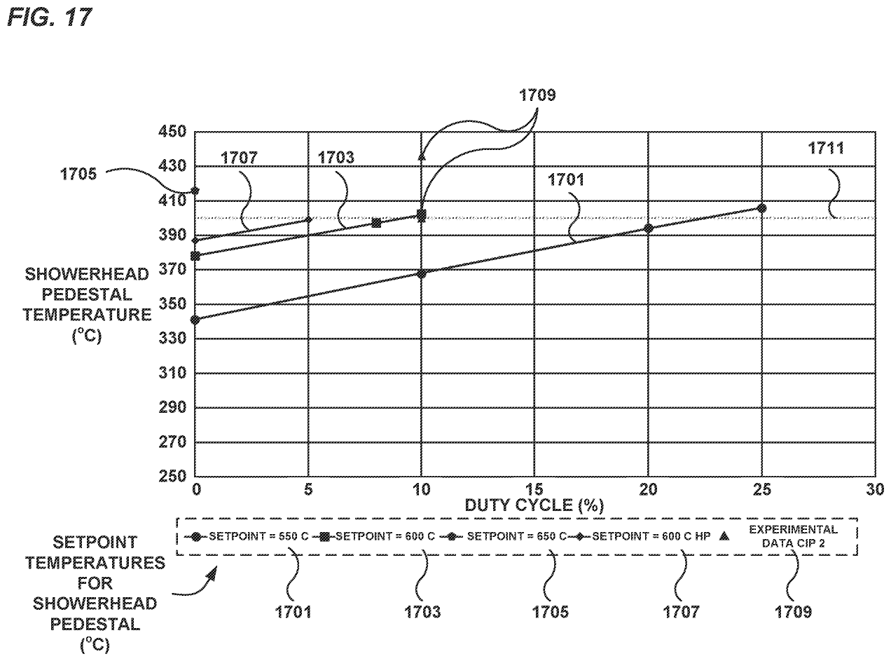

In some embodiments, one of first and second distal ends 1605d and 1605e of cooling loop 1605 provides an inlet for conductive cooling fluid at a first temperature (e.g., a low temperature) and the other of first and second distal ends 1605d and 1605e serves as an outlet for the conductive cooling fluid at a second temperature (e.g., a high temperature). For instance, assuming CDA is utilized as the conductive cooling fluid with a flow rate of about 100 SLM to about 140 SLM, the CDA may enter inlet 1605d at about 20° C. and exit outlet 1605e at about 275° C. Such metrics may enable about 620 watts (W) to about 775 W, such as 675 W to about 725 W, of thermal energy to be removed from showerhead pedestal 700 in association with a backside deposition process. This, in turn, can enable adequate temperature control over the setpoint temperature of showerhead pedestal 700 as demonstrated in FIG. 17.

FIG. 17 is a graph demonstrating simulated temperature control of a gas distributor at various setpoint temperatures and duty cycles according to some embodiments.

To determine an efficacy of cooling loop 1605, an implementation of showerhead pedestal 700 was simulated as part of a PECVD backside deposition process, but without the presence of a substrate. Main body 701, outer wall 703, stem 705, first and second cap structures 1603 and 1607, a processing chamber (e.g., chamber 2903 of FIG. 29), and a top plate of the processing chamber were each assumed as being formed of AL6061. An emissivity of main body 701, outer wall 703, stem 705, and first and second cap structures 1603 and 1607 was assumed to be 0.3, and an emissivity of the processing chamber and top plate was assumed to be 0.2. Cooling loop 1605 was assumed as being formed of stainless steel and CDA was utilized as the conductive cooling fluid. A showerhead opposing showerhead pedestal 700 in the processing chamber was assumed as being formed of an HA-12 variant of aluminum nitride provided by NGK Insulators, Ltd. As such, an emissivity of the showerhead was assumed to be 0.7. In addition, a top plate of the processing chamber was set at 75° C., the showerhead was set at 550° C., the processing chamber was set at 75° C., and an ambient environment of the processing chamber was set at 25° C. With these conditions, the efficacy of cooling loop 1605 flowing 140 SLM of CDA was determined in conjunction with various set point temperatures for showerhead pedestal 700, such as the setpoint temperatures shown in FIG. 17, e.g., 550° C., 600° C., 650° C., and 600° C. with a higher RF power being applied to generate plasma, and assuming various RF duty cycles, e.g., 0%, 5%, 7%, 10%, 20%, and 25%. For each of cases 1701 to 1705, power utilized to generate plasma was 530 W. For case 1707, the power utilized to generate plasma was 2750 W. As seen in FIG. 17, dashed line 1711 demonstrates that, under most of the assumed processing conditions and despite heat transfer to showerhead pedestal 700, simulated temperatures for showerhead pedestal 700 were capable of being maintained at approximately 400° C. In other words, cooling loop 1605 may, in some embodiments, enable adequate temperature control over the setpoint temperature of showerhead pedestal 700.

According to various embodiments, operation of heating loop 1601 and cooling loop 1605 may be controlled via a thermal management system. FIG. 28 schematically illustrates a thermal management system configured to control the temperature of a gas distributor according to some embodiments.

Referring to FIG. 28, cooling may be provided during operation of a substrate processing system (e.g., substrate processing system 2900 of FIG. 29) by thermal management system (or system) 2800 via introduction of a convective cooling fluid (e.g., atmospheric air, argon, helium, nitrogen, hydrogen, CDA, and/or the like) via inlet 2801 having valve 2803. In some embodiments, one or more additives may be introduced to the flow before and/or after valve 2803. The additive(s) may be utilized to increase the cooling efficiency and/or service life of cooling loop 2805, and, thereby, of gas distributor 2807. According to one or more implementations, the convective cooling fluid received at inlet 2801 is facilities-provided CDA at conventional facilities pressure. It will, therefore, be appreciated that different flow rates may be imposed based on different facilities pressures. For example, at a facilities pressure of about 80 psi, about 100 standard liters per minute (SLM) of CDA may be used. It is noted, however, that typical facilities pressure may range between about 80 psi to about 100 psi, and, therefore, flow rates through cooling loop 2805 may reach about 140 SLM. Hereinafter, it will be assumed that the convective cooling fluid is CDA.

Valve 2803 may be an electrically actuated valve capable of modulating the CDA flow through cooling loop 2805 to not only cool gas distributor 2807, but also to facilitate turbulent flow through cooling loop 2807. Such turbulent flow may increase thermal transfer from gas distributor 2807, and, thereby, the cooling efficiency of cooling loop 2805. For instance, modulation of the CDA flow may not only help impart a Reynolds number greater than or equal to about 2500, but it may compensate for some energy dissipation of the CDA flow along cooling loop 2805. It is also contemplated that the modulation of the CDA flow may be utilized to decrease a cooling effect of cooling loop 2805. In some implementations, valve 2803 may include one or more gas amplification features (e.g., constricting structures, such as Coanda profiles) that, in conjunction with a fluidic connection to a compressed gas source, can increase/decrease a flow rate (and, thereby, turbulence) of the CDA flow through cooling loop 2805. Additionally (or alternatively), one or more throttling valves, pendulum valves, and/or other flow modulators may be disposed upstream or downstream from cooling loop 2805 to increase/decrease turbulent flow through cooling loop 2805. Although valve 2803 has been described as an electrically actuated valve, it is contemplated that any other suitably controllable valve may be utilized as (or in addition to) valve 2803. An outlet of valve 2803 is fluidically connected to an input portion 2809 of cooling loop 2807.

System 2800 also includes outlet 2811 having heat exchanger 2813 and exhaust system 2815. A first inlet to heat exchanger 2813 is fluidically connected to an outlet portion 2817 of cooling loop 2807, and a first outlet of heat exchanger 2813 is fluidically connected to an input conduit 2819 of exhaust system 2815. Coolant, e.g., liquid coolant, for heat exchanger 2813 may enter heat exchanger 2813 at second inlet 2821, follow coolant path 2823, and exit heat exchanger 2813 via second outlet 2825. The coolant may be water or any other suitable coolant, e.g., Freon. In one embodiment, the coolant may be facilities provided water. After exiting heat exchanger 2813 via second outlet 2825, the coolant may be compressed and recirculated back into heat exchanger 2813 in a closed-loop coolant system, but embodiments are not limited thereto. In this manner, the CDA flow from outlet portion 2817 of cooling loop 2805 may be cooled via heat exchanger 2813 and expelled via exhaust system 2815.

Although heat exchanger 2813 has been described as a gas-to-liquid heat exchanger, embodiments are not limited thereto. For instance, heat exchanger 2813 may be configured as a gas-to-gas heat exchanger, and, in such cases, aspects of second inlet 2821 and second outlet 2825 of heat exchanger 2813 reconfigured to correspondingly interface with a suitable cooling source and a suitable effluent waste, recycling, and/or feedback system. When configured as a gas-to-gas heat exchanger, the cooling fluid may be, for instance, a source of atmospheric air, argon, helium, nitrogen, hydrogen, CDA, and/or the like.

According to some embodiments, the CDA output from heat exchanger 2813 may be about or slightly above ambient temperature and pressure. In some implementations, the temperature of the CDA output from heat exchanger 2813 may be greater than or equal to about 20° C. and less than or equal to about 65° C. It is noted, however, that heat exchanger 2813 may be configured to ensure that any residual heat in the effluent from cooling loop 2805 can be held within output-based environmental regulatory limits.

Conduit 2819 may be coupled to conduit 2827, which may be part of (or fluidically connected to) exhaust system 2815. In some implementations, exhaust system 2815 may be a scrubbed exhaust system. As such, any environmentally controlled components, constituents, by-products, etc., of the effluent from the first outlet of heat exchanger 2813 may be scrubbed via scrubber 2827 along with other effluents 2829 of the substrate processing system and/or ambient environment.

According to some embodiments, heating of gas distributor 2807 may be provided by thermal management system (or system) 2800 via heating loop 2833, such as heating loop 1601 described in association with FIG. 16. In this manner, input portion 2835 of heating loop 2833 may receive power from power supply 2837, and output portion 2839 of heating loop 2833 may be, for instance, coupled to reference level 2841, such as ground, floating ground, or another relatively low potential. In some instances, radio frequency (RF) power applied to gas distributor 2807 or at least one other component in a chamber (e.g., chamber 2903 of FIG. 29) of a semiconductor processing system may be above 100 W, sometimes above 1000 W. As such, an amplitude of RF voltages can exceed a kilovolt. Such RF power can affect operation of control and power circuits of heating loop 2833 without filtration or isolation. In some embodiments, an RF filter may be used to shunt the RF power away from control and power circuits. An RF filter may be a simple broad-band filter or a tuned-filter for predetermined RF frequencies used in a semiconductor processing system. An RF isolator, in contrast, eliminates direct electrical connection between any RF-coupled components and control and power circuits via, for example, an optical coupler or transformer. Thus, at least one RF component (e.g., filter, isolator, and/or the like) 2843 may be electrically connected between power supply 2837 and input portion 2835, and at least one RF component 2845 may be electrically connected between output portion 2839 and reference level 2841.

According to some embodiments, control module (or controller) 2847 is configured to operate various components of system 2800, such as valve 2803, power supply 2837, etc., to actively control the temperature of gas distributor 2807. In some embodiments, feedback information may be provided to controller 2847 from, for example, one or more sensors 2849, such as one or more thermocouples. Sensors 2849 may be configured to monitor temperature of at least one of cooling loop 2805, gas distributor 2807, and heating loop 2833. In some instances, at least one sensor 2849 may be configured to monitor temperature of conductive cooling fluid upstream, downstream, or within at least one portion of cooling loop 2805, such as input portion 2809, output portion 2817, etc. It is also contemplated that one or more of sensors 2849 may be thermally coupled to (or embedded within) various portions of gas distributor 2807, such as first surface 2807a, second surface 2807b, and body portion 2807c. As with power supply 2837 and reference level 2841, one or more RF components 2851 may be electrically connected between sensors 2849 and controller 2847 to mitigate or eliminate interference in signals from sensors 2849.

Controller 2847 may, in some implementations, receive feed forward information 2853 from at least one other controller (e.g., control module 2913 of FIG. 29, system controller 3023 of FIG. 30, etc.) of another system or tool and/or sensor associated with at least one other gas distributor of a multi-station processing tool (e.g., multi-station processing tool 3000). In this manner, controller 2847 may utilize feed forward information 2853 to control the temperature of gas distributor 2807 in anticipation of a processing event. For example, controller 2847 may increase power input to heating loop 2833 in anticipation of a cooling event, e.g., chamber purge event, or decrease power input to heating loop 2833 in anticipation of a heating event, such as before or during process gas activation. Similarly, controller 2847 may increase cooling input to cooling loop 2805 by increasing conductive fluid flow in anticipation of a heating event or decrease the cooling input by decreasing conductive fluid flow in anticipation of a cooling event. As such, different combinations of various heating and/or cooling inputs may be used to accurately control the temperature of gas distributor 2807, whether proactively or reactively. Furthermore, one or more features or functions of controller 2847 may be shared with, assumed by, or negotiated amongst at least one other controller (e.g., control module 2913 of FIG. 29, system controller 3023 of FIG. 30, etc.).

FIG. 29 schematically illustrates substrate processing system (or system) 2900, which may be used to process wafer 2901 according to some embodiments.

System 2900 includes chamber 2903. A center column is configured to support a pedestal when a surface of wafer 2901 is being processed, e.g., a film is being formed on the surface of wafer 2901. The pedestal, in accordance with some embodiments, may be referred to as showerhead pedestal 2905. Showerhead 2907 is disposed over showerhead pedestal 2905. In an embodiment, showerhead 2907 is electrically coupled to power supply 2909 via match network 2911. As such, power supply 2909 may be controlled by control module 2913, e.g., a controller. In some embodiments, power may be provided to showerhead pedestal 2905 instead of (or in addition to) showerhead 2907. Control module 2913 is configured to operate system 2900 by executing one or more sequences of one or more instructions defining at least one process recipe. Depending on whether a frontside or backside of wafer 2901 is to receive a deposited film, control module 2913 may set various operational inputs for defining a process recipe, such as power levels, timing parameters, process gases, mechanical movement of wafer 2901, height of wafer 2901 from showerhead pedestal 2905, etc.

The center column may also include lift pins, which may be controlled by a lift pin control signal from, for instance, control module 2913. The lift pins may be used to raise wafer 2901 from showerhead pedestal 2905 to allow an end-effector to pick wafer 2901 and to lower wafer 2901 after being placed by the end end-effector. The end effector may also place wafer 2901 over spacers 2915. As will be described below, spacers 2915 are sized to provide a controlled separation of wafer 2901 between a surface of showerhead 2907 facing wafer 2901 and a surface of showerhead pedestal 2905 facing wafer 2901.

System 2900 further includes gas sources 2917 and 2919, e.g., gas chemistry supplies from a facility and/or dilution (e.g., inert) gases. Depending on the processing being performed relative to a surface of wafer 2901, control module 2913 may control the delivery of gas sources 2917 to showerhead 2907 and/or showerhead pedestal 2905. In some embodiments, gas manifold 2921 may be fluidically interposed between gas sources 2917 and showerhead 2907 and gas manifold 2923 may be fluidically interposed between gas sources 2919 and showerhead pedestal 2905. Appropriate valving and mass flow control mechanisms may be employed and controlled via control module 2913 to ensure suitable gases are delivered during deposition and plasma treatment phases of a process. In some implementations, at least one of stem 2925 of showerhead 2907 and stem 2927 of showerhead pedestal 2905 may include one or more interior flow paths including one or more structures configured to induce turbulent flow along its longitudinal axis as received gas(es) are flowed to a corresponding main body of showerhead 2907 and showerhead pedestal 2905 from a respective one of gas sources 2917 and 2919. In some embodiments, chamber 2903 may include openings 2903a and 2903b through which portions of stems 2925 and 2927 respectively extend. Example stem structures were described in association with at least FIGS. 7B, 8, 12B, 12C, 18A, 18B, 19, 20, 21A, 21B, and 22-27. Gas flow into showerhead 2907 and showerhead pedestal 2905 may be output, and, thereby, distributed in a space volume between wafer 2901 and a corresponding surface of showerhead 2907 and showerhead pedestal 2905 facing wafer 2901 via one or more gas distribution structures of showerhead 2907 and showerhead pedestal 2905. Example gas distribution structures were at least described in association with FIGS. 7A, 7B, 8, 9A-9C, 10, 11, 12A-12C, 13-16, 18A, 18B, 19, 20, 21A, 21B, and 22-27.

During substrate processing, spacers 2915 are configured to maintain a predetermined separation of wafer 2901 from a gas distribution surface of showerhead pedestal 2905 to facilitate (e.g., optimize) deposition to the backside of wafer 2901, while reducing (or even preventing) deposition on the frontside of wafer 2901. In some embodiments, while deposition is targeted for the backside of wafer 2901, one or more inert gases may be flowed over the frontside of wafer 2901 via showerhead 2907 to push reactant gas away from the frontside of wafer 2901 and enable reactant gas(es) output from showerhead pedestal 2905 to be directed to the backside of wafer 2901.

In various embodiments, process and/or dilution gases exit chamber 2903 via an outlet fluidically coupled to, for instance, vacuum pump 2929, which may be a one or two stage mechanical dry pump and/or a turbomolecular pump. In this manner, process and/or dilution gases may be drawn out of chamber 2903 to maintain a suitably low pressure therein. To this end, a closed-loop flow restriction device, such as a throttle valve or a pendulum valve, may be controlled via control module 2913 to further ensure a suitably low pressure in chamber 2903.

System 2900 may further include carrier ring 2931 encircling an outer region of showerhead pedestal 2905. When the frontside of wafer 2901 is being processed, e.g., a material is being deposited thereon, carrier ring 2931 is configured to sit over a carrier ring support region stepped down from a wafer support region in a center (or central portion) of showerhead pedestal 2905. Carrier ring 2931 includes an outer edge side of its disk structure, e.g., outer radius, and a wafer edge side of its disk structure, e.g., inner radius, that is closest to where wafer 2901 is supported. The wafer edge side of carrier ring 2931 may include a plurality of contact support structures configured to lift wafer 2901 when carrier ring 2931 is held by spacers 2915. In this manner, spider forks 3001 (see FIG. 30) may be used to lift and maintain carrier ring 2931 at a predetermined height during, for example, backside deposition processing, as well as utilized to rotate wafer 2901 about an axis perpendicular to a surface of, for instance, showerhead 2907 or showerhead pedestal 2905. Thus, carrier ring 2931 may also be lifted (or otherwise manipulated) along with wafer 2901 to be, for example, rotated to another station, e.g., in a multi-station system, such as multi-station processing tool 3000.

According to various embodiments, system 2900 may include or communicate with thermal management system 2933, such as thermal management system 2800 of FIG. 28, to actively control the temperature of showerhead 2907 and/or showerhead pedestal 2905.

FIG. 30 schematically illustrates a multi-station processing tool configured for backside wafer deposition according to some embodiments.

In some implementations, multi-station processing tool 3000 can include an inbound load lock 3003 and an outbound load lock 3005, either or both of which may include a plasma source and/or an ultraviolet (UV) source. Robot 3007, at atmospheric pressure, is configured to move wafers from a cassette loaded through pod 3009 into inbound load lock 3003 via an atmospheric port 3011. Wafer 2901 is placed by robot 3007 on pedestal 3013 in inbound load lock 3003, atmospheric port 3011 is closed, and inbound load lock 3003 is pumped down. In instances in which inbound load lock 3003 includes a remote plasma source, wafer 2901 may be exposed to a remote plasma treatment in inbound load lock 3003 prior to being introduced into processing chamber 3015. Further, wafer 2901 may be heated in inbound load lock 3003 to, for example, remove moisture and/or adsorbed gases. Next, chamber transport port 3017 to processing chamber 3015 is opened, and another robot 3019 places wafer 2901 into the reactor on a pedestal of a first station shown in the reactor for processing. While the implementation depicted in FIG. 13 includes load locks, it will be appreciated that, in some implementations, direct entry of wafer 2901 into a processing station may be provided.

As seen in FIG. 30, processing chamber 3015 includes four process stations, numbered 1 to 4. Each station has a temperature-controlled pedestal (such as temperature-controlled pedestal 3021 of station 1), and gas line inlets. It will be appreciated that, in some cases, each process station may have different or multiple purposes. For example, in some embodiments, a process station may be switchable between a CVD and PECVD process mode. In another example, deposition operations, such as PECVD operations, may be performed in one station, while exposure to UV radiation for UV curing may be performed in another station. In some embodiments, deposition and UV curing may be performed in the same station. Further, although processing chamber 3015 shown as including four stations, embodiments are not limited thereto. For example, processing chamber 3015 may have any suitable number of stations, such as five or more stations, or three or less stations.

As previously mentioned, multi-station processing tool 3000 may include a wafer handling system (e.g., robot 3019 including spider forks 3001) for transferring and/or positioning wafers within processing chamber 3015. In some embodiments, the wafer handling system may transfer wafers between various process stations and/or between a process station and a load lock. It is contemplated, however, that any suitable wafer handling system may be employed, such as, for example, wafer carousels, other wafer handling robots, etc. Further, multi-station processing tool 3000 may include (or otherwise be coupled to) a system controller 3023 employed to control process conditions and hardware states of multi-station processing tool 3000. System controller 3023 may include one or more memory devices 3025, one or more mass storage devices 3027, and one or more processors 3029. Each processor 3029 may include a central processing unit (CPU) or computer, analog, and/or digital input/output connections, stepper motor controller boards, etc.

In some embodiments, system controller 3023 controls each of the activities of multi-station processing tool 3000. For instance, system controller 3023 may execute system control software 3031 stored in mass storage device 3027, loaded into memory device 3025, and executed by processor 3029. Alternatively, control logic may be hard coded in system controller 3023. Application specific integrated circuits (ASIC), programmable logic devices (e.g., field-programmable gate arrays (FPGAs)) and/or the like may be used for these purposes. In the following discussion, wherever “software” or “code” is used, functionally comparable hard coded logic may be used in its place. System control software 3031 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by multi-station processing tool 3000. System control software 3031 may be configured in any suitable way. For example, various process tool component subroutines or control objects may be written to control operation of the process tool components used to carry out various process tool processes. System control software 3031 may be coded in any suitable computer readable programming language.

In some embodiments, system control software 3031 may include input/output control (IOC) sequencing instructions for controlling the various parameters described above. Other computer software and/or programs stored on mass storage device 3027 and/or memory device 3025 associated with system controller 3023 may be employed in some embodiments. Examples of programs or sections of programs for this purpose include a substrate positioning program, a process gas control program, a pressure control program, a heater control program, a cooler control program, and a plasma control program.

A substrate positioning program may include program code for process tool components that are used to load and orientate wafer 2901 on pedestal 3021 and to control the spacing between wafer 2901 and other parts of multi-station processing tool 3000.

A process gas control program may include code for controlling gas composition (e.g., silicon-containing gases, oxygen-containing gases, nitrogen-containing gases, dilution (or inert) gases, etc., as described herein) and flow rates and optionally for flowing gas into one or more process stations prior to deposition to stabilize the pressure in the process station. A pressure control program may include code for controlling the pressure in the process station by regulating, for example, a throttle valve in an exhaust system of the process station, a gas flow into the process station, etc.

A heater control program may include code for controlling current to a heating unit (e.g., heating loop 1601 of FIG. 16) used to heat a gas distributor (e.g., showerhead 2907, showerhead pedestal 2905, etc.), and, thereby, heat wafer 2901. Alternatively, the heater control program may control delivery of a heat transfer gas (such as helium) to a gas distributor, and, thereby, wafer 2901.

A cooler control program may include code for controlling a flow rate of fluid (e.g., CDA) through a cooling unit (e.g., cooling loop 1605 of FIG. 16) used to extract heat from a gas distributor, such as showerhead 2907, showerhead pedestal 2905, etc., and transfer such thermal energy to, for instance, a waste heat capturing, storage, recycling, and/or disposing system.

A plasma control program may include code for setting RF power levels applied to the process electrodes in one or more process stations in accordance with various embodiments.

A pressure control program may include code for maintaining pressure in a reaction chamber in accordance with various embodiments.

In some embodiments, a user interface may be provided in association with system controller 3023. The user interface may include a display screen, graphical software displays of the apparatus and/or process conditions, and user input devices, such as pointing devices, keyboards, touch screens, microphones, etc.

In some embodiments, parameters adjusted by system controller 3023 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 3023 from various process tool sensors. The signals for controlling the process may be output on analog and/or digital output connections of multi-station process tool 3000. Non-limiting examples of process tool sensors that may be monitored include mass flow controllers, pressure sensors (such as manometers), thermocouples, etc. Appropriately programmed feedback and control algorithms may be used with data from the sensors to maintain process conditions.

System controller 3023 may provide program instructions for implementing one or more of the above-described processes. The program instructions may control a variety of process parameters, such as DC power level, RF bias power level, pressure, temperature, etc. The instructions may control the parameters to operate deposition of film stacks of a stress compensation layer according to various embodiments.

The system controller 3023 will typically include one or more memory devices and one or more processors configured to execute the instructions so that the apparatus will perform a method in accordance with some embodiments. In some instances, machine-readable media containing instructions for controlling process operations in accordance with various embodiments may be coupled to system controller 3023.

In some embodiments, system controller 3023 may be part of a system, which may be part of at least one of the above-described examples. Such systems may include semiconductor processing equipment, including a processing tool or tools, a chamber or chambers, a platform or platforms for processing, and/or specific processing components (e.g., a wafer pedestal, a gas flow system, a thermal management system, etc.). The systems discussed above may be integrated with electronics for controlling their operation before, during, and/or after processing of a semiconductor wafer or substrate. The electronics may be referred to as the “controller,” which may control various components or subparts of the system or systems. For instance, system controller 3023, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, radio frequency (RF) generator settings, RF matching circuit settings, frequency settings, flow rate settings, fluid delivery settings, positional and operational settings, wafer transfers into and out of a tool or chamber and other transfer tools and/or load locks connected to or interfaced with a specific system. In this manner, system controller 3023 may be configured to control, among other systems, the various actuators and motors of a backside wafer processing system.

Broadly speaking, system controller 3023 may be defined as electronics having various integrated circuits, logic, memory, and/or software that receive instructions, issue instructions, control operation, enable cleaning operations, enable endpoint measurements, and/or the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to system controller 3023 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, dies of a wafer, etc.

System controller 3023, in some implementations, may be a part of or coupled to a computer that is integrated with, coupled to the system, otherwise networked to the system, or a combination thereof. For example, system controller 3023 may be in the “cloud” or all or a part of a fab host computer system, which can allow for remote access of wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It is to be understood that the parameters may be specific to the type of process to be performed and the type of tool that the controller is configured to interface with or control. Thus, as described above, system controller 3023 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and/or any other semiconductor processing system that may be associated or used in the fabrication and/or manufacturing of semiconductor wafers.

As noted above, depending on the process step or steps to be performed by the tool, system controller 3023 might communicate with one or more of other tool circuits or modules, other tool components, cluster tools, other tool interfaces, adjacent tools, neighboring tools, tools located throughout a factory, a main computer, another controller, and/or tools used in material transport that bring containers of wafers to and from tool locations and/or load ports in a semiconductor manufacturing factory.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items—it is to be understood that a set or a subset can encompass only one member or multiple members (unless the context indicates otherwise). The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Accordingly, the term “substantially” as used herein, unless otherwise specified, means within 5% of a referenced value. For example, substantially perpendicular means within ±5% of parallel.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element, it may be directly on, directly connected to, or directly coupled to the other element or at least one intervening element may be present. When, however, an element is referred to as being “directly on,” “directly connected to,” or “directly coupled to” another element, there are no intervening elements present. Other terms and/or phrases if used herein to describe a relationship between elements should be interpreted in a like fashion, such as “between” versus “directly between,” “adjacent” versus “directly adjacent,” “on” versus “directly on,” etc. Further, the term “connected” may refer to physical, electrical, and/or fluid connection. To this end, for the purposes of this disclosure, the phrase “fluidically connected” is used with respect to volumes, plenums, holes, etc., that may be connected to one another, either directly or via one or more intervening components or volumes, to form a fluidic connection, similar to how the phrase “electrically connected” is used with respect to components that are connected to form an electric connection. The phrase “fluidically interposed,” if used, may be used to refer to a component, volume, plenum, hole, etc., that is fluidically connected with at least two other components, volumes, plenums, holes, etc., such that fluid flowing from one of those other components, volumes, plenums, holes etc., to the other or another of those components, volumes, plenums, holes, etc., would first flow through the “fluidically interposed” component before reaching that other or another of those components, volumes, plenums, holes, etc., For example, if a pump is fluidically interposed between a reservoir and an outlet, fluid flowing from the reservoir to the outlet would first flow through the pump before reaching the outlet. The phrase “fluidically adjacent,” if used, refers to placement of a fluidic element relative to another fluidic element such that no potential structures fluidically are interposed between the two elements that might potentially interrupt fluid flow between the two fluidic elements. For example, in a flow path having a first valve, a second valve, and a third valve arranged sequentially therealong, the first valve would be fluidically adjacent to the second valve, the second valve fluidically adjacent to both the first and third valves, and the third valve fluidically adjacent to the second valve.

For the purposes of this disclosure, “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. As used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.” Further, the use, if any, of ordinal indicators, such as (a), (b), (c), . . . , or (1), (2), (3), . . . , or the like, in this disclosure and accompanying claims, is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated), unless indicated otherwise. For example, if step (ii) involves the handling of an element that is created in step (i), then step (ii) may be viewed as happening at some point after step (i). In a similar manner, if step (i) involves the handling of an element that is created in step (ii), the reverse is to be understood.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “between,” as used herein and when used with a range of values, is to be understood, unless otherwise indicated, as being inclusive of the start and end values of that range. For example, between 1 and 5 is to be understood as inclusive of the numbers 1, 2, 3, 4, and 5, not just the numbers 2, 3, and 4.

As used herein, the phrase “operatively connected” is to be understood as referring to a state in which two components and/or systems are connected, either directly or indirectly, such that, for example, at least one component or system can control the other. For instance, a controller may be described as being operatively connected with (or to) a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely will not supply such power directly to the resistive heating unit due to the current(s) involved, but it is to be understood that the controller is nonetheless operatively connected with the resistive heating unit.

As used herein, the singular forms, “a,” “an,” and “the” are intended to include the plural forms as well, unless the context clearly indicates otherwise. It is also to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items—it is to be understood that a set or a subset can encompass only one member or multiple members (unless the context indicates otherwise). In addition, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional views, isometric views, perspective views, plan views, and/or exploded illustrations that are schematic depictions of idealized embodiments and/or intermediate structures. As such, variations from the shapes of the illustrations as a result of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and, as such, are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and are not to be interpreted in an idealized or overly formal sense, unless expressly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the inventive concepts. Further, the blocks, units, and/or modules of some embodiments may be physically combined into more complex blocks, units, and/or modules without departing from the teachings of the disclosure.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered as illustrative and not as restrictive, and embodiments are not to be limited to the details given herein.

It is to be further understood that the above disclosure, although focusing on a particular example implementation or implementations, is not limited to only the discussed example, but may also apply to similar variants and mechanisms as well, and such similar variants and mechanisms are also considered to be within the scope of this disclosure. For the avoidance of any doubt, it is also to be understood that the above disclosure is at least directed to the following numbered implementations, as well as to other implementations that are evident from the above disclosure.

Implementation 1: An apparatus including a stem body and a plurality of interior flow paths. The stem body includes a proximal end and a distal end. The proximal end includes a plurality of inlets, each of the inlets being distinct from one another and configured to receive a corresponding one or more gases. The distal end is disposed opposite the proximal end along a longitudinal axis of the stem body, the distal end being configured to interface with a gas distributor of a deposition apparatus, the distal end including a plurality of outlets, at least one of the outlets being distinct from at least another one of the outlets. The plurality of interior flow paths include a first interior flow path and a second interior flow path, each of the interior flow paths extending between a corresponding inlet among the inlets and at least one corresponding outlet among the outlets such that the interior flow paths are distinct from one another, each of the interior flow paths including one or more structures configured to induce turbulent flow along the longitudinal axis of the stem body in response to a flow of the corresponding one or more gases along that interior flow path.

Implementation 2: The apparatus of implementation 1, in which: the inlets include a first inlet and a second inlet; an axis of the first inlet is spaced apart from the longitudinal axis of the stem body in a first direction; a first portion of the first interior flow path longitudinally extends along the axis of the first inlet; an axis of the second inlet is spaced apart from the longitudinal axis of the stem body in a second direction different from the first direction; and a first portion of the second interior flow path longitudinally extends along the axis of the second inlet.

Implementation 3: The apparatus of either implementation 1 or implementation 2, in which the one or more structures define one or more second portions of the first interior flow path, each of the second portions of the first interior flow path following a first helical path about the longitudinal axis of the stem body; and the one or more structures define one or more second portions of the second interior flow path, each of the second portions of the second interior flow path following a second helical path about the longitudinal axis of the stem body.

Implementation 4: The apparatus of implementation 3, in which the first and second helical paths are out of phase with one another such that each second portion of the second interior flow path is intertwined with a corresponding second portion of the first interior flow path.

Implementation 5: The apparatus of either implementation 3 or implementation 4, in which: the one or more first structures further define one or more third portions of the first interior flow path, each of the third portions of the first interior flow path linearly extends along the longitudinal axis of the stem body; and the one or more second structures further define one or more third portions of the second interior flow path, each of the third portions of the second interior flow path linearly extends along the longitudinal axis of the stem body.

Implementation 6: The apparatus of implementation 5, in which: each of the third portions of the first interior flow path is spaced apart from the longitudinal axis of the stem body in the second direction; and each of the third portions of the second interior flow path is spaced apart from the longitudinal axis of the stem body in the first direction.

Implementation 7: The apparatus of either implementation 5 or implementation 6, in which: each of the third portions of the first interior flow path defines a first chamber including at least one first impinging protrusion constricting a passageway of the first interior flow path; and each of the third portions of the second interior flow path defines a second chamber including at least one second impinging protrusion constricting a passageway of the second interior flow path.

Implementation 8: The apparatus of implementation 7, in which: the at least one first impinging protrusion extends along a first circumferential section of an interior wall of the first chamber; and the at least one second impinging protrusion extends along a second circumferential section of an interior wall of the second chamber.

Implementation 9: The apparatus of implementation 8, in which: a median reference plane divides the first and second chambers into corresponding divisions, the median reference plane extending parallel to and crossing the longitudinal axis of the stem body; and the first circumferential section of the first chamber is disposed on an opposite side of the median reference plane from the second circumferential section of the second chamber.

Implementation 10: The apparatus of any one of implementations 7 to 9, in which: the first chamber includes multiple first impinging protrusions; and the second chamber includes multiple second impinging protrusions.

Implementation 11: The apparatus of any one of implementations 5 to 10, in which: the one or more second portions of the first interior flow path are alternately arranged with the one or more third portions of the first interior flow path along the longitudinal axis of the stem body; and the one or more second portions of the second interior flow path are alternately arranged with the one or more third portions of the second interior flow path along the longitudinal axis of the stem body.

Implementation 12: The apparatus of any one of implementations 5 to 11, in which: the first interior flow path includes four second portions and three third portions; and the second interior flow path includes four second portions and three third portions.

Implementation 13: The apparatus of implementation 12, in which: three of the four second portions of the first interior flow path include at least three revolutions about the longitudinal axis of the stem body; one of the four second portions of the first interior flow path includes at least one revolution about the longitudinal axis of the stem body, the one of the four second portions of the first interior flow path being closer to the distal end of the stem body than the three of the four second portions of the first interior flow path; three of the four second portions of the second interior flow path include at least three revolutions about the longitudinal axis of the stem body; and one of the four second portions of the second interior flow path includes at least one revolution about the longitudinal axis of the stem body, the one of the four second portions of the second interior flow path being closer to the distal end of the stem body than the three of the four second portions of the second interior flow path.

Implementation 14: The apparatus of any one of implementations 5 to 13, in which: the at least one of the outlets defines an outlet of the first interior flow path; and a fourth portion of the first interior flow path longitudinally extends along an axis of the at least one of the outlets, the axis of the at least one of the outlets extending along the longitudinal axis of the stem body.

Implementation 15: The apparatus of implementation 14, in which the axis of the at least one of the outlets is coaxially aligned with the longitudinal axis of the stem body.

Implementation 16: The apparatus of either implementation 14 or implementation 15, in which: the one or more structures further define one or more fourth portions of the second interior flow path, each of the fourth portions of the second interior flow path surrounding the fourth portion of the first interior flow path; each of the fourth portions of the second interior flow path includes an annular passageway extending along the longitudinal axis of the stem body, each annular passageway including a first end closer to the proximal end of the stem body and a second end closer to the distal end of the stem body; and each second end terminates at a corresponding impinging surface including a plurality of through-channel orifices extending along the longitudinal axis of the stem body, the corresponding plurality of through-channel orifices being circumferentially spaced apart from one another about the longitudinal axis of the stem body.

Implementation 17: The apparatus of implementation 16, in which each annular passageway is coaxially aligned with the longitudinal axis of the stem body.

Implementation 18: The apparatus of either implementation 16 or implementation 17, in which: the second interior flow path includes multiple fourth portions axially arranged along the longitudinal axis of the stem body; and first central axes of the through-channel orifices of one fourth portion among the multiple fourth portions are circumferentially offset from second central axes of the through-channel orifices of another fourth portion among the multiple fourth portions.

Implementation 19: The apparatus of implementation 18, in which the first central axes are incongruent with the second central axes.

Implementation 20: The apparatus of either implementation 18 or implementation 19, in which the through-channel orifices of the one fourth portion of the second interior flow path define multiple ones of the outlets of the distal end of the stem body, the multiple ones of the outlets being distinct from the outlet of the first interior flow path.

Implementation 21: The apparatus of any one of implementations 16 to 20, in which the second interior flow path includes five of the fourth portions.

Implementation 22: The apparatus of any one of implementations 16 to 21, in which the fourth portion of the first interior flow path extends further from the proximal end of the stem body than each of the fourth portions of the second interior flow path.

Implementation 23: The apparatus of any one of implementations 1 to 22, in which: the stem body is an additively manufactured component; and the interior flow paths define contiguous voids in the stem body.

Implementation 24: The apparatus of any one of implementations 1 to 23, in which the stem body is formed of an aluminum alloy.

Implementation 25: The apparatus of any one of implementations 1 to 24, in which the interior flows paths are fluidically isolated from one another within the stem body.

Implementation 26: The apparatus of any one of implementations 1 to 25, in which the gas distributor is a showerhead-pedestal of the deposition apparatus.

Implementation 27: The apparatus of any one of implementations 1 to 25, in which the gas distributor is a showerhead of the deposition apparatus.

Implementation 28: The apparatus of any one of implementations 1 to 27, in which the interior flow paths further include at least a third interior flow path.

Implementation 29: An apparatus including a showerhead. The showerhead includes a first surface, a second surface, and a stem body. The first surface includes a plurality of first inlets. The second surface opposes the first surface, the second surface including a plurality of gas distribution ports. The stem body includes a proximal end, a distal end, and a plurality of interior flow paths. The proximal end includes a plurality of second inlets, each of the second inlets being distinct from one another and configured to receive one or more gases. The distal end is disposed opposite the proximal end along a longitudinal axis of the stem body, the distal end being coupled to the first surface of the showerhead, the distal end including a plurality of outlets interfacing with the plurality of first inlets, at least one of the outlets being distinct from at least another one of the outlets. Each of the interior flow paths extends between a corresponding second inlet among the second inlets and at least one corresponding outlet among the outlets such that the interior flow paths are fluidically isolated from one another within the stem body, each of the interior flow paths including one or more structures configured to induce turbulent flow along the longitudinal axis of the stem body in response to a flow of one or more gases. A first interior flow path among the interior flow paths is fluidically connected to a first group of the gas distribution ports. A second interior flow path among the interior flow paths is fluidically connected to a second group of the gas distribution ports, the second group being different from the first group.

Implementation 30: The apparatus of implementation 29, in which the showerhead is a showerhead pedestal configured to support a substrate at or near its periphery such that a backside of the substrate is substantially exposed to the plurality of gas distribution ports.

Implementation 31: The apparatus of either implementation 29 or implementation 30, further including: a process chamber configured to support a first portion of the stem body and the showerhead therein, the process chamber including an opening through which a second portion of the stem body extends to expose the proximal end.

Implementation 32: An apparatus including a main body. The main body includes a first surface and a second surface opposing the first surface in a first direction, the first surface including a plurality of gas distribution ports and being divided into a plurality of zones. The plurality of gas distribution ports includes a group of first gas distribution ports, a group of second gas distribution ports, and a group of third gas distribution ports. The first gas distribution ports are distributed across a first zone among the zones, each first gas distribution port being fluidically connected to one or more first gas inlets via a corresponding first gas distribution flow path. The second gas distribution ports are distributed across a second zone among the zones, each second gas distribution port being fluidically connected to one or more second gas inlets via a corresponding second gas distribution flow path. The third gas distribution ports are distributed across a third zone among the zones, each third gas distribution port being fluidically connected to one or more of the third gas inlets via a corresponding third gas distribution flow path. The first zone separates the second zone from the third zone. Within the main body, the first gas distribution flow paths are separated from each of the second and third gas distribution flow paths.

Implementation 33: The apparatus of implementation 32, in which the one or more second gas inlets also define the one or more third gas inlets.

Implementation 34: The apparatus of either implementation 32 or implementation 33, in which: the first gas distribution flow paths are configured to provide one or more first gases to the first gas distribution ports such that an output of the one or more first gases from the first gas distribution ports exhibits a first gas flow profile across the first zone; the second gas distribution flow paths are configured to provide one or more second gases to the second gas distribution ports such that an output of the one or more second gases from the second gas distribution ports exhibits a second gas flow profile across the second zone; the third gas distribution flow paths are configured to provide the one or more second gases to the third gas distribution ports such that an output of the one or more second gases from the third gas distribution ports exhibits a third gas flow profile across the third zone; and the first, second, and third gas flow profiles are different for identical inlet/outlet boundary conditions.

Implementation 35: The apparatus of implementation 34, in which: the first gas flow profile is substantially uniform; the second gas flow profile varies in at least one direction across the second zone; and the third gas flow profile varies in at least one direction across the third zone.

Implementation 36: The apparatus of implementation 35, in which each of the second and third gas flow profiles increase with increasing distance from the first gas flow profile.

Implementation 37: The apparatus of any one of implementations 32 to 36, in which each of the second and third zones includes: a first arrangement of gas distribution ports having a first spatial relationship; and a second arrangement of gas distribution ports having a second spatial relationship different from the first spatial relationship.

Implementation 38: The apparatus of implementation 37, in which the second spatial relationship includes more densely arranged gas distribution ports than the first spatial relationship.

Implementation 39: The apparatus of either implementation 37 or implementation 38, in which the first gas distribution ports are distributed across the first zone according to the first spatial arrangement.

Implementation 40: The apparatus of either implementation 37 or implementation 38, in which the first arrangement of gas distribution ports surrounds the second arrangement of gas distribution ports.

Implementation 41: The apparatus of any one of implementations 37 to 40, in which the second arrangement of gas distribution ports is closer to a periphery of the first surface than a center of the first surface.

Implementation 42: The apparatus of any one of implementations 32 to 36, in which: the group of the second gas distribution ports includes: a first sub-group of the second gas distribution ports distributed across a first sub-zone of the second zone; and a second sub-group of the second gas distribution ports distributed across a second sub-zone of the second zone, the second sub-zone of the second zone being adjacent to the first sub-zone of the second zone; and the group of the third gas distribution ports includes: a first sub-group of the third gas distribution ports distributed across a first sub-zone of the third zone; and a second sub-group of the third gas distribution ports distributed across a second sub-zone of the third zone, the second sub-zone of the third zone being adjacent to the first sub-zone of the third zone.

Implementation 43: The apparatus of implementation 42, in which, under identical inlet/outlet boundary conditions: the second gas distribution flow paths are configured such that a respective flow conductance along each of those second gas distribution flow paths associated with the second sub-group of the second gas distribution ports is greater than each respective flow conductance along each of those second gas distribution flow paths associated with the first sub-group of the second gas distribution ports; and the third gas distribution flow paths are configured such that a respective flow conductance along each of those third gas distribution flow paths associated with the second sub-group of the third gas distribution ports is greater than each respective flow conductance along each of those third gas distribution flow paths associated with the first sub-group of the third gas distribution ports.

Implementation 44: The apparatus of implementation 42, in which: the group of the second gas distribution ports further includes: a third sub-group of the second gas distribution ports distributed across a third sub-zone of the second zone, the third sub-zone of the second zone being between the first and second sub-zones of the second zone; the group of the third gas distribution ports further includes: a third sub-group of the third gas distribution ports distributed across a third sub-zone of the third zone, the third sub-zone of the third zone being between the first and second sub-zones of the third zone.

Implementation 45: The apparatus of implementation 44, in which, under identical inlet/outlet boundary conditions: the second gas distribution flow paths are configured such that a respective flow conductance along each of those second gas distribution flow paths associated with the third sub-group of the second gas distribution ports is greater than each respective flow conductance along each of those second gas distribution flow paths associated with the first sub-group of the second gas distribution ports and less than each respective flow conductance along each of those second gas distribution flow paths associated with the second sub-group of the second gas distribution ports; and the third gas distribution flow paths are configured such that a respective flow conductance along each of those third gas distribution flow paths associated with the third sub-group of the third gas distribution ports is greater than each respective flow conductance along each of those third gas distribution flow paths associated with the first sub-group of the third gas distribution ports and less than each respective flow conductance along each of those third gas distribution flow paths associated with the second sub-group of the third gas distribution ports.

Implementation 46: The apparatus of either implementation 44 or implementation 45, in which: the third sub-zone of the second zone includes a sub-portion in which a first plurality of the second gas distribution ports of the third sub-group of the second gas distribution ports are configured differently than a second plurality of the second gas distribution ports of the third sub-group of the second gas distribution ports; and the third sub-zone of the third zone includes a sub-portion in which a first plurality of the third gas distribution ports of the third sub-group of the third gas distribution ports are configured differently than a second plurality of the third gas distribution ports of the third sub-group of the third gas distribution ports.

Implementation 47: The apparatus of implementation 46, in which: the first plurality of the second gas distribution ports of the third sub-group of the second gas distribution ports are more densely arranged than the second plurality of the second gas distribution ports of the third sub-group of the second gas distribution ports; and the first plurality of the third gas distribution ports of the third sub-group of the third gas distribution ports are more densely arranged than the second plurality of the third gas distribution ports of the third sub-group of the third gas distribution ports.

Implementation 48: The apparatus of any one of implementations 32 to 47, in which: the main body includes a plurality of passages extending in a second direction different from the first direction, the passages being spaced apart from one another in a third direction different from the second direction; and each of the passages is fluidically connected to a corresponding plurality of the gas distribution ports.

Implementation 49: The apparatus of implementation 48, in which a cross-sectional area of each of the passages in a plane perpendicular to the second direction is substantially equivalent.

Implementation 50: The apparatus of implementation 48, in which a cross-sectional area of at least one of the passages in a plane perpendicular to the second direction is different from a cross-sectional area of at least another one of the passages in the plane perpendicular to the second direction.

Implementation 51: The apparatus of any one of implementations 48 to 50, in which corresponding pitches between adjacent passages among the passages are substantially equivalent.

Implementation 52: The apparatus of any one of implementations 48 to 50, in which: a first plurality of the passages is arranged in the third direction with a first pitch; and a second plurality of the passages is arranged in the third direction with a second pitch different from the first pitch.

Implementation 53: The apparatus of any one of implementations 48 to 52, further including an outer wall surrounding the main body. The main body further includes: a third surface extending between the first surface and the second surface; a plurality of first blind cavities recessed into the third surface and arranged about a perimeter of the main body; and a plurality of second blind cavities recessed into the third surface and arranged about the perimeter of the main body, each of the first blind cavities being disposed between the first surface and a corresponding one of the second blind cavities in the first direction. A portion of the third surface extending between the first blind cavities and the second blind cavities forms a septal wall. The septal wall includes a plurality of recessed portions in the third surface, each of the recessed portions being disposed between corresponding ones of the first and second blind cavities adjacent to one another in the first direction so as to form, in association with an inner surface of the outer wall, a respective gas flow channel fluidically connecting the corresponding ones of the first and second blind cavities.

Implementation 54: The apparatus of implementation 53, in which each of the first blind cavities is fluidically connected to one or more of the passages.

Implementation 55: The apparatus of either implementation 53 or implementation 54, in which some of the passages fluidically connect two of the first blind cavities to one another, the two first blind cavities opposing one another relative to a central axis of the main body extending in the first direction.

Implementation 56: The apparatus of any one of implementations 53 to 55, in which: each first blind cavity among a first group of the first blind cavities has a first opening area facing the inner surface of the outer wall and is fluidically connected to a first amount of the passages; and each first blind cavity among a second group of the first blind cavities has a second opening area facing the inner surface of the outer wall and is fluidically connected to a second amount of the passages, the second opening area being larger than the first opening area, the second amount being greater than the first amount.

Implementation 57: The apparatus of any one of implementations 53 to 56, further including: a plurality of first elongated holes in the main body that extend radially from a first central region of the main body, each of the first elongated holes having: a corresponding proximal end fluidically connected to at least one of the one or more first inlets; and a corresponding distal end fluidically connected to a second blind cavity among the second blind cavities so as to form a corresponding portion of at least one of the first gas distribution flow paths; and a plurality of second elongated holes in the main body that extend radially from a second central region of the main body, each of the second elongated holes having: a corresponding proximal end fluidically connected to at least one of the one or more second inlets and the one or more third inlets; and a corresponding distal end fluidically connected to a second blind cavity among the second blind cavities so as to form a corresponding portion of at least one of the second and third gas distribution flow paths.

Implementation 58: The apparatus of implementation 57, in which: each of the first elongated holes extends in a first planar region of the main body; each of the second elongated holes extends in a second planar region of the main body different from the first planar region of the main body; and the first planar region is closer to the second surface of the main body than the second planar region.

Implementation 59: The apparatus of implementation 58, in which each of the first and second planar regions are closer to the second surface than each of the passages.

Implementation 60: The apparatus of any one of implementations 57 to 59, in which respective cross-sectional areas of the first and second elongated holes in corresponding planes perpendicular to their respective directions of longitudinal extension are equivalent.

Implementation 61: The apparatus of any one of implementations 57 to 59, in which: a first group of the second blind cavities is physically and fluidically connected directly to the first elongated holes and separated from the second elongated holes in an interior of the main body; a second group of the second blind cavities is physically and fluidically connected directly to the second elongated holes and separated from the first elongated holes in the interior of the main body; the second group of the second blind cavities includes: a first sub-group of second blind cavities, each second blind cavity of the first sub-group of second blind cavities being physically and fluidically connected directly to one distal end of the second elongated holes among the distal ends of the second elongated holes; and a second sub-group of second blind cavities, each second blind cavity of the second sub-group of second blind cavities being physically and fluidically connected directly to two distal ends of the second elongated holes among the distal ends of the second elongated holes.

Implementation 62: The apparatus of implementation 61, in which: the first group of the second blind cavities is arranged in a first region of the main body; the first sub-group of second blind cavities is arranged in a second region of the main body; and the second sub-group of second blind cavities is arranged in a third region of the main body, the second region of the main body being between the first and third regions of the main body.

Implementation 63: The apparatus of implementation 62, in which: the second region is disposed on opposite sides of the first region; and the third region is disposed on opposite sides of the second region and opposite sides of the first region.

Implementation 64: The apparatus of either implementation 62 or implementation 63, in which: each of the first elongated holes has a substantially equivalent first cross-sectional area in a plane perpendicular to its respective direction of longitudinal extension; each second elongated hole associated with the first sub-group of second blind cavities has a substantially equivalent second cross-sectional area in a plane perpendicular to its respective direction of longitudinal extension; each second elongated hole associated with the second sub-group of second blind cavities has a substantially equivalent third cross-sectional area in a plane perpendicular to its respective direction of longitudinal extension; and the first, second, and third cross-sectional areas are different from one another.

Implementation 65: The apparatus of implementation 64, in which: the third cross-sectional area is greater than the second cross-sectional area; and the second cross-sectional area is greater than the first cross-sectional area.

Implementation 66: The apparatus of any one of implementations 32 to 65, further including: a cooling conduit thermally coupled to the main body, the cooling conduit having an inlet being configured to receive clean dry air (CDA) at a first temperature and an outlet being configured to output the CDA at a second temperature different from the first temperature. The main body includes a first groove recessed into the second surface, a portion of the cooling conduit extending within the first groove.

Implementation 67: The apparatus of implementation 66, further including: a first cap structure enclosing the cooling conduit in the first groove in a compressed state.

Implementation 68: The apparatus of either implementation 66 or implementation 67, in which the cooling conduit is formed of stainless steel.

Implementation 69: The apparatus of any one of implementations 66 to 68, in which the cooling conduit is sized to enable a flow rate of CDA up to about 140 standard liters per minute with a Reynolds number greater than about 2500.

Implementation 70: The apparatus of any one of implementations 66 to 69, further including a resistive heating element. The main body further includes a second groove recessed into the second surface, a portion of the resistive heating element extending within the second groove.

Implementation 71: The apparatus of implementation 70, in which: in the first direction, the second groove extends farther into the second surface than the first groove; and in a radial direction perpendicular to the first direction, an outermost portion of second groove is closer to a periphery of the main body than an outermost portion of the first groove.

Implementation 72: The apparatus of any one of implementations 32 to 71, further including a process chamber configured to support the main body therein. The main body forms a portion of a showerhead.

Implementation 73: The apparatus of implementation 72, in which the showerhead is a showerhead pedestal configured to support a substrate thereover such that a majority of a backside of the substrate is exposed to the plurality of gas distribution ports.

Implementation 74: The apparatus of any one of implementations 32 to 73, in which the main body is formed of an aluminum alloy.

1. An apparatus comprising:
a main body comprising a first surface and a second surface opposing the first surface in a first direction, the first surface comprising a plurality of gas distribution ports divided into a plurality of zones,
wherein the plurality of gas distribution ports comprises:
a group of first gas distribution ports distributed across a first zone of the zones, wherein each first gas distribution port is in fluidic communication with one or more first gas inlets along a first gas distribution flow path;
a group of second gas distribution ports distributed across a second zone of the zones, wherein each second gas distribution port is in fluidic communication with one or more second gas inlets along a second gas distribution flow path; and
a group of third gas distribution ports distributed across a third zone of the zones, wherein each third gas distribution port is in fluidic communication with one or more third gas inlets along a third gas distribution flow path,
wherein the first zone separates the second zone from the third zone, and
wherein, within the main body, the first gas distribution flow paths are separated from each of the second and third gas distribution flow paths.

2. The apparatus of claim 1, wherein:
the first gas distribution flow paths are configured to provide one or more first gases to the first gas distribution ports such that an output of the one or more first gases from the first gas distribution ports exhibits a first gas flow profile across the first zone;
the second gas distribution flow paths are configured to provide one or more second gases to the second gas distribution ports such that an output of the one or more second gases from the second gas distribution ports exhibits a second gas flow profile across the second zone;
the third gas distribution flow paths are configured to provide the one or more second gases to the third gas distribution ports such that an output of the one or more second gases from the third gas distribution ports exhibits a third gas flow profile across the third zone; and
the first, second, and third gas flow profiles are different for identical inlet/outlet boundary conditions.

3. The apparatus of claim 2, wherein:
the first gas flow profile is substantially uniform;
the second gas flow profile varies in at least one direction across the second zone; and
the third gas flow profile varies in at least one direction across the third zone.

4. The apparatus of claim 1, wherein each of the second and third zones comprises:
a first arrangement of gas distribution ports having a first spatial relationship; and
a second arrangement of gas distribution ports having a second spatial relationship different from the first spatial relationship.

5. The apparatus of claim 4, wherein:
the group of the second gas distribution ports comprises:
a first sub-group of the second gas distribution ports distributed across a first sub-zone of the second zone; and
a second sub-group of the second gas distribution ports distributed across a second sub-zone of the second zone, the second sub-zone of the second zone being adjacent to the first sub-zone of the second zone; and
the group of the third gas distribution ports comprises:
a first sub-group of the third gas distribution ports distributed across a first sub-zone of the third zone; and
a second sub-group of the third gas distribution ports distributed across a second sub-zone of the third zone, the second sub-zone of the third zone being adjacent to the first sub-zone of the third zone.

6. The apparatus of claim 5, wherein, under identical inlet/outlet boundary conditions:
the second gas distribution flow paths are configured such that a respective flow conductance along each of those second gas distribution flow paths associated with the second sub-group of the second gas distribution ports is greater than each respective flow conductance along each of those second gas distribution flow paths associated with the first sub-group of the second gas distribution ports; and
the third gas distribution flow paths are configured such that a respective flow conductance along each of those third gas distribution flow paths associated with the second sub-group of the third gas distribution ports is greater than each respective flow conductance along each of those third gas distribution flow paths associated with the first sub-group of the third gas distribution ports.

7. The apparatus of claim 6, wherein:
the group of the second gas distribution ports further comprises:
a third sub-group of the second gas distribution ports distributed across a third sub-zone of the second zone, the third sub-zone of the second zone being between the first and second sub-zones of the second zone;
the group of the third gas distribution ports further comprises:
a third sub-group of the third gas distribution ports distributed across a third sub-zone of the third zone, the third sub-zone of the third zone being between the first and second sub-zones of the third zone.

8. The apparatus of claim 7, wherein, under identical inlet/outlet boundary conditions:
the second gas distribution flow paths are configured such that a respective flow conductance along each of those second gas distribution flow paths associated with the third sub-group of the second gas distribution ports is greater than each respective flow conductance along each of those second gas distribution flow paths associated with the first sub-group of the second gas distribution ports and less than each respective flow conductance along each of those second gas distribution flow paths associated with the second sub-group of the second gas distribution ports; and
the third gas distribution flow paths are configured such that a respective flow conductance along each of those third gas distribution flow paths associated with the third sub-group of the third gas distribution ports is greater than each respective flow conductance along each of those third gas distribution flow paths associated with the first sub-group of the third gas distribution ports and less than each respective flow conductance along each of those third gas distribution flow paths associated with the second sub-group of the third gas distribution ports.

9. The apparatus of claim 7, wherein:
the third sub-zone of the second zone comprises a sub-portion in which a first plurality of the second gas distribution ports of the third sub-group of the second gas distribution ports are configured differently than a second plurality of the second gas distribution ports of the third sub-group of the second gas distribution ports; and
the third sub-zone of the third zone comprises a sub-portion in which a first plurality of the third gas distribution ports of the third sub-group of the third gas distribution ports are configured differently than a second plurality of the third gas distribution ports of the third sub-group of the third gas distribution ports.

10. The apparatus of claim 1, wherein:
the main body comprises a plurality of passages extending in a second direction different from the first direction, the passages being spaced apart from one another in a third direction different from the second direction; and
each of the passages is fluidically connected to a plurality of the gas distribution ports.

11. The apparatus of claim 10, wherein:
a first plurality of the passages is arranged in the third direction with a first pitch; and
a second plurality of the passages is arranged in the third direction with a second pitch different from the first pitch.

12. The apparatus of claim 10, further comprising:
an outer wall surrounding the main body,
wherein the main body further comprises:
a third surface extending between the first surface and the second surface;
a plurality of first blind cavities recessed into the third surface and arranged about a perimeter of the main body; and
a plurality of second blind cavities recessed into the third surface and arranged about the perimeter of the main body, each of the first blind cavities being disposed between the first surface and one of the second blind cavities in the first direction, and
wherein:
a portion of the third surface extending between the first blind cavities and the second blind cavities forms a septal wall; and
the septal wall comprises a plurality of recessed portions in the third surface, each of the recessed portions being disposed between corresponding ones of the first and second blind cavities adjacent to one another in the first direction so as to form, in association with an inner surface of the outer wall, a respective gas flow channel fluidically connecting the corresponding ones of the first and second blind cavities.

13. The apparatus of claim 12, wherein:
each first blind cavity among a first group of the first blind cavities has a first opening area facing the inner surface of the outer wall and is fluidically connected to a first amount of the passages; and
each first blind cavity among a second group of the first blind cavities has a second opening area facing the inner surface of the outer wall and is fluidically connected to a second amount of the passages, the second opening area being larger than the first opening area, the second amount being greater than the first amount.

14. The apparatus of claim 12, further comprising:
a plurality of first elongated holes in the main body that extend radially from a first central region of the main body, each of the first elongated holes having:
a proximal end fluidically connected to at least one of the one or more first gas inlets; and
a distal end fluidically connected to a second blind cavity among the second blind cavities so as to form a corresponding portion of at least one of the first gas distribution flow paths; and
a plurality of second elongated holes in the main body that extend radially from a second central region of the main body, each of the second elongated holes having:
a proximal end fluidically connected to at least one of the one or more second gas inlets and the one or more third gas inlets; and
a distal end fluidically connected to a second blind cavity among the second blind cavities so as to form a corresponding portion of at least one of the second and third gas distribution flow paths.

15. The apparatus of claim 14, wherein:
each of the first elongated holes extends in a first planar region of the main body;
each of the second elongated holes extends in a second planar region of the main body different from the first planar region of the main body;
the first planar region is closer to the second surface of the main body than the second planar region; and
each of the first and second planar regions are closer to the second surface than each of the passages.

16. The apparatus of claim 14, wherein:
a first group of the second blind cavities is physically and fluidically connected directly to the first elongated holes and separated from the second elongated holes in an interior of the main body;
a second group of the second blind cavities is physically and fluidically connected directly to the second elongated holes and separated from the first elongated holes in the interior of the main body;
the second group of the second blind cavities comprises:
a first sub-group of second blind cavities, each second blind cavity of the first sub-group of second blind cavities being physically and fluidically connected directly to one distal end of the second elongated holes among the distal ends of the second elongated holes; and
a second sub-group of second blind cavities, each second blind cavity of the second sub-group of second blind cavities being physically and fluidically connected directly to two distal ends of the second elongated holes among the distal ends of the second elongated holes.

17. The apparatus of claim 16, wherein:
the first group of the second blind cavities is arranged in a first region of the main body;
the first sub-group of second blind cavities is arranged in a second region of the main body;
the second sub-group of second blind cavities is arranged in a third region of the main body,
the second region of the main body being between the first and third regions of the main body;
the second region is disposed on opposite sides of the first region; and
the third region is disposed on opposite sides of the second region and opposite sides of the first region.

18. The apparatus of claim 17, wherein:
each of the first elongated holes has a substantially equivalent first cross-sectional area in a plane perpendicular to its respective direction of longitudinal extension;
each second elongated hole associated with the first sub-group of second blind cavities has a substantially equivalent second cross-sectional area in a plane perpendicular to its respective direction of longitudinal extension;
each second elongated hole associated with the second sub-group of second blind cavities has a substantially equivalent third cross-sectional area in a plane perpendicular to its respective direction of longitudinal extension; and
the first, second, and third cross-sectional areas are different from one another.

19. The apparatus of claim 1, further comprising:
either or both of a cooling conduit and a resistive heating element,
wherein:
when the apparatus includes the cooling conduit, the cooling conduit is thermally coupled to the main body and comprises:
an inlet configured to receive clean dry air at a first temperature; and
an outlet configured to output the clean dry air at a second temperature different from the first temperature;
when the apparatus includes the cooling conduit, the main body comprises a first groove recessed into the second surface, a portion of the cooling conduit extending within the first groove; and
when the apparatus includes the resistive heating element, the main body further comprises a second groove recessed into the second surface, a portion of the resistive heating element extending within the second groove.

20. The apparatus of claim 1, further comprising:
a process chamber configured to support the main body therein,
wherein the main body forms a portion of a showerhead or a showerhead pedestal.
